(19) United States
(12) Patent Application Publication
(10) Pub. No.: US 2025/0004377 A1
(43) Pub. Date: Jan. 2, 2025

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR PRODUCING ELECTRONIC DEVICE

(71) Applicant: FUJIFILM Corporation, Tokyo (JP)

(72) Inventors: Eiji FUKUZAKI, Haibara-gun, Shizuoka (JP); Shuhei YAMAGUCHI, Haibara-gun, Shizuoka (JP); Tomoaki YOSHIOKA, Haibara-gun, Shizuoka (JP); Taro MIYOSHI, Haibara-gun, Shizuoka (JP)

(73) Assignee: FUJIFILM Corporation, Tokyo (JP)

(21) Appl. No.: 18/424,834

(22) Filed: Jan. 28, 2024

Related U.S. Application Data
(63) Continuation of application No. PCT/JP2022/028542, filed on Jul. 22, 2022.

(30) Foreign Application Priority Data
Jul. 30, 2021 (JP) 2021-126330
Jun. 24, 2022 (JP) 2022-102247

(51) Int. Cl. G03F 7/039; C08F 212/14; C08F 212/32; C08F 220/30; C08F 220/58; C08F 226/06; C08K 5/42; G03F 7/00; G03F 7/004; G03F 7/16

(52) U.S. Cl. CPC G03F 7/0397; C08F 212/24; C08F 212/32; C08F 220/301; C08F 220/302; C08F 220/58; C08F 226/06; C08K 5/42; G03F 7/0045; C08F 2800/10; G03F 7/162; G03F 7/70025; G03F 7/70033

(57) ABSTRACT

An actinic ray-sensitive or radiation-sensitive resin composition contains (A) a resin having a repeating unit (a) having a group that is decomposed by the action of an acid to generate a carboxylic acid and (B) a compound that generates an acid upon irradiation with an actinic ray or a radiation and is represented by a specified general formula (1). The repeating unit (a) is represented by a general formula (a), and the compound (B) is represented by a general formula (1).

### CROSS REFERENCE TO RELATED APPLICATION

This is a continuation of International Application No. PCT/JP2022/028542 filed on Jul. 22, 2022, and claims priority from Japanese Patent Applications No. 2021-126330 filed on Jul. 30, 2021, and No. 2022-102247 filed on Jun. 24, 2022, the entire disclosures of which are incorporated herein by reference.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for producing an electronic device.

### 2. Description of the Related Art

In fabrication processes for semiconductor devices such as ICs (Integrated Circuits) or LSIs (Large Scale Integrations), microprocessing by lithography using resist compositions has been performed. In recent years, with an increase in the degree of integration of integrated circuits, formation of ultrafine patterns in the submicron range or the quarter micron range has come to be in demand. With this, there is a trend for exposure wavelengths toward shorter wavelengths from the g-line to the i-line further to the KrF excimer laser beam; currently, exposure apparatuses using, as light sources, the ArF excimer laser having a wavelength of 193 nm have been developed. In addition, as a technique of further increasing the resolving power, a technique in which the space between a projection lens and a sample is filled with a liquid having a high refractive index (hereafter, also referred to as “immersion liquid”), what is called, the immersion method is being developed.

In addition, currently, lithography using, instead of excimer laser beams, an electron beam (EB), X-rays, extreme ultraviolet rays (EUV), or the like is also being developed. With this, chemical amplification resist compositions that are effectively sensitive to various actinic rays or radiations and provide high resolution have been developed.

For example, WO2020/045534A describes an actinic ray-sensitive or radiation-sensitive resin composition containing a resin that is decomposed by the action of an acid to provide an increased degree of solubility in an alkali developer and a compound that has a benzenesulfonate anion having a specified sterically hindered group introduced therein and generates an acid upon irradiation with an actinic ray or a radiation.

In addition, WO2017/138267A describes an actinic ray-sensitive or radiation-sensitive resin composition containing an acid decomposable resin having a specified amount or more of a repeating unit having an aromatic ring and including a repeating unit having a specified structure in which a carboxyl group is protected with a group having an alicyclic structure.

### SUMMARY OF THE INVENTION

In recent years, the size of patterns has been reduced; in order to form such patterns, further improvements in various performances of actinic ray-sensitive or radiation-sensitive resin compositions have been in demand.

The related art described in WO2020/045534A and WO2017/138267A still has room for further improvements in resolution, roughness performance, pattern profiles, and development defects.

Accordingly, an object of the present invention is to provide an actinic ray-sensitive or radiation-sensitive resin composition that has high resolution and high roughness performance, can provide an excellent pattern profile, and can achieve reduction in development defects in the formation of an ultrafine pattern (having, in particular, a line width or a space width of 20 nm or less), and an actinic ray-sensitive or radiation-sensitive film, a pattern forming method, and a method for producing an electronic device that use the composition.

The inventors of the present invention performed thorough studies and have found that the above-described object can be addressed by using an actinic ray-sensitive or radiation-sensitive resin composition containing a resin including a repeating unit having a specified structure in which a carboxyl group bonded to an aromatic ring group is protected with a group that is decomposed to leave by the action of an acid (leaving group), and a compound that has a benzenesulfonate anion into which a specified sterically hindered group is introduced and that generates an acid upon irradiation with an actinic ray or a radiation.

Specifically, the inventors of the present invention have found that the above-described object can be achieved by employing the following features.

[1]

An actinic ray-sensitive or radiation-sensitive resin composition including (A) and (B) below:
(A) a resin having a repeating unit (a) having a group that is decomposed by an action of an acid to generate a carboxylic acid and represented by a general formula (a) below; and
(B) a compound that generates an acid upon irradiation with an actinic ray or a radiation and is represented by a general formula (1) below,

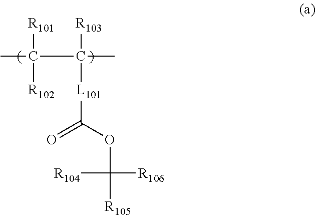

in the general formula (a), R₁₀₁ to R₁₀₃ each independently represent a hydrogen atom, an organic group, or a halogen atom; L₁₀₁ represents a divalent aromatic ring group; R₁₀₄ to R₁₀₆ each independently represent a hydrogen atom, an alkyl group, a cycloalkyl group, an aryl group, an alkenyl group, or an alkynyl group; two among R₁₀₄ to R₁₀₆ may be linked together to form a ring; when R₁₀₄ is a hydrogen atom, at least one of R₁₀₅ or R₁₀₆ represents an alkenyl group; when R₁₀₄ and R₁₀₅ are methyl groups and two among R₁₀₄ to R₁₀₆ are not linked together, R₁₀₆ represents a substituent other than a methyl group and an ethyl group,

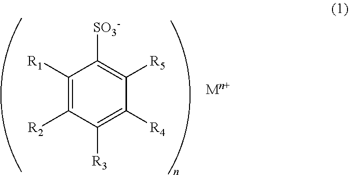

in the general formula (1), R₁ and R₅ each independently represent an aryl group or a heteroaryl group, R₂ to R₄ each independently represent a hydrogen atom or a substituent, Mⁿ⁺ represents a cation, and n represents an integer of 1 or more.
   [2]

The actinic ray-sensitive or radiation-sensitive resin composition according to [1], wherein, in the general formula (1), R₃ represents an aryl group.

[3]

The actinic ray-sensitive or radiation-sensitive resin composition according to [1] or [2], wherein, in the general formula (1), at least one of R₁ to R₅ is a group including a polar group, a group including a group that is decomposed by an action of an acid to provide increased polarity, or a group including a group that is decomposed by an action of an alkali developer to provide an increased degree of solubility in the alkali developer.

[4]

The actinic ray-sensitive or radiation-sensitive resin composition according to any one of [1] to [3], wherein, in the general formula (1), R₁, R₃, and R₅ are each a group represented by a general formula (Ar) below:

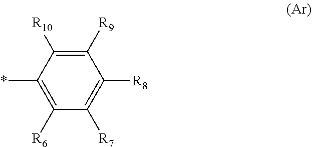

in the general formula (Ar), R₆ to R₁₀ each independently represent a hydrogen atom or a substituent; at least one of R₆ to R₁₀ is a group including a polar group, a group including a group that is decomposed by an action of an acid to provide increased polarity, or a group including a group that is decomposed by an action of an alkali developer to provide an increased degree of solubility in the alkali developer; and * represents a direct bond to the benzene ring in the general formula (1).
   [5]

The actinic ray-sensitive or radiation-sensitive resin composition according to any one of [1] to [3], wherein, in the general formula (1), R₁, R₃, and R₅ are each a group represented by a general formula (Ar1) below:

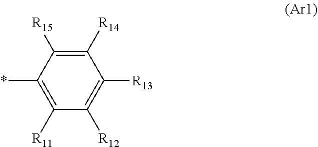

in the general formula (Ar1), R₁₁ to R₁₅ each independently represent a hydrogen atom or a substituent, and at least one of R₁₁ to R₁₅ represents a substituent Y below; and * represents a direct bond to the benzene ring in the general formula (1),

Substituent Y: a hydroxy group, a carboxyl group, a group having a carbonyl bond, an acyloxy group, an alkoxycarbonyloxy group, an aryloxycarbonyloxy group, an aryloxycarbonyl group, an alkoxycarbonyl group, a carbamoyl group, or an imide group.

[6]

The actinic ray-sensitive or radiation-sensitive resin composition according to any one of [1] to [5], wherein the acid generated from the compound (B) upon irradiation with an actinic ray or a radiation has a pKa of −10 or more and 5 or less.

[7]

The actinic ray-sensitive or radiation-sensitive resin composition according to any one of [1] to [6], wherein L₁₀₁ in the general formula (a) is a phenylene group.

[8]

The actinic ray-sensitive or radiation-sensitive resin composition according to any one of [1] to [7], wherein a total number of carbon atoms included in R₁₀₄ to R₁₀₆ in the general formula (a) is 5 to 9.

[9]

The actinic ray-sensitive or radiation-sensitive resin composition according to any one of [1] to [7], wherein a total number of carbon atoms included in R₁₀₄ to R₁₀₆ in the general formula (a) is 10 to 16.

[10]

The actinic ray-sensitive or radiation-sensitive resin composition according to any one of [1] to [9], wherein at least one of R₁₀₄ to R₁₀₆ in the general formula (a) represents a group having a cyclic group.

[11]

The actinic ray-sensitive or radiation-sensitive resin composition according to any one of [1] to [10], wherein two among R₁₀₄ to R₁₀₆ in the general formula (a) are linked together to form a ring.

[12]

The actinic ray-sensitive or radiation-sensitive resin composition according to any one of [1] to [11], wherein the resin (A) further includes a repeating unit (c) represented by a general formula (c) below:

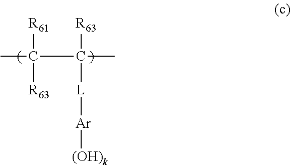

in the general formula (c), R₆₁ to R₆₃ each independently represent a hydrogen atom, an organic group, or a halogen atom, with the proviso that R₆₂ may be bonded to Ar to form a ring, and, in this case, R₆₂ represents a single bond or an alkylene group; L represents a single bond or a divalent linking group; Ar represents a (k+1) valent aromatic ring group and, when Ar is bonded to R₆₂ to form a ring, Ar represents a (k+2) valent aromatic ring group; and k represents an integer of 1 to 5.
   [13]

The actinic ray-sensitive or radiation-sensitive resin composition according to [12], wherein L in the general formula (c) is a single bond.

[14]

The actinic ray-sensitive or radiation-sensitive resin composition according to [12] or [13], wherein Ar in the general formula (c) is a phenylene group.

[15]

The actinic ray-sensitive or radiation-sensitive resin composition according to any one of [1] to [14], wherein a content of the repeating unit (a) is 10 mass % or more relative to a total mass of the resin (A).

[16]

The actinic ray-sensitive or radiation-sensitive resin composition according to any one of [1] to [15], wherein a mass ratio (repeating unit (a)/compound (B)) of the repeating unit (a) included in the resin (A) to the compound (B), the resin (A) and the compound (B) being included in the actinic ray-sensitive or radiation-sensitive resin composition, is 0.75 or more.

[17]

An actinic ray-sensitive or radiation-sensitive film formed from the actinic ray-sensitive or radiation-sensitive resin composition according to any one of [1] to [16].

[18]

A pattern forming method including:
an actinic ray-sensitive or radiation-sensitive film-forming step of forming an actinic ray-sensitive or radiation-sensitive film from the actinic ray-sensitive or radiation-sensitive resin composition according to any one of [1] to [16];
an exposure step of exposing the actinic ray-sensitive or radiation-sensitive film; and
a development step of developing the exposed actinic ray-sensitive or radiation-sensitive film using a developer.
   [19]

A method for producing an electronic device, the method including the pattern forming method according to [18].

The present invention can provide an actinic ray-sensitive or radiation-sensitive resin composition that has high resolution and high roughness performance, can provide an excellent pattern profile, and can achieve reduction in development defects in the formation of an ultrafine pattern (having, in particular, a line width or a space width of 20 nm or less), and an actinic ray-sensitive or radiation-sensitive film, a pattern forming method, and a method for producing an electronic device that use the composition.

### DESCRIPTION OF THE PREFERRED EMBODIMENTS

Hereinafter, the present invention will be described in detail.

In the following descriptions, features may be described on the basis of representative embodiments of the present invention; however, the present invention is not limited to such embodiments.

In this Specification, “actinic ray” or “radiation” means, for example, a line spectrum of a mercury lamp, far ultraviolet rays represented by excimer lasers, extreme ultraviolet rays (EUV: Extreme Ultraviolet), X-rays, soft X-rays, an electron beam (EB: Electron Beam), or the like. In this Specification, “light” means an actinic ray or a radiation. In this Specification, “exposure” includes not only exposure using a line spectrum of a mercury lamp, far ultraviolet rays represented by excimer lasers, extreme ultraviolet rays, X-rays, EUV, or the like, but also drawing using a corpuscular beam such as an electron beam or an ion beam, unless otherwise specified.

In this Specification, “a value ‘to’ another value” is used to mean that it includes the value and the other value as the lower limit value and the upper limit value.

In this Specification, (meth)acrylate represents at least one of acrylate or methacrylate. (Meth)acrylic acid represents at least one of acrylic acid or methacrylic acid.

In this Specification, for resins, the weight-average molecular weight (Mw), the number-average molecular weight (Mn), and the dispersity (also referred to as molecular weight distribution) (Mw/Mn) are defined as polystyrene-equivalent values measured, using a GPC (Gel Permeation Chromatography) apparatus (HLC-8120GPC, manufactured by Tosoh Corporation), by GPC measurement (solvent: tetrahydrofuran, flow rate (sample injection amount): 10 μL, column: TSK gel Multipore HXL-M manufactured by Tosoh Corporation, column temperature: 40° C., flow rate: 1.0 mL/min, detector: differential refractive index detector (Refractive Index Detector)).

In this Specification, for the wording of groups (atomic groups), wording without referring to substituted or unsubstituted encompasses groups not having a substituent and groups having a substituent. For example, “alkyl groups” encompasses not only alkyl groups not having a substituent (unsubstituted alkyl groups), but also alkyl groups having a substituent (substituted alkyl groups). In this Specification, “organic group” refers to a group including at least one carbon atom.

In this Specification, the bonding directions of divalent groups described are not limited unless otherwise specified. For example, in a compound represented by a formula “X—Y—Z” where Y is —COO—, Y may be —CO—O— or —O—CO—. In other words, the compound may be “X—CO—O—Z” or “X—O—CO—Z”.

In this Specification, the acid dissociation constant (pKa) represents pKa in an aqueous solution, specifically, a value determined using the following Software package 1, on the basis of the Hammett's substituent constant and the database of values in publicly known documents, by calculation. All the values of pKa described in this Specification are values determined by calculation using this software package.

Software package 1: Advanced Chemistry Development (ACD/Labs) Software V8.14 for Solaris (1994-2007 ACD/Labs)

Alternatively, pKa can be determined by a molecular orbital calculation method. Specifically, this method may be a calculation method of calculating H⁺ dissociation free energy in an aqueous solution based on a thermodynamic cycle. The H⁺ dissociation free energy can be calculated by a method such as DFT (density functional theory); however, the calculation method is not limited thereto and various other methods have been reported in documents and the like. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density functional theory) using Gaussian 16 is employed.

In this Specification, pKa refers to “pKa in an aqueous solution” as described above, but when pKa in an aqueous solution cannot be determined, “pKa in a dimethyl sulfoxide (DMSO) solution” is employed.

Actinic ray-sensitive or radiation-sensitive resin composition

An actinic ray-sensitive or radiation-sensitive resin composition according to the present invention (hereinafter, also referred to as “composition of the present invention”) is an actinic ray-sensitive or radiation-sensitive resin composition containing (A) and (B) below: (A) a resin containing a repeating unit (a) having a group that is decomposed by an action of an acid to generate a carboxylic acid and represented by a general formula (a) below, and (B) a compound that generates an acid upon irradiation with an actinic ray or a radiation and is represented by a general formula (1) below,

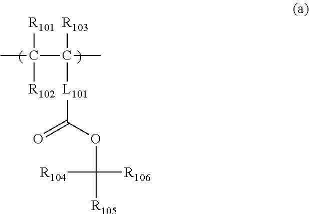

in the general formula (a), R₁₀₁ to R₁₀₃ each independently represent a hydrogen atom, an organic group, or a halogen atom; L₁₀₁ represents a divalent aromatic ring group; two among R₁₀₄ to R₁₀₆ each independently represent a hydrogen atom, an alkyl group, a cycloalkyl group, an aryl group, an alkenyl group, or an alkynyl group; R₁₀₄ to R₁₀₆ may be linked together to form a ring; when R₁₀₄ is a hydrogen atom, at least one of R₁₀₅ or R₁₀₆ represents an alkenyl group; when R₁₀₄ and R₁₀₅ are methyl groups and two among R₁₀₄ to R₁₀₆ are not linked together, R₁₀₆ represents a substituent other than a methyl group and an ethyl group,

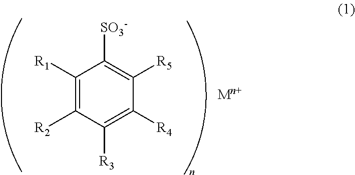

In the general formula (1), R₁ and R₅ each independently represent an aryl group or a heteroaryl group; R₂ to R₄ each independently represent a hydrogen atom or a substituent; Mⁿ⁺ represents a cation; and n represents an integer of 1 or more.

In the present invention, use of the combination of the above-described (A) resin containing a repeating unit (a) having a group that is decomposed by the action of an acid to generate a carboxylic acid and represented by the general formula (a) (also referred to as “resin (A)”) and the above-described (B) compound that generates an acid upon irradiation with an actinic ray or a radiation and is represented by the general formula (1) below (also referred to as “compound (B)” or “photoacid generator (B)”), can provide, as described above, an actinic ray-sensitive or radiation-sensitive resin composition that can provide, in the formation of an ultrafine pattern (in particular, having a line width or space width of 20 nm or less), high resolution, high roughness performance, and an excellent pattern profile, and can achieve reduction in development defects.

The reason for this has not been clarified, but is inferred as follows.

First, for the acid generated from the compound (B) upon irradiation with an actinic ray or a radiation, in the general formula (1), R₁ and R₅ each independently represent an aryl group or a heteroaryl group. R₁ and R₅ are respectively at the 2- and 6-positions with respect to the carbon atom bonded to the sulfonate anion, and thus can be said as being at positions adjacent to the sulfonate anion. Further, the aryl group or the heteroaryl group is a bulky and rigid group. Therefore, compared with a case where hydrogen atoms or bulky but flexible groups (for example, cycloalkyl groups) are at the positions corresponding to R₁ and R₅, R₁ and R₅ in the general formula (1) inferentially have a high steric hindrance function against the sulfonate anion. As a result, the acid generated in the exposed regions from such a compound (B) having a sulfonate anion is less likely to excessively diffuse into the unexposed regions, which inferentially contributes to improvement in the resolving power.

In general, when a bulky group is introduced into an acid generator, for example, the acid generator has increased hydrophobicity, so that development defects due to development scum may be likely to occur during alkaline development.

However, in the case of using the compound (B) of the present invention in which R₁ and R₅ are each an aryl group or a heteroaryl group, surprisingly, the development defects due to development scum are further suppressed, compared with the case of using an acid generator or the like in which R₁ and R₅ are both replaced by cycloalkyl groups, which are bulky. The reason for this has not been specifically clarified; however, the C log P value of the aryl group or the heteroaryl group is lower than the C log P value of the cycloalkyl group, so that the compound (B) of the present invention has a high affinity for a developer (preferably an alkali developer), and hence, in spite of the presence of the aryl group or the heteroaryl group serving as bulky groups, the development defects due to development scum are inferentially suppressed.

Furthermore, the repeating unit (a) in the resin (A) and the compound (B) described above have an aryl group and polar groups such as an ester bond and a sulfonate anion, hence the π-π interaction and the action of hydrogen bonds provide high compatibility, and the resin (A) and the compound (B) are inferentially distributed with high uniformity in the actinic ray-sensitive or radiation-sensitive film. Therefore, an aggregate of the compound (B) is less likely to be generated in the film, so that development defects due to development scum are inferentially suppressed.

The acid generated from the compound (B) upon irradiation with an actinic ray or a radiation is a sulfonic acid directly bonded to a benzene ring and hence, in general, the acid strength thereof is not very high; thus, in order to cause the reaction of the resin in the exposed regions to proceed with certainty, the above-described resin having high reactivity to the sulfonic acid (decomposability by the action of the acid) is desirably used.

In the resin (A) in the present invention, the group represented by —COO(R₁₀₄)(R₁₀₅)(R₁₀₆) in the acid decomposable group is bonded to the main chain of the resin via a divalent aromatic ring group serving as L₁₀₁ and being a rigid group, and hence, compared with a case where the group is bonded to the main chain of the resin not via such a linking group or via a linking group having a flexible structure, the molecule has low mobility and the diffusion of the acid can be suppressed.

Because of the feature “when R₁₀₄ and R₁₀₅ are methyl groups and two among R₁₀₄ to R₁₀₆ are not linked together, R₁₀₆ represents a substituent other than a methyl group and an ethyl group”, the compound that leaves from —COO(R₁₀₄)(R₁₀₅)(R₁₀₆) by the action of an acid and is derived from R₁₀₄, R₁₀₅, and R₁₀₆ is a compound having a relatively large size. Such a feature results in stabilization of the reaction intermediate generated by the deprotection (leaving) reaction, and hence the decomposition reaction in —COO(R₁₀₄)(R₁₀₅)(R₁₀₆) by an acid easily proceeds.

As has been described so far, in the composition of the present invention, the decomposition reaction of the resin by an acid tends to occur with certainty in the exposed regions, which inferentially results in great contribution to improvements in resolution, roughness performance, and pattern profile.

Furthermore, the repeating unit (a) in the resin (A) and the compound (B) described above have an aryl group and polar groups such as an ester bond and a sulfonate anion, hence the π-π interaction and the action of hydrogen bonds provide high compatibility, and the resin (A) and the compound (B) are inferentially distributed with high uniformity in the actinic ray-sensitive or radiation-sensitive film. In particular, in the compound (B), not only the benzene ring directly bonded to the sulfonate anion, but also the aryl group or heteroaryl group serving as R₁ and R₅ exerts the π-π interaction with, for example, the aromatic ring group serving as L₁₀₁ in the repeating unit (a), and hence the compatibility between the resin (A) and the compound (B) is inferentially very high. As a result, the reaction between the resin (A) and the acid in the exposed regions tends to proceed uniformly in the film, and pattern defects due to separation between the resin (A) and the compound (B) are extremely unlikely to occur inferentially.

As has been described so far, in the formation of an ultrafine pattern (having, in particular, a line width or a space width of 20 nm or less), high resolution and high roughness performance are provided and an excellent pattern profile and reduction in development defects are achieved inferentially.

The actinic ray-sensitive or radiation-sensitive resin composition of the present invention (also referred to as the composition of the present invention) is preferably a resist composition, and may be a positive resist composition or a negative resist composition. The resist composition may be a resist composition for alkaline development or a resist composition for organic solvent development. In particular, the resist composition is preferably a positive resist composition and a resist composition for alkaline development.

Further, the composition of the present invention is preferably a chemical amplification resist composition, and more preferably a chemical amplification positive resist composition.

(A) Resin Having Repeating Unit (a) Having Group that is Decomposed by Action of Acid to Generate Carboxylic Acid and Represented by General Formula (a)

(A) The resin having a repeating unit (a) having a group that is decomposed by the action of an acid to generate a carboxylic acid and represented by the general formula (a) (also referred to as “resin (A)”) will be described.

The resin (A) preferably has a repeating unit having a group that is decomposed by the action of an acid to generate an acid to provide increased polarity (hereinafter, also referred to as “acid decomposable group”), and is preferably a resin having a repeating unit having an acid decomposable group (hereinafter, also referred to as “acid decomposable resin”).

The resin (A) is a resin containing a repeating unit (a) having a group that is decomposed by the action of an acid to generate a carboxylic acid to provide increased polarity and represented by the general formula (a) and is an acid decomposable resin.

The resin (A) is preferably a resin whose solubility in a developer is changed by the action of an acid.

The resin whose solubility in a developer is changed by the action of an acid may be a resin whose solubility in a developer is increased by the action of an acid or may be a resin whose solubility in a developer is decreased by the action of an acid.

The resin (A) has a group that is decomposed by the action of an acid to generate a carboxylic acid, so that, in a pattern forming method of the present invention, typically, when the developer is an alkali developer, a positive-type pattern is suitably formed, or when the developer is an organic-based developer, a negative-type pattern is suitably formed.

### Repeating Unit (a)

The repeating unit (a) is a repeating unit having a group that is decomposed by the action of an acid to generate a carboxylic acid and is represented by a general formula (a) below.

The repeating unit (a) is also referred to as “repeating unit having an acid decomposable group”.

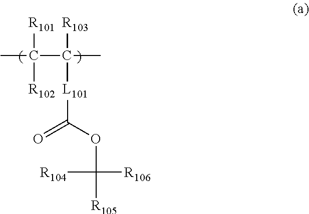

In the general formula (a), R₁₀₁ to R₁₀₃ each independently represent a hydrogen atom, an organic group, or a halogen atom. L₁₀₁ represents a divalent aromatic ring group. R₁₀₄ to R₁₀₆ each independently represent a hydrogen atom, an alkyl group, a cycloalkyl group, an aryl group, an alkenyl group, or an alkynyl group. Two among R₁₀₄ to R₁₀₆ may be linked together to form a ring. When R₁₀₄ is a hydrogen atom, at least one of R₁₀₅ or R₁₀₆ represents an alkenyl group. When R₁₀₄ and R₁₀₅ are methyl groups and two among R₁₀₄ to R₁₀₆ are not linked together, R₁₀₆ represents a substituent other than a methyl group and an ethyl group.

In the general formula (a), R₁₀₁ to R₁₀₃ each independently represent a hydrogen atom, an organic group, or a halogen atom.

Examples of the organic group represented by R₁₀₁ to R₁₀₃ include an alkyl group and a cycloalkyl group.

The alkyl group may be linear or branched. The number of carbon atoms of the alkyl group is not particularly limited, but is preferably 1 to 10, more preferably 1 to 3.

The cycloalkyl group may be monocyclic or polycyclic. The cycloalkyl group preferably has 3 to 8 carbon atoms.

Examples of the halogen atoms represented by R₁₀₁ to R₁₀₃ include a fluorine atom, a chlorine atom, a bromine atom, and an iodine atom.

In the general formula (a), R₁₀₁ to R₁₀₃ are each independently preferably a hydrogen atom or an alkyl group, more preferably R₁₀₁ and R₁₀₂ are hydrogen atoms and R₁₀₃ is a hydrogen atom or a methyl group, and still more preferably R₁₀₁ to R₁₀₃ are hydrogen atoms.

In the general formula (a), L₁₀₁ represents a divalent aromatic ring group.

Examples of the divalent aromatic ring group represented by L₁₀₁ include an arylene group and a heteroarylene group.

Examples of the arylene group serving as L₁₀₁ include an arylene group having 6 to 15 carbon atoms, and specific preferred examples thereof include a phenylene group, a naphthylene group, and an anthrylene group.

Examples of the heteroarylene group serving as L₁₀₁ include a heteroarylene group having 2 to 15 carbon atoms and having a 5- to 10-membered ring; specific examples thereof include a group provided by removing any one of hydrogen atoms from a furyl group, a thienyl group, a thiazolyl group, a pyrrolyl group, an oxazolyl group, a pyridyl group, a benzofuranyl group, a benzothienyl group, a quinolinyl group, a carbazolyl group, or the like.

The divalent aromatic ring group represented by L₁₀₁ may further have a substituent, and examples thereof include halogen atoms.

In a preferred embodiment, the divalent aromatic ring group represented by L₁₀₁ may further have a group represented by —C(═O)O—C(R₁₀₄)(R₁₀₅)(R₁₀₆) as a substituent. The divalent aromatic ring group represented by L₁₀₁ may further have two or more substituents.

L₁₀₁ is preferably an arylene group, and more preferably a phenylene group.

R₁₀₄ to R₁₀₆ each independently represent a hydrogen atom, an alkyl group, a cycloalkyl group, an aryl group, an alkenyl group, or an alkynyl group. R₁₀₄ to R₁₀₆ may be linked together to form a ring. When R₁₀₄ is a hydrogen atom, at least one of R₁₀₅ or R₁₀₆ represents an alkenyl group. When R₁₀₄ and R₁₀₅ are methyl groups and two among R₁₀₄ to R₁₀₆ are not linked together, R₁₀₆ represents a substituent other than a methyl group and an ethyl group.

Examples of the alkyl groups represented by R₁₀₄ to R₁₀₆ include an alkyl group that may be linear or branched and has 1 to 8 carbon atoms, and preferred are alkyl groups having 1 to 4 carbon atoms such as a methyl group, an ethyl group, an n-propyl group, an isopropyl group, an n-butyl group, an isobutyl group, and a t-butyl group.

Examples of the cycloalkyl groups represented by R₁₀₄ to R₁₀₆ include a monocyclic or polycyclic cycloalkyl group having 3 to 10 carbon atoms, preferred is a monocyclic cycloalkyl group having 4 to 6 carbon atoms, and preferred is a cyclopentyl group or a cyclohexyl group.

Examples of the aryl groups represented by R₁₀₄ to R₁₀₆ include an aryl group having 6 to 15 carbon atoms such as a phenyl group and a naphthyl group.

Examples of the alkenyl groups represented by R₁₀₄ to R₁₀₆ include an alkenyl group having 2 to 6 carbon atoms, and preferred are alkenyl groups having 2 to 4 carbon atoms such as a vinyl group, a 1-methylvinyl group, a 1-propenyl group, an allyl group, and a 2-methyl-1-propenyl group.

Examples of the alkynyl groups represented by R₁₀₄ to R₁₀₆ include an alkynyl group having 2 to 6 carbon atoms.

When R₁₀₄ to R₁₀₆ are linked together to form a ring, two among R₁₀₄ to R₁₀₆ are preferably bonded together to form a cycloalkyl group or a cycloalkenyl group.

Examples of the cycloalkyl group formed by bonding together two among R₁₀₄ to R₁₀₆ include a monocyclic or polycyclic cycloalkyl group having 3 to 10 carbon atoms; preferred are monocyclic cycloalkyl groups such as a cyclopentyl group and a cyclohexyl group and, in addition, preferred are polycyclic cycloalkyl groups such as a norbornyl group, a tetracyclodecanyl group, a tetracyclododecanyl group, and an adamantyl group. Of these, preferred is a monocyclic cycloalkyl group having 5 to 6 carbon atoms.

Examples of the cycloalkenyl group formed by bonding together two among R₁₀₄ to R₁₀₆ include a monocyclic or polycyclic cycloalkenyl group having 3 to 10 carbon atoms, and, of these, preferred is a monocyclic cycloalkenyl group having 5 to 6 carbon atoms.

The substituents represented by R₁₀₄ to R₁₀₆ may be further substituted with an organic group. The number of heteroatoms included in the organic group is preferably 0 to 1.

In a case where each group of the substituents represented by R₁₀₄ to R₁₀₆ is substituted with an organic group, examples of the organic group include an alkyl group (having 1 to 4 carbon atoms), an alkoxy group (having 1 to 4 carbon atoms), and an aryl group (having 6 to 10 carbon atoms). One of methylene groups in the substituents represented by R₁₀₄ to R₁₀₆ may be replaced by a group having a heteroatom such as a carbonyl group.

In the cycloalkyl group or cycloalkenyl group formed by bonding together two among R₁₀₄ to R₁₀₆, for example, one of the methylene groups constituting the ring may be replaced by a heteroatom such as an oxygen atom or a sulfur atom, or a group having a heteroatom such as a carbonyl group.

The total number of heteroatoms included in R₁₀₄ to R₁₀₆ is more preferably 0 to 1.

The number of carbon atoms included in each group of R₁₀₄ to R₁₀₆ is preferably 1 to 7.

When R₁₀₄ and R₁₀₅ are methyl groups and two among R₁₀₄ to R₁₀₆ are not linked together, R₁₀₆ represents a substituent other than a methyl group and an ethyl group. When R₁₀₄ and R₁₀₅ are methyl groups, two among R₁₀₄ to R₁₀₆ are not linked together, and R₁₀₆ represents a methyl group or an ethyl group, the reactivity of the deprotection reaction of the acid decomposable group in the resin (A) by the acid generated from the compound (B) described later may not be sufficiently provided.

The total number of carbon atoms included in R₁₀₄ to R₁₀₆ is more preferably 5 or more from the viewpoint of ensuring reactivity to the acid generated from the compound (B).

The total number of carbon atoms included in R₁₀₄ to R₁₀₆ is not particularly limited, but is preferably 9 or less, and more preferably 7 or less. When the total number of carbon atoms is set to 9 or less, the leaving product having left from the resin (A) by the acid generated from the compound (B) described later is less likely to remain in the actinic ray-sensitive or radiation-sensitive film, which results in further improvement in the resolving power.

The total number of carbon atoms included in R₁₀₄ to R₁₀₆ is preferably 5 to 9, and more preferably 5 to 7.

In a preferred embodiment, the total number of carbon atoms included in R₁₀₄ to R₁₀₆ is preferably 10 to 16, and more preferably 10 to 12.

When the total number of carbon atoms is set to 10 to 16, the resin (A) is likely to become rigid, the actinic ray-sensitive or radiation-sensitive film becomes hard, and the acid generated in exposed regions is less likely to diffuse to unexposed regions, which inferentially results in further improvement in the resolving power.

In a preferred embodiment, at least one of R₁₀₄ to R₁₀₆ preferably represents a group having a cyclic group.

The cyclic group is not particularly limited as long as it is a group forming a ring, and examples thereof include a cycloalkyl group and an aryl group.

The phrase “at least one of R₁₀₄ to R₁₀₆ represents a group having a cyclic group” specifically includes the following embodiment.

An embodiment in which at least one of R₁₀₄ to R₁₀₆ represents an alkyl group, an alkenyl group, or an alkynyl group, the alkyl group, the alkenyl group, or the alkynyl group has a substituent, and the substituent has a cycloalkyl group or an aryl group.

The alkyl group may be linear or branched. Examples include an alkyl group having 1 to 8 carbon atoms and preferred are alkyl groups having 1 to 4 carbon atoms such as a methyl group, an ethyl group, an n-propyl group, an isopropyl group, an n-butyl group, an isobutyl group, and a t-butyl group.

Examples of the alkenyl group include an alkenyl group having 2 to 6 carbon atoms, and preferred are alkenyl groups having 2 to 4 carbon atoms such as a vinyl group, a 1-methylvinyl group, a 1-propenyl group, an allyl group, and a 2-methyl-1-propenyl group.

Examples of the alkynyl group include an alkynyl group having 2 to 6 carbon atoms.

The cycloalkyl group serving as the substituent may be a monocyclic or polycyclic cycloalkyl group having 3 to 10 carbon atoms, is preferably a monocyclic cycloalkyl group having 4 to 6 carbon atoms, and is preferably a cyclopentyl group or a cyclohexyl group.

Examples of the aryl group serving as the substituent include an aryl group having 6 to 15 carbon atoms such as a phenyl group or a naphthyl group.

The group having a cyclic group may be a cyclic group itself. In this case, examples of the group having a cyclic group include a cycloalkyl group and an aryl group.

Examples of the cycloalkyl group include the same cycloalkyl groups as those described above as the substituent, and examples of the aryl group include the same aryl groups as those described above as the substituent.

The cycloalkyl group and the aryl group may further have a substituent.

As described above, two among R₁₀₄ to R₁₀₆ may be linked together to form a ring, and, in a preferred embodiment, two among R₁₀₄ to R₁₀₆ are preferably linked together to form a ring.

In the repeating unit (a), R₁₀₄ to R₁₀₆ preferably each independently represent an alkyl group or an alkenyl group. Two among R₁₀₄ to R₁₀₆ may be linked together to form a ring. When R₁₀₄ and R₁₀₅ are methyl groups and two among R₁₀₄ to R₁₀₆ are not linked together, R₁₀₆ represents a substituent other than a methyl group and an ethyl group.

For R₁₀₄ to R₁₀₆, for example, in a preferred embodiment, R₁₀₄ is an alkyl group or an alkenyl group, and R₁₀₅ and R₁₀₆ are bonded together to form a cyclopentyl group or a cyclohexyl group; in a more preferred embodiment, R₁₀₄ is an alkyl group or an alkenyl group having 1 to 3 carbon atoms, and R₁₀₅ and R₁₀₆ are bonded together to form a cyclopentyl group.

In another preferred embodiment of R₁₀₄ to R₁₀₆, R₁₀₄ and R₁₀₅ are preferably alkyl groups having 1 to 3 carbon atoms and R₁₀₆ is preferably an alkenyl group having 2 to 3 carbon atoms.

The repeating unit represented by the general formula (a) is preferably a repeating unit represented by the following general formula (a-1).

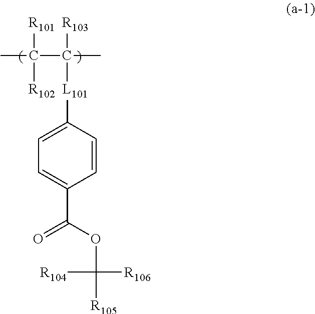

In the general formula (a-1), R₁₀₁ to R₁₀₃ each independently represent a hydrogen atom, an organic group, or a halogen atom. R₁₀₄ to R₁₀₆ each independently represent a hydrogen atom, an alkyl group, a cycloalkyl group, an aryl group, an alkenyl group, or an alkynyl group. R₁₀₄ to R₁₀₆ may be linked together to form a ring. When R₁₀₄ is a hydrogen atom, at least one of R₁₀₅ or R₁₀₆ represents an alkenyl group. When R₁₀₄ and R₁₀₅ are methyl groups and two among R₁₀₄ to R₁₀₆ are not linked together, R₁₀₆ represents a substituent other than a methyl group and an ethyl group.

R₁₀₁ to R₁₀₃ in the general formula (a-1) have the same meanings and preferred examples as R₁₀₁ to R₁₀₃ in the general formula (a).

R₁₀₄ to R₁₀₆ in the general formula (a-1) have the same meanings and preferred examples as R₁₀₄ to R₁₀₆ in the general formula (a).

Specific examples of the repeating unit (a) will be described below; however, the present invention is not limited thereto.

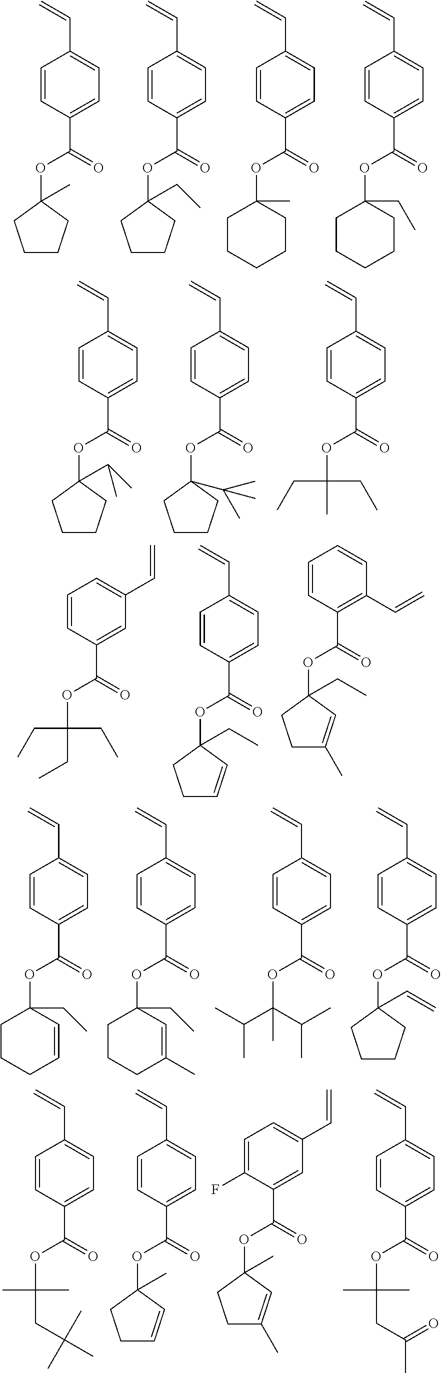

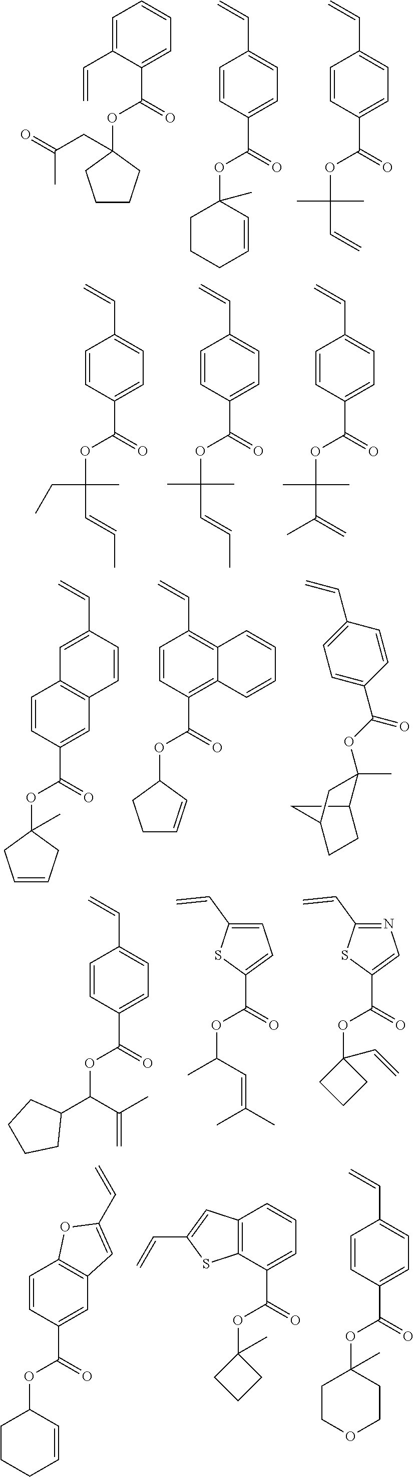

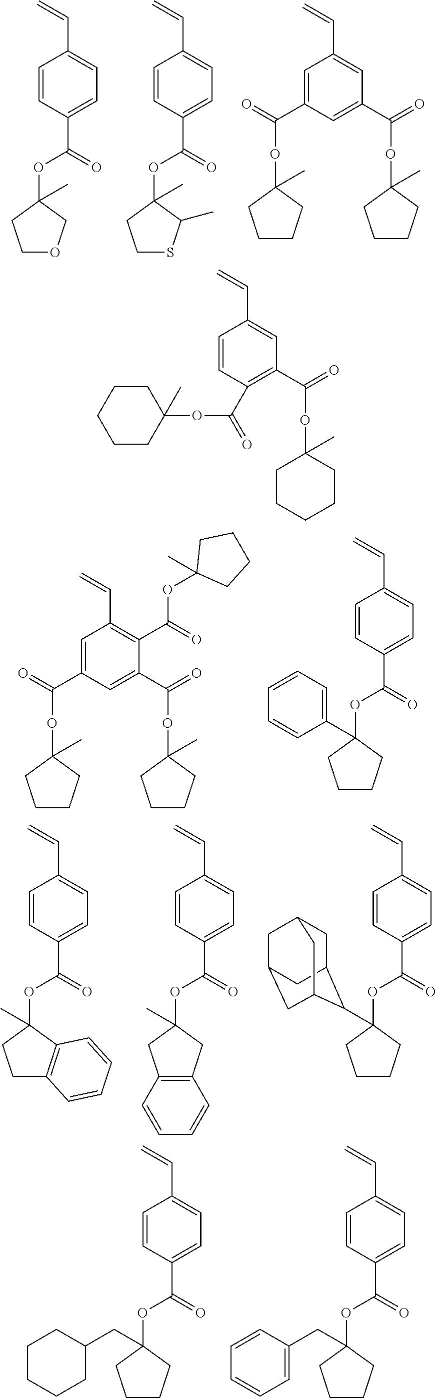

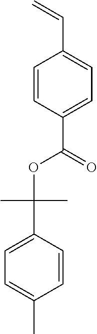

The resin (A) may include a single repeating unit (a) species alone, or may include two or more repeating unit (a) species in combination.

The content of the repeating unit (a) included in the resin (A) (in the case where a plurality of repeating units (a) are present, the total content thereof) is, relative to all the repeating units of the resin (A), preferably 15 mol % or more, more preferably 20 mol % or more, still more preferably 30 mol % or more. When the content is set to 15 mol % or more, advantages of the present invention are more likely to be provided.

The content of the repeating unit (a) included in the resin (A) (in the case where a plurality of repeating units (a) are present, the total content thereof) is, relative to all the repeating units of the resin (A), preferably 70 mol % or less, more preferably 60 mol % or less, and still more preferably 50 mol % or less.

The content of the repeating unit (a) included in the resin (A) (in the case where a plurality of repeating units (a) are present, the total content thereof) is, relative to the total mass of the resin (A), preferably 10 mass % or more, more preferably 20 mass % or more, and still more preferably 30 mass % or more. When the content is set to 10 mass % or more, advantages of the present invention are more likely to be provided.

The content of the repeating unit (a) included in the resin (A) (in the case where a plurality of repeating units (a) are present, the total content thereof) is, relative to the total mass of the resin (A), preferably 70 mass % or less, more preferably 60 mass % or less, and still more preferably 50 mass % or less.

In the composition of the present invention, the mass ratio (repeating unit (a)/compound (B)) of the repeating unit (a) included in the resin (A) to the compound (B) described later is preferably 0.75 or more, more preferably 1 or more, and still more preferably 2 or more. When the ratio is set to 0.75 or more, the number of aromatic ring groups included in the resin (A) and the number of aromatic ring groups included in the compound (B) become close to each other, so that the compatibility between the resin (A) and the compound (B) is further improved, and higher roughness performance and better pattern profiles are obtained, which is preferred.

The upper limit of the ratio is not particularly limited, but is preferably 10 or less, more preferably 8 or less, and still more preferably 6 or less.

The resin (A) may contain a repeating unit having an acid decomposable group other than the repeating unit (a) as long as advantages of the present invention are not impaired.

As the repeating unit having an acid decomposable group other than the repeating unit (a), a publicly known repeating unit can be appropriately used. Preferred examples include publicly known repeating units having an acid decomposable group in resins disclosed in paragraphs [0055] to [0191] of US2016/0274458A1, paragraphs [0035] to [0085] of US2015/0004544A1, and paragraphs [0045] to [0090] of US2016/0147150A1.

The content of the repeating unit having an acid decomposable group included in the resin (A) (in the case where a plurality of repeating units having an acid decomposable group are present, the total content thereof) is, relative to all the repeating units of the resin (A), preferably 10 to 90 mol %, more preferably 20 to 80 mol %, and still more preferably 30 to 70 mol %.

### Repeating Unit Having Acid Group

The resin (A) may have a repeating unit having an acid group.

The acid group is preferably an acid group having an acid dissociation constant (pKa) of 13 or less.

The acid group is particularly preferably a phenolic hydroxyl group.

The resin (A) preferably further has, in addition to the repeating unit (a), a repeating unit having a phenolic hydroxyl group.

The repeating unit having an acid group is preferably a repeating unit represented by a formula (B).

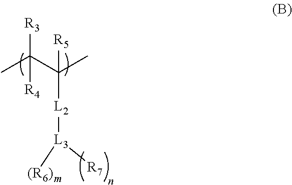

R₃ represents a hydrogen atom or a monovalent organic group.

The monovalent organic group is preferably a group represented by -L₄-R₈. L₄ represents a single bond or an ester group. Examples of R₈ include an alkyl group, a cycloalkyl group, an aryl group, and a group that is a combination of the foregoing.

R₄ and R₅ each independently represent a hydrogen atom, a halogen atom, or an alkyl group.

Examples of the halogen atom include a fluorine atom, a chlorine atom, a bromine atom, and an iodine atom.

L₂ represents a single bond or an ester group.

L₃ represents an (n+m+1) valent aromatic hydrocarbon ring group or an (n+m+1) valent alicyclic hydrocarbon ring group. Examples of the aromatic hydrocarbon ring group include a benzene ring group and a naphthalene ring group. The alicyclic hydrocarbon ring group may be monocyclic or polycyclic, and examples thereof include a cycloalkyl ring group.

R₆ represents a hydroxyl group or a fluorinated alcohol group (preferably a hexafluoroisopropanol group). When R₆ is a hydroxyl group, L₃ is preferably an (n+m+1) valent aromatic hydrocarbon ring group.

R₇ represents a halogen atom. Examples of the halogen atom include a fluorine atom, a chlorine atom, a bromine atom, and an iodine atom.

m represents an integer of 1 or more. m is preferably an integer of 1 to 3, and more preferably an integer of 1 to 2.

n represents 0 or an integer of 1 or more. n is preferably an integer of 1 to 4.

Note that (n+m+1) is preferably an integer of 1 to 5.

The repeating unit having an acid group is also preferably a repeating unit represented by a general formula (c) below (repeating unit (c)).

The resin (A) preferably further includes the repeating unit (c) represented by the following general formula (c).

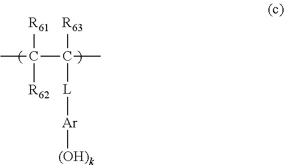

In the general formula (c), R₆₁ to R₆₃ each represent a hydrogen atom, an organic group, or a halogen atom. However, R₆₂ may be bonded to Ar to form a ring and, in this case, R₆₂ represents a single bond or an alkylene group. L represents a single bond or a divalent linking group. Ar represents a (k+1) valent aromatic ring group and, when Ar is bonded to R₆₂ to form a ring, Ar represents a (k+2) valent aromatic ring group. k represents an integer of 1 to 5.

In the general formula (c), R₆₁ to R₆₃ represent a hydrogen atom, an organic group, or a halogen atom.

Examples of the organic groups represented by R₆₁ to R₆₃ include alkyl groups, cycloalkyl groups, a cyano group, and alkoxycarbonyl groups.

The alkyl groups represented by R₆₁ to R₆₃ are preferably alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, more preferably alkyl groups having 8 or less carbon atoms, and still more preferably alkyl groups having 3 or less carbon atoms.

The cycloalkyl groups represented by R₆₁ to R₆₃ may be monocyclic or polycyclic. Of these, preferred are monocyclic cycloalkyl groups having 3 to 8 carbon atoms, such as a cyclopropyl group, a cyclopentyl group, and a cyclohexyl group.

The alkyl groups included in the alkoxycarbonyl groups represented by R₆₁ to R₆₃ are preferably the same as the above-described alkyl groups in R₆₁ to R₆₃.

In the case where R₆₂ is bonded to Ar to form a ring, the alkylene group of R₆₂ is preferably a group provided by removing any one hydrogen atom from the above-described alkyl groups of R₆₁ to R₆₃.

Examples of the halogen atoms represented by R₆₁ to R₆₃ include a fluorine atom, a chlorine atom, a bromine atom, and an iodine atom, and preferred is a fluorine atom.

Preferred examples of substituents for the above-described groups include alkyl groups, cycloalkyl groups, aryl groups, an amino group, an amide group, a ureido group, a urethane group, a hydroxyl group, a carboxyl group, halogen atoms, alkoxy groups, a thioether group, acyl groups, acyloxy groups, alkoxycarbonyl groups, a cyano group, and a nitro group. Such a substituent preferably has 8 or less carbon atoms.

In the general formula (c), Ar represents a (k+1) valent aromatic ring group. In a case where k is 1, the divalent aromatic ring group may have a substituent, and preferred examples thereof include arylene groups having 6 to 18 carbon atoms such as a phenylene group, a tolylene group, a naphthylene group, and an anthracenylene group, and aromatic ring groups including a heterocycle such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring.

In a case where k is an integer of 2 or more, specific examples of the (k+1) valent aromatic ring group include groups provided by removing any (k−1) hydrogen atoms from the above-described specific examples of the divalent aromatic ring group.

The (k+1) valent aromatic ring group may further have a substituent.

Examples of the substituent that the (k+1) valent aromatic ring group may have include halogen atoms, alkyl groups, cycloalkyl groups, aryl groups, alkenyl groups, aralkyl groups, alkoxy groups, alkylcarbonyloxy groups, alkylsulfonyloxy groups, alkyloxycarbonyl groups, and aryloxycarbonyl groups.

Ar is preferably an aromatic ring group having 6 to 18 carbon atoms, and more preferably a benzene ring group, a naphthalene ring group, or a biphenylene ring group.

The repeating unit represented by the general formula (c) preferably includes a hydroxystyrene structure. That is, Ar is preferably a benzene ring group, and more preferably a phenylene group (divalent benzene ring group).

In the general formula (c), L represents a single bond or a divalent linking group.

Examples of the divalent linking group represented by L include *—X₄-L₄-**.

In the above-described formula, X₄ represents a single bond, —COO—, or —CONR₆₄—, and R₆₄ represents a hydrogen atom or an alkyl group.

L₄ represents a single bond or an alkylene group.

* is a direct bond to a carbon atom of the main chain in the general formula (c), and ** is a direct bond to Ar.

In —CONR₆₄— (R₆₄ represents a hydrogen atom or an alkyl group) represented by X₄, examples of the alkyl group of R₆₄ include alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, and preferred are alkyl groups having 8 or less carbon atoms.

X₄ is preferably a single bond, —COO—, or —CONH—, and more preferably a single bond or —COO—.

The alkylene group in L₄ is preferably an alkylene group having 1 to 8 carbon atoms such as a methylene group, an ethylene group, a propylene group, a butylene group, a hexylene group, or an octylene group.

L is preferably a single bond, —COO—, or —CONH—, and more preferably a single bond.

In the general formula (c), k represents an integer of 1 to 5.

k is preferably an integer of 1 to 3, more preferably 1 or 2, and still more preferably 1.

The repeating unit having an acid group is preferably a repeating unit represented by the following general formula (1).

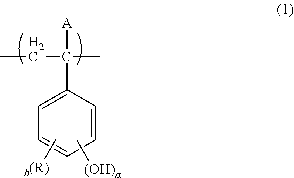

In the general formula (1),

A represents a hydrogen atom, an alkyl group, a cycloalkyl group, a halogen atom, or a cyano group.

R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group; when there are a plurality of R's, they may be the same or different. When there are a plurality of R's, they may together form a ring. R is preferably a hydrogen atom.

a represents an integer of 1 to 3.

b represents an integer of 0 to (3−a).

Specific examples of the repeating unit having an acid group will be described below; however, the present invention is not limited thereto. In the formulas, a represents an integer of 1 to 3.

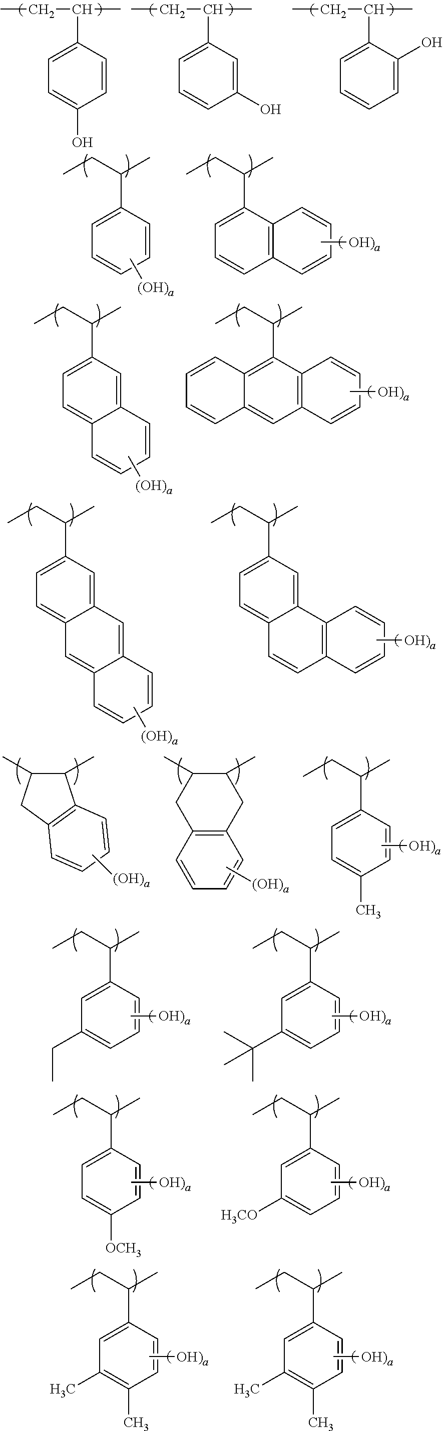

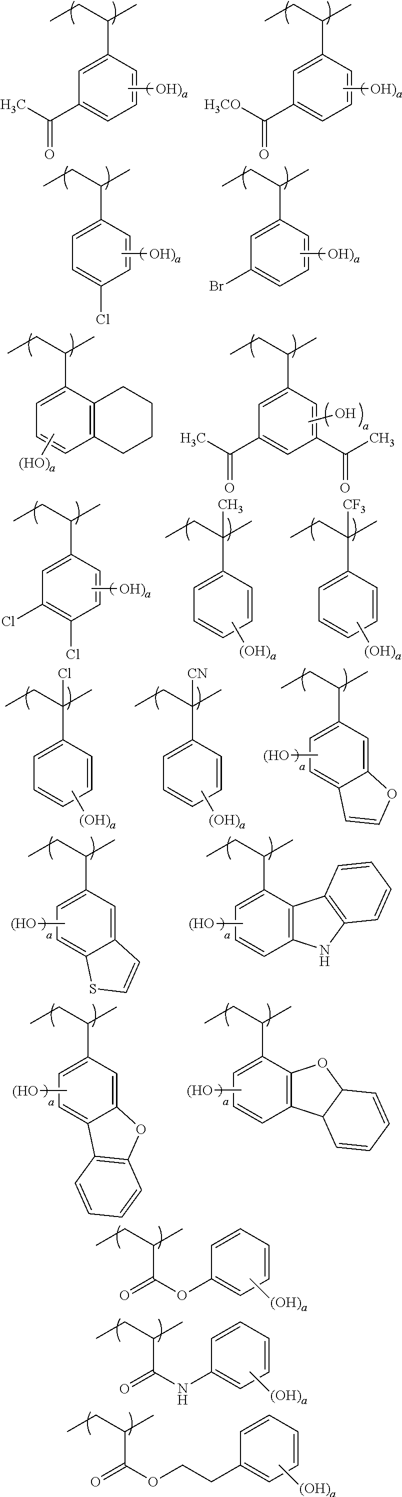

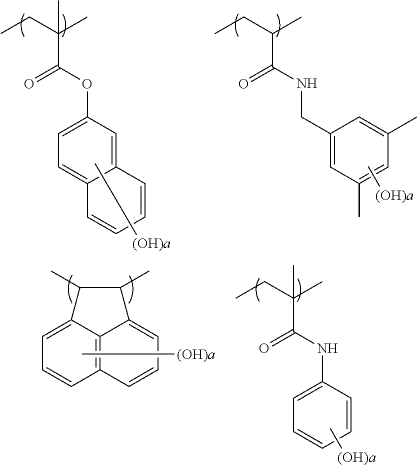

Note that, of the above-described repeating units, preferred are the following specific repeating units. In the formulas, R represents a hydrogen atom or a methyl group, and a represents 2 or 3.

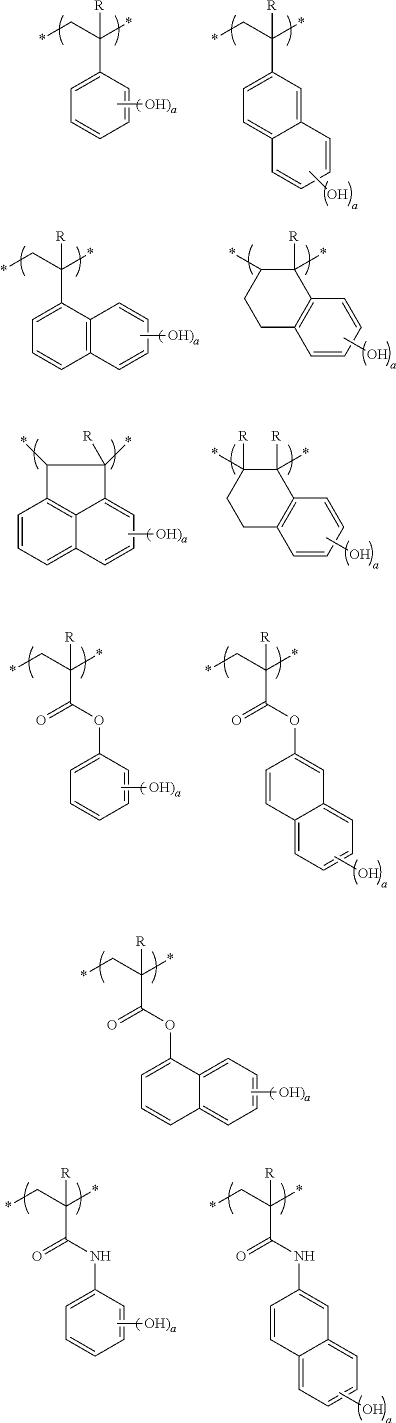

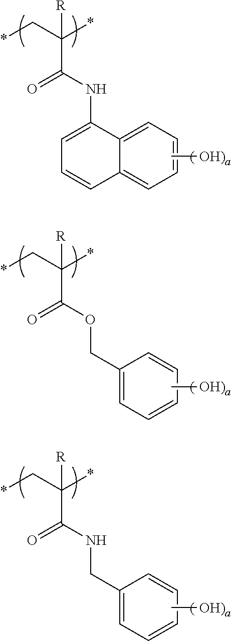

The content of the repeating unit having an acid group relative to all the repeating units in the resin (A) is preferably 10 to 80 mol %, more preferably 15 to 75 mol %, and still more preferably 20 to 70 mol %.

### Repeating Unit Having Lactone Group or Sultone Group

The resin (A) may further have a repeating unit having a lactone group or a sultone group.

The lactone group or the sultone group may be any group as long as it has a lactone structure or a sultone structure, but is preferably a group having a 5- to 7-membered lactone structure or a 5- to 7-membered sultone structure, and more preferably a group in which a 5- to 7-membered lactone structure is fused with another ring structure to form a bicyclo structure or a spiro structure, or a group in which a 5- to 7-membered sultone structure is fused with another ring structure to form a bicyclo structure or a spiro structure. The repeating unit more preferably has a group having a lactone structure represented by any one of the following general formulas (LC1-1) to (LC1-21) or a group having a sultone structure represented by any one of the following general formulas (SL1-1) to (SL1-3). A group having a lactone structure or a sultone structure may be directly bonded to the main chain. Preferred structures are groups represented by the general formula (LC1-1), the general formula (LC1-4), the general formula (LC1-5), the general formula (LC1-6), the general formula (LC1-13), or the general formula (LC1-14).

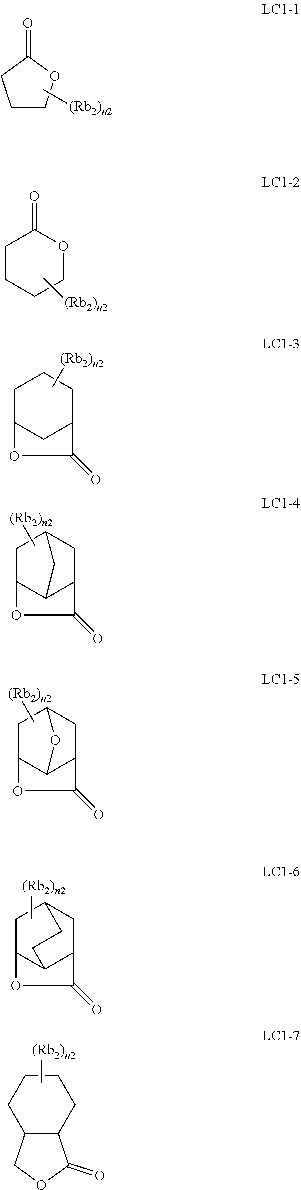

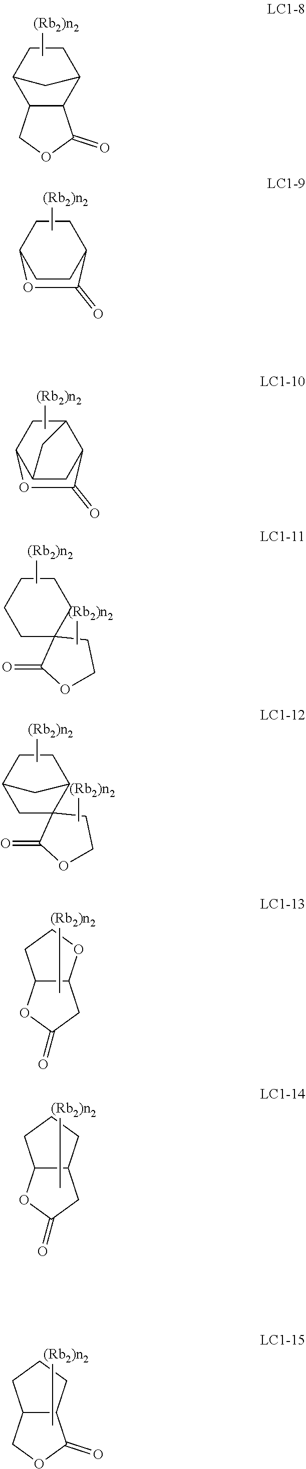

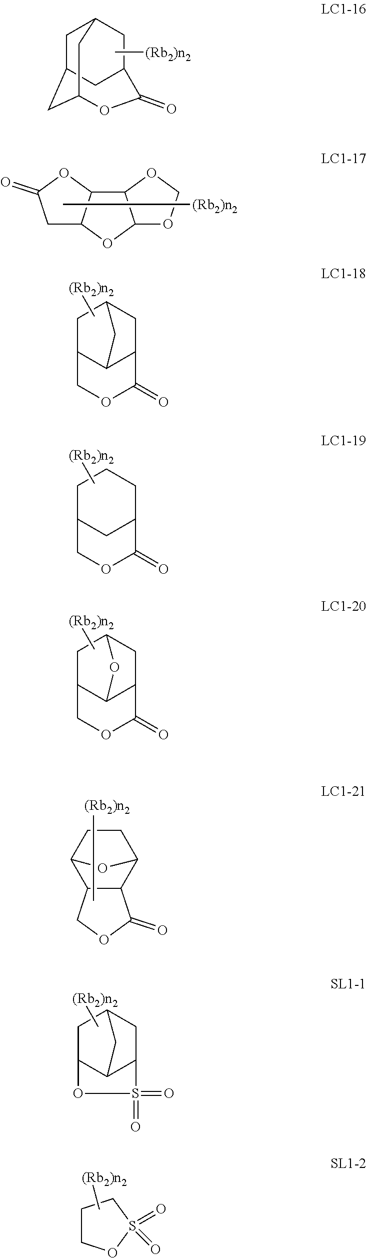

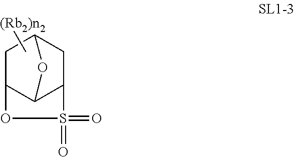

The lactone structure moiety or the sultone structure moiety may have a substituent (Rb₂). Preferred examples of the substituent (Rb₂) include alkyl groups having 1 to 8 carbon atoms, cycloalkyl groups having 4 to 7 carbon atoms, alkoxy groups having 1 to 8 carbon atoms, alkoxycarbonyl groups having 1 to 8 carbon atoms, a carboxyl group, halogen atoms, a hydroxyl group, a cyano group, and acid decomposable groups. n2 represents an integer of 0 to 4. When n2 is 2 or more, the plurality of Rb₂'s present may be different, or the plurality of Rb₂'s present may be linked together to form a ring.

Examples of the repeating unit having a group having a lactone structure or a sultone structure include a repeating unit represented by the following general formula (AI).

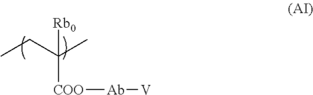

In the general formula (AI), Rb₀ represents a hydrogen atom, a halogen atom, or an alkyl group having 1 to 4 carbon atoms.

Preferred examples of the substituent that the alkyl group of Rb₀ may have include a hydroxyl group and halogen atoms.

Examples of the halogen atom of Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group that is a combination of the foregoing. Of these, preferred are a single bond and a linking group represented by -Ab₁-CO₂—. Ab₁ is a linear or branched alkylene group or a monocyclic or polycyclic cycloalkylene group, preferably a methylene group, an ethylene group, a cyclohexylene group, an adamantylene group, or a norbornylene group.

V represents a group having a lactone structure or a sultone structure.

The group having a lactone structure or a sultone structure and serving as V is preferably a group represented by any one of the general formulas (LC1-1) to (LC1-21) and the general formulas (SL1-1) to (SL1-3).

The repeating unit having a group having a lactone structure or a sultone structure ordinarily has optical isomers, and any one of the optical isomers may be used. One of the optical isomers may be used alone, or a plurality of optical isomers may be used in admixture. In the case of mainly using one of the optical isomers, its optical purity (ee) is preferably 90 or more, and more preferably 95 or more.

Specific examples of the repeating unit having a group having a lactone structure or a sultone structure will be described below; however, the present invention is not limited thereto. Note that, in the formulas, Rx represents H, CH₃, CH₂OH, or CF₃.

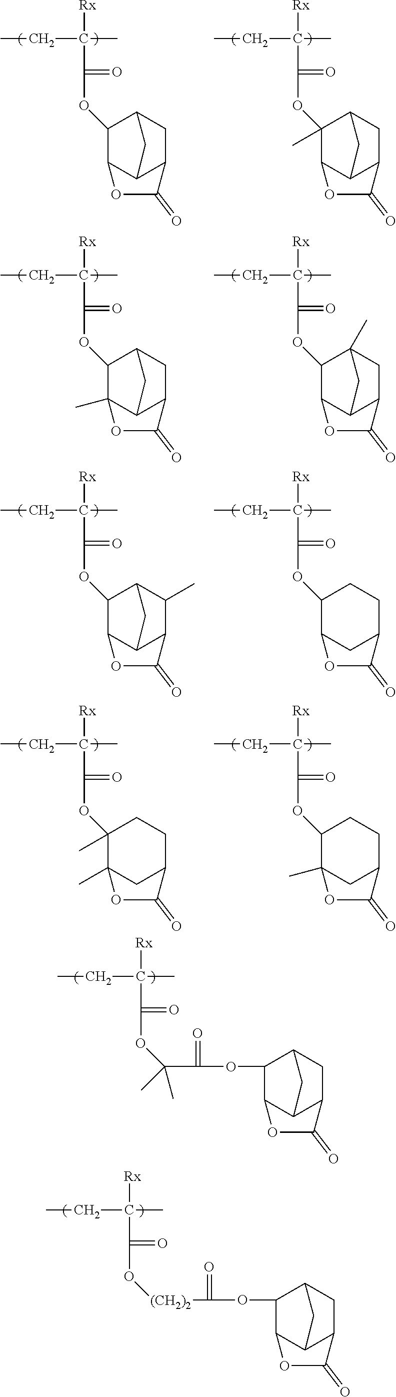

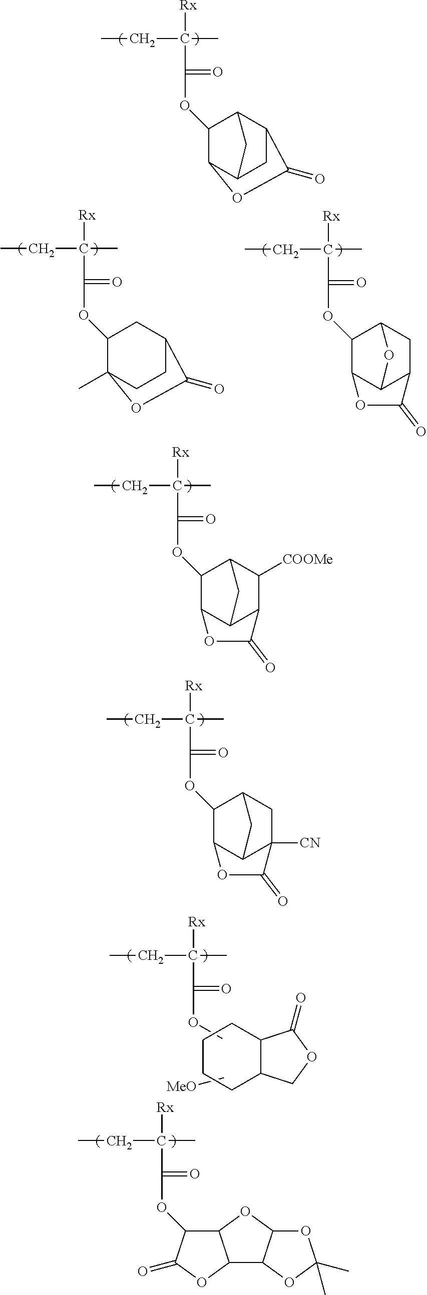

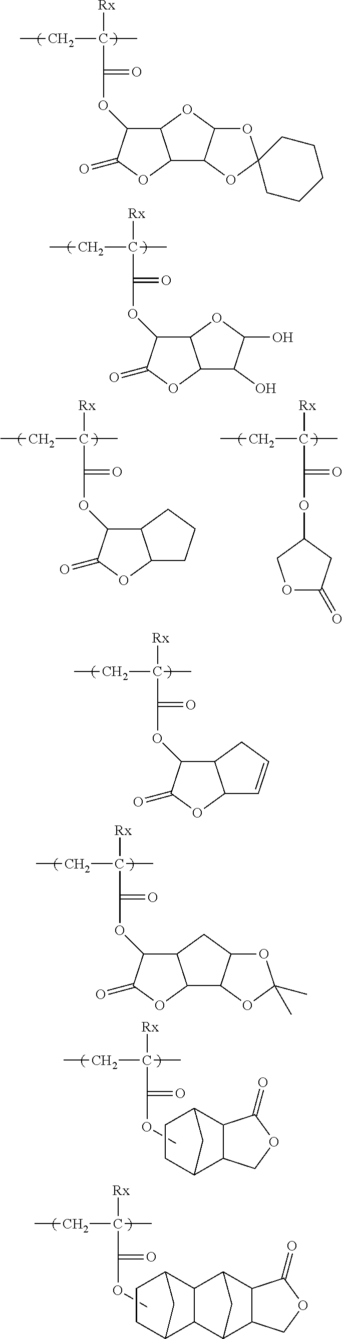

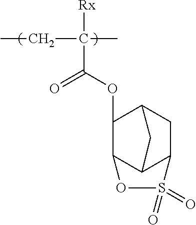

The content of the repeating unit having a lactone group or a sultone group is, relative to all the repeating units in the resin (A), preferably 1 to 60 mol %, more preferably 5 to 50 mol %, and still more preferably 10% to 40 mol %.

### Repeating Unit Having Fluorine Atom or Iodine Atom

The resin (A) may have a repeating unit having a fluorine atom or an iodine atom.

Examples of the repeating unit having a fluorine atom or an iodine atom include the repeating units described in paragraphs 0080 to 0081 of JP2019-045864A.

Repeating unit having photoacid generation group

The resin (A) may have, in addition to the above-described repeating units, a repeating unit having a group that generates an acid upon irradiation with a radiation.

Examples of the repeating unit having a fluorine atom or an iodine atom include the repeating units described in paragraphs 0092 to 0096 of JP2019-045864A.

### Repeating Unit Having Alkali-Soluble Group

The resin (A) may have a repeating unit having an alkali-soluble group.

Examples of the alkali-soluble group include a carboxyl group, a sulfonamide group, a sulfonylimide group, a bissulfonylimide group, and aliphatic alcohols substituted with an electron-withdrawing group at the α-position (for example, a hexafluoroisopropanol group), and preferred is a carboxyl group. The resin (A) that has a repeating unit having an alkali-soluble group provides increased resolution in the contact-hole applications.

Examples of the repeating unit having an alkali-soluble group include repeating units in which an alkali-soluble group is directly bonded to the main chain of the resin, such as repeating units derived from acrylic acid and methacrylic acid, and repeating units in which an alkali-soluble group is bonded to the main chain of the resin via a linking group. Note that the linking group may have a monocyclic or polycyclic cyclic hydrocarbon structure.

The repeating unit having an alkali-soluble group is preferably a repeating unit derived from acrylic acid or methacrylic acid.

### Repeating Unit not Having Acid Decomposable Group or Polar Group

The resin (A) may further have a repeating unit not having an acid decomposable group or a polar group. The repeating unit not having an acid decomposable group or a polar group preferably has an alicyclic hydrocarbon structure.

Examples of the repeating unit not having an acid decomposable group or a polar group include the repeating units described in paragraphs 0236 to 0237 of US2016/0026083A and the repeating units described in paragraph 0433 of US2016/0070167A.

The resin (A) may have, in addition to the above-described repeating structural units, various repeating units in accordance with, for example, a purpose of controlling dry etching resistance, suitability for the standard developer, adhesiveness to the substrate, resist profiles, resolving power, heat resistance, sensitivity, or the like.

The resin (A) can be synthesized in accordance with standard procedures (for example, radical polymerization). Examples of the general synthesis method include (1) a batch polymerization method in which a monomer species and an initiator are dissolved in a solvent and heated to perform polymerization, and (2) a dropping polymerization method in which a solution containing a monomer species and an initiator is added dropwise for 1 to 10 hours to perform addition to a heated solvent.

The resin (A) preferably has a weight-average molecular weight (Mw) of 1,000 to 200,000, more preferably 2,000 to 30,000, and still more preferably 3,000 to 25,000. The dispersity (Mw/Mn) is ordinarily 1.0 to 3.0, preferably 1.0 to 2.6, more preferably 1.0 to 2.0, and still more preferably 1.1 to 2.0.

For the resin (A), one species may be used alone, or two or more species may be used in combination.

In the resin solution of the present invention, the content of the resin (A) is, relative to the total solid content, preferably 50 mass % or more, more preferably 70 mass % or more, still more preferably 80 mass % or more, and particularly preferably 90 mass % or more. The upper limit is not particularly limited, and may be, for example, 99 mass % or less.

The total solid content means, except for the solvent, the other components.

(B) Compound that Generates Acid Upon Irradiation with Actinic Ray or Radiation and Represented by General Formula (1)

As described above, the actinic ray-sensitive or radiation-sensitive resin composition of the present invention contains (B) a compound that generates an acid upon irradiation with an actinic ray or a radiation and is represented by a general formula (1) below (also referred to as “compound (B)” or “photoacid generator (B)”).

The compound (B) is a compound that generates an acid upon irradiation with an actinic ray or a radiation (photoacid generator).

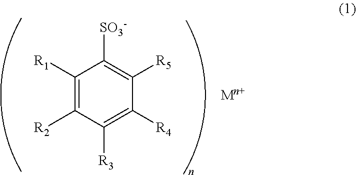

In the general formula (1), R₁ and R₅ each independently represent an aryl group or a heteroaryl group. R₂ to R₄ each independently represent a hydrogen atom or a substituent. Mⁿ⁺ represents a cation. n represents an integer of 1 or more.

Examples of the aryl groups serving as R₁ and R₅ include aryl groups having 6 to 15 carbon atoms, and preferred specific examples thereof include a phenyl group, a naphthyl group, and an anthryl group.

Examples of the heteroaryl groups serving as R₁ and R₅ include heteroaryl groups having 2 to 15 carbon atoms and heteroaryl groups having a 5- to 10-membered ring; specific examples thereof include a furyl group, a thienyl group, a pyrrolyl group, an oxazolyl group, a pyridyl group, a quinolinyl group, and a carbazolyl group.

The substituents serving as R₂ to R₄ are not particularly limited as long as they are monovalent substituents, and examples thereof include alkyl groups; alkenyl groups; cycloalkyl groups; aryl groups; halogen atoms; groups including a heteroatom such as an oxygen atom, a sulfur atom, a nitrogen atom, or a silicon atom; and combinations of two or more of the foregoing.

Examples of the alkyl groups serving as R₂ to R₄ include alkyl groups having 1 to 30 carbon atoms. The alkyl groups are preferably alkyl groups having 1 to 20 carbon atoms such as a methyl group, an ethyl group, a propyl group, an isopropyl group, an n-butyl group, a sec-butyl group, a hexyl group, a 2-ethylhexyl group, an octyl group, and a dodecyl group, and more preferably alkyl groups having 1 to 8 carbon atoms.

Examples of the alkenyl groups serving as R₂ to R₄ include alkenyl groups having 2 to 30 carbon atoms, and preferred are alkenyl groups having 2 to 8 carbon atoms.

The cycloalkyl groups serving as R₂ to R₄ may be monocyclic or polycyclic. The number of carbon atoms of such a cycloalkyl group is not particularly limited, but is preferably 3 to 8.

Examples of the aryl groups serving as R₂ to R₄ include aryl groups having 6 to 15 carbon atoms, and specifically preferred examples thereof include a phenyl group, a naphthyl group, and an anthryl group.

Examples of the halogen atoms serving as R₂ to R₄ include a fluorine atom, a chlorine atom, a bromine atom, and an iodine atom.

Examples of the groups including a heteroatom include a hydroxyl group, a carboxyl group, alkoxy groups, a thiol group, a thioether group, a nitro group, a nitroso group, a cyano group, an amino group, acyloxy groups, acylamide groups, heteroaryl groups, an ether bond, a carbonyl bond, and combinations of two or more of the foregoing.

For such an alkoxy group, an acyloxy group, or an acylamide group, the number of carbon atoms is preferably 20 or less, and more preferably 8 or less. Examples of the alkoxy group include a methoxy group, an ethoxy group, a propoxy group, an isopropoxy group, an n-butyloxy group, a t-butoxy group, and an octyloxy group. Of these, particularly preferred are a methoxy group, an ethoxy group, a propoxy group, an isopropoxy group, and a t-butoxy group. Examples of the thioether group are the same as those for the alkoxy group except that the oxygen atoms are replaced by sulfur atoms. Examples of the acyloxy group include an acetyloxy group. Examples of the acylamide group include an acetylamide group.

Examples of the heteroaryl groups include groups the same as those for the heteroaryl groups serving as R₁ and R₅.

The aryl groups and heteroaryl groups serving as R₁ and R₅ may have an additional substituent. Examples of the additional substituent include alkyl groups; alkenyl groups; cycloalkyl groups; aryl groups; halogen atoms; groups including a heteroatom such as an oxygen atom, a sulfur atom, a nitrogen atom, or a silicon atom; and combinations of two or more of the foregoing.

The alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing are respectively the same as the alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing in the specific examples of the substituents serving as R₂ to R₄.

When the aryl groups or the heteroaryl groups serving as R₁ and R₅ have a plurality of substituents, at least two among the plurality of substituents may be linked together to form a ring.

The alkyl groups, the alkenyl groups, the cycloalkyl groups, the aryl groups, and the groups including a heteroatom such as an oxygen atom, a sulfur atom, a nitrogen atom, or a silicon atom serving as the substituents represented by R₂ to R₄ may have an additional substituent. Examples of the additional substituent include alkyl groups, alkenyl groups, cycloalkyl groups, aryl groups, an amino group, an amide group, a ureido group, a urethane group, a hydroxy group, a carboxy group, halogen atoms, alkoxy groups, a thioether group, acyl groups, acyloxy groups, alkoxycarbonyl groups, a cyano group, a nitro group, and combinations of two or more of the foregoing.

R₁ and R₅ above can constitute a group including a polar group, a group including a group that is decomposed by the action of an acid to provide increased polarity, or a group including a group that is decomposed by the action of an alkali developer to provide an increased degree of solubility in the alkali developer, which will be described later.

R₂ to R₄ above can constitute a group including a polar group, a group including a group that is decomposed by the action of an acid to provide increased polarity, or a group including a group that is decomposed by the action of an alkali developer to provide an increased degree of solubility in the alkali developer, which will be described later.

In the above-described general formula (1), R₃ preferably represents an aryl group.

Examples of the aryl group serving as R₃ include the same as those for the aryl groups serving as R₁ and R₅.

The aryl group serving as R₃ may have an additional substituent. Examples of the additional substituent include the groups described above as specific examples of the substituent that R₁ and R₅ above may further have.

When the aryl group serving as R₃ has a plurality of substituents, at least two among the plurality of substituents may be linked together to form a ring.

In the above-described general formula (1), at least one of R₁ to R₅ is preferably a group including a polar group, a group including a group that is decomposed by the action of an acid to provide increased polarity, or a group including a group that is decomposed by the action of an alkali developer to provide an increased degree of solubility in the alkali developer.

In the group including a polar group serving as at least one of R₁ to R₅, examples of the polar group include acidic groups such as a carboxyl group, a phenolic hydroxyl group, fluorinated alcohol groups, a sulfonamide group, a sulfonylimide group, (alkylsulfonyl)(alkylcarbonyl) methylene groups, (alkylsulfonyl)(alkylcarbonyl) imide groups, bis(alkylcarbonyl) methylene groups, bis(alkylcarbonyl) imide groups, bis(alkylsulfonyl) methylene groups, bis(alkylsulfonyl) imide groups, tris(alkylcarbonyl) methylene groups, and tris(alkylsulfonyl) methylene group, and an alcoholic hydroxyl group.

Note that the alcoholic hydroxyl group is a hydroxyl group bonded to a hydrocarbon group, and refers to a hydroxyl group other than a hydroxyl group directly bonded to an aromatic ring (phenolic hydroxyl group); as the hydroxyl group, aliphatic alcohols substituted with an electron-withdrawing group such as a fluorine atom at the α-position (for example, a hexafluoroisopropanol group) are excluded. The alcoholic hydroxyl group is preferably a hydroxyl group having a pKa (acid dissociation constant) of 12 or more and 20 or less.

Of these, the polar group is preferably a carboxyl group, a phenolic hydroxyl group, or a fluorinated alcohol group (preferably a hexafluoroisopropanol group).

Examples of the group including a polar group also include a group having a carbonyl bond.

Examples of the group having a carbonyl bond include alkylcarbonyl groups and arylcarbonyl groups.

Examples of such an alkyl group include the same as the alkyl groups serving as R₂ to R₄.

Examples of such an aryl group include the same as the aryl groups serving as R₁ and R₅.

The group having a carbonyl bond is a group in which a carbonyl bond and an ether bond are not adjacently bonded.

The alkylcarbonyl group or arylcarbonyl group serving as the group having a carbonyl bond may have an additional substituent.

Examples of the additional substituent include alkyl groups; alkenyl groups; cycloalkyl groups; aryl groups; halogen atoms; groups including a heteroatom such as an oxygen atom, a sulfur atom, a nitrogen atom, or a silicon atom; and combinations of two or more of the foregoing.

The alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing are respectively the same as the alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing in the specific examples of the substituents serving as R₂ to R₄.

The group including a polar group is not particularly limited, and examples thereof include an organic group including a polar group. Examples of the organic group including a polar group include alkyl groups; alkenyl groups; cycloalkyl groups; aryl groups; halogen atoms; groups including a heteroatom such as an oxygen atom, a sulfur atom, a nitrogen atom, or a silicon atom; and combinations of two or more of the foregoing that have a polar group.

The alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing are respectively the same as the alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing in the specific examples of the substituents serving as R₂ to R₄.

Examples of the group including a polar group include alkyl groups including a polar group and aryl groups including a polar group.

In the alkyl groups including a polar group, examples of the alkyl groups include the same as the alkyl groups serving as R₂ to R₄.

In the aryl groups including a polar group, examples of the aryl groups include the same as the aryl groups serving as R₁ and R₅.

The groups including a polar group may themselves be polar groups.

In the group serving as at least one of R₁ to R₅ and including a group that is decomposed by the action of an acid to provide increased polarity, the group that is decomposed by the action of an acid to provide increased polarity (hereinafter, also referred to as “acid decomposable group”) preferably has a structure in which the polar group is protected by a group that is decomposed by the action of an acid to leave (leaving group).

Examples of the polar group include the same as those for, in the group including a polar group and serving as at least one of R₁ to R₅, the polar group.

Examples of the group that is decomposed to leave by the action of an acid (leaving group) include groups represented by the formulas (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (Y4):

In the formula (Y1) and the formula (Y2), Rx₁ to Rx₃ each independently represent an alkyl group (linear or branched) or a cycloalkyl group (monocyclic or polycyclic). Note that, when all of Rx₁ to Rx₃ are alkyl groups (linear or branched), at least two among Rx₁ to Rx₃ are preferably methyl groups.

In particular, preferably, Rx₁ to Rx₃ each independently represent a linear or branched alkyl group, and more preferably Rx₁ to Rx₃ each independently represent a linear alkyl group.

Two among Rx₁ to Rx₃ may be linked together to form a monocycle or a polycycle.

In Rx₁ to Rx₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

In Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

The cycloalkyl group formed by combining two among Rx₁ to Rx₃ is preferably a monocyclic cycloalkyl group such as a cyclopentyl group or a cyclohexyl group, and a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms.

In the cycloalkyl group formed by combining two among Rx₁ to Rx₃, for example, one of methylene groups constituting the ring may be replaced by a heteroatom such as an oxygen atom or a group having a heteroatom such as a carbonyl group.

In a preferred embodiment, for the group represented by the formula (Y1) or the formula (Y2), for example, Rx₁ is a methyl group or an ethyl group, and Rx₂ and Rx₃ are bonded together to form the above-described cycloalkyl group.

In the formula (Y3), R₃₆ to R₃₈ each independently represent a hydrogen atom or a monovalent organic group. R₃₇ and R₃₈ may be bonded together to form a ring. Examples of the monovalent organic group include alkyl groups, cycloalkyl groups, aryl groups, aralkyl groups, and alkenyl groups. R₃₆ is also preferably a hydrogen atom.

The formula (Y3) preferably represents a group represented by the following formula (Y3-1).

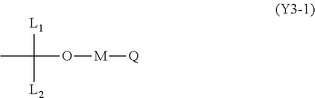

L₁ and L₂ each independently represent a hydrogen atom, an alkyl group, a cycloalkyl group, an aryl group, or a group that is a combination of the foregoing (for example, a group that is a combination of an alkyl group and an aryl group).

M represents a single bond or a divalent linking group.

Q represents an alkyl group that may include a heteroatom, a cycloalkyl group that may include a heteroatom, an aryl group that may include a heteroatom, an amino group, an ammonium group, a mercapto group, a cyano group, an aldehyde group, or a group that is a combination of the foregoing (for example, a group that is a combination of an alkyl group and a cycloalkyl group).

In the alkyl group and the cycloalkyl group, for example, one of methylene groups may be replaced by a heteroatom such as an oxygen atom or a group having a heteroatom such as a carbonyl group.

Note that one of L₁ and L₂ is preferably a hydrogen atom and the other is preferably an alkyl group, a cycloalkyl group, an aryl group, or a group that is a combination of an alkylene group and an aryl group.

At least two among Q, M, and L₁ may be bonded together to form a ring (preferably a 5-membered or 6-membered ring).

From the viewpoint of reducing the size of patterns, L₂ is preferably a secondary or tertiary alkyl group, more preferably a tertiary alkyl group. Examples of the secondary alkyl group include an isopropyl group, a cyclohexyl group, and a norbornyl group, and examples of the tertiary alkyl group include a tert-butyl group and an adamantane group. In such embodiments, Tg (glass transition temperature) and activation energy are increased, so that the film hardness can be ensured and fogging can be suppressed.

In the formula (Y4), Ar represents an aromatic ring group. Rn represents an alkyl group, a cycloalkyl group, or an aryl group. Rn and Ar may be bonded together to form a non-aromatic ring. Ar is more preferably an aryl group.

The acid decomposable group preferably has an acetal structure. The acetal structure is, for example, a structure in which a polar group such as a carboxyl group, a phenolic hydroxyl group, or a fluorinated alcohol group is protected by the above-described group represented by the formula (Y3).

The group including an acid decomposable group is not particularly limited as long as it is a group including an acid decomposable group, and examples thereof include an organic group including an acid decomposable group. Examples of the organic group including an acid decomposable group include alkyl groups; alkenyl groups; cycloalkyl groups; aryl groups; halogen atoms; groups including a heteroatom such as an oxygen atom, a sulfur atom, a nitrogen atom, or a silicon atom; and groups being combinations of two or more of the foregoing that have an acid decomposable group.

The alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing are respectively the same as the alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing in the specific examples of the substituents serving as R₂ to R₄.

Examples of the group including an acid decomposable group include alkyl groups including an acid decomposable group and aryl groups including an acid decomposable group.

In the alkyl group including an acid decomposable group, examples of the alkyl group include the same as the alkyl groups serving as R₂ to R₄.

In the aryl group including an acid decomposable group, examples of the aryl group include the same as the aryl groups serving as R₁ and R₅.

The group including an acid decomposable group may itself be an acid decomposable group.

In the group serving as at least one of R₁ to R₅ and including a group that is decomposed by the action of an alkali developer to provide an increased degree of solubility in the alkali developer, the group that is decomposed by the action of an alkali developer to provide an increased degree of solubility in the alkali developer is also referred to as “polarity conversion group”; examples thereof include a lactone group, a carboxylic acid ester group (—COO—), an acid anhydride group (—C(O)OC(O)—), an acid imide group (—NHCONH—), a carboxylic acid thioester group (—COS—), a carbonic acid ester group (—OC(O)O—), a sulfuric acid ester group (—OSO₂O—), and a sulfonic acid ester group (—SO₂O—).

Examples of the group including a polarity conversion group include acyloxy groups, alkoxycarbonyloxy groups, aryloxycarbonyloxy groups, aryloxycarbonyl groups, alkoxycarbonyl groups, a carbamoyl group, and an imide group.

In such an acyloxy group, the number of carbon atoms of the acyl group is preferably 1 to 30, and more preferably 1 to 8.

In such an alkoxycarbonyloxy group, the number of carbon atoms of the alkoxy group is preferably 1 to 30, and more preferably 1 to 8.

In such an aryloxycarbonyloxy group, the number of carbon atoms of the aryl group is preferably 6 to 14, and more preferably 6 to 10.

In such an aryloxycarbonyl group, the number of carbon atoms of the aryl group is preferably 6 to 14, and more preferably 6 to 10.

In such an alkoxycarbonyl group, the number of carbon atoms of the alkoxy group is preferably 1 to 30, and more preferably 1 to 8.

The imide group is a group provided by removing a single hydrogen atom from imide.

The acyloxy group, the alkoxycarbonyloxy group, the aryloxycarbonyloxy group, the aryloxycarbonyl group, the alkoxycarbonyl group, the carbamoyl group, and the imide group may have an additional substituent.

Examples of the additional substituent include the groups described above as specific examples of the substituent that R₁ and R₅ above may further have.

In one preferred embodiment of the present invention, the polarity conversion group is a group represented by X in the partial structure represented by a general formula (KA-1) or (KB-1).

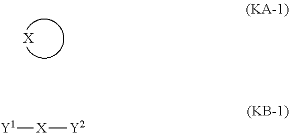

In the general formula (KA-1) or (KB-1), X represents a carboxylic acid ester group: —COO—, an acid anhydride group: —C(O)OC(O)—, an acid imide group: —NHCONH—, a carboxylic acid thioester group: —COS—, a carbonic acid ester group: —OC(O)O—, a sulfuric acid ester group: —OSO₂O—, or a sulfonic acid ester group: —SO₂O—.

Y¹ and Y² may be the same or different, and represent electron-withdrawing groups.

In one preferred embodiment of the present invention, the compound (B) has, as a group including a polarity conversion group, a group having a partial structure represented by the general formula (KA-1) or (KB-1), and when the partial structure does not have a direct bond as in the case of the partial structure represented by the general formula (KA-1) or the partial structure represented by (KB-1) where Y¹ and Y² are monovalent, the group having the partial structure is a group having a mono- or higher valent group provided by removing at least any one hydrogen atom in the partial structure.

The partial structure represented by the general formula (KA-1) is a structure that forms, together with the group serving as X, a ring structure.

X in the general formula (KA-1) is preferably a carboxylic acid ester group (that is, a case where a lactone ring structure is formed as KA-1), an acid anhydride group, or a carbonic acid ester group. More preferred is a carboxylic acid ester group.

The ring structure represented by the general formula (KA-1) may have a substituent, and, for example, may have nka substituents Zₖₐ₁.

In such a case where a plurality of Zₖₐ₁'s are present, Zₖₐ₁'s each independently represent an alkyl group, a cycloalkyl group, an ether group, a hydroxyl group, an amide group, an aryl group, a lactone ring group, or an electron-withdrawing group.

Zₖₐ₁'s may be linked together to form a ring. Examples of the ring formed by linking together of Zₖₐ₁'s include cycloalkyl rings and heterocycles (for example, cyclic ether rings or lactone rings).

nka represents an integer of 0 to 10. It is preferably an integer of 0 to 8, more preferably an integer of 0 to 5, still more preferably an integer of 1 to 4, and most preferably an integer of 1 to 3.

The electron-withdrawing group serving as Zₖₐ₁ is the same as the electron-withdrawing groups represented by halogen atoms and serving as Y¹ and Y² described later.

Note that the electron-withdrawing group may be substituted with another electron-withdrawing group.

Zₖₐ₁ is preferably an alkyl group, a cycloalkyl group, an ether group, a hydroxyl group, or an electron-withdrawing group, and more preferably an alkyl group, a cycloalkyl group, or an electron-withdrawing group. Note that the ether group is preferably a group substituted with, for example, an alkyl group or a cycloalkyl group, that is, an alkyl ether group or the like. Preferred examples of the electron-withdrawing group are the same as the electron-withdrawing groups serving as Y¹ and Y² described later.

Examples of the halogen atom serving as Zₖₐ₁ include a fluorine atom, a chlorine atom, a bromine atom, and an iodine atom, and preferred is a fluorine atom.

The alkyl group serving as Zₖₐ₁ may have a substituent and may be linear or branched. The linear alkyl group preferably has 1 to 30 carbon atoms, and more preferably 1 to 20 carbon atoms; and examples thereof include a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, and an n-decanyl group. The branched alkyl group preferably has 3 to 30 carbon atoms, and more preferably 3 to 20 carbon atoms; and examples thereof include an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, and a t-decanoyl group. Preferred are those having 1 to 4 carbon atoms such as a methyl group, an ethyl group, an n-propyl group, an i-propyl group, an n-butyl group, an i-butyl group, and a t-butyl group.

The cycloalkyl group serving as Zₖₐ₁ may have a substituent, and may be monocyclic, polycyclic, or bridged. For example, the cycloalkyl group may have a bridged structure. The monocyclic one is preferably a cycloalkyl group having 3 to 8 carbon atoms, and examples thereof include a cyclopropyl group, a cyclopentyl group, a cyclohexyl group, a cyclobutyl group, and a cyclooctyl group. Examples of the polycyclic one include a group having, for example, a bicyclo, tricyclo, or tetracyclo structure having 5 or more carbon atoms, and preferred is a cycloalkyl group having 6 to 20 carbon atoms; and examples thereof include an adamantyl group, a norbornyl group, an isobornyl group, a camphanyl group, a dicyclopentyl group, an α-pinenyl group, a tricyclodecanyl group, a tetracyclododecyl group, and an androstanyl group. The cycloalkyl group also preferably has the following structures. Note that a part of the carbon atoms in the cycloalkyl group may be substituted with a heteroatom such as an oxygen atom.

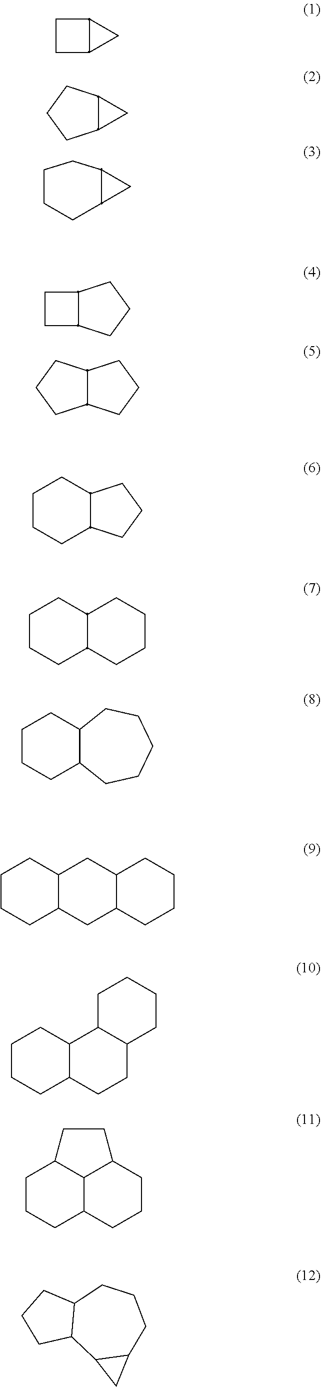

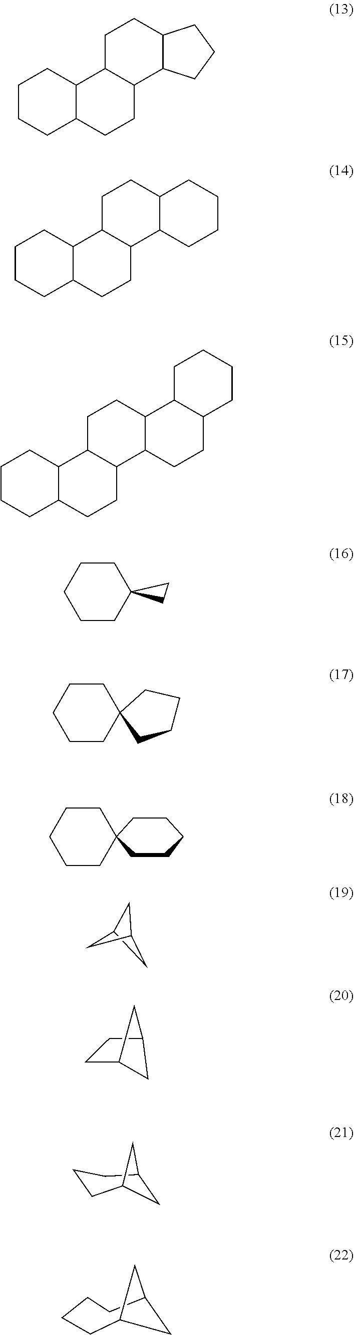

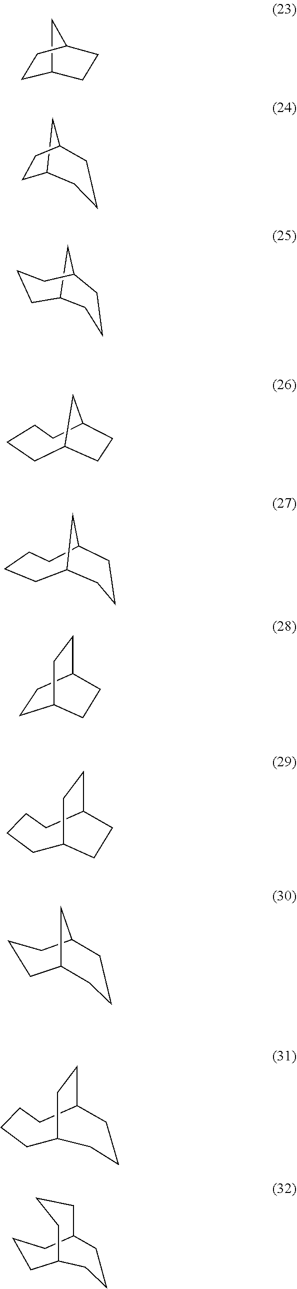

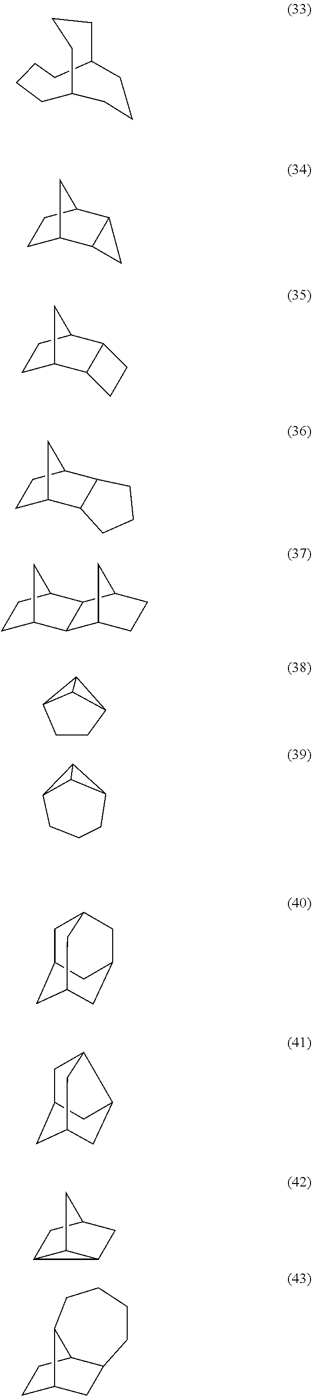

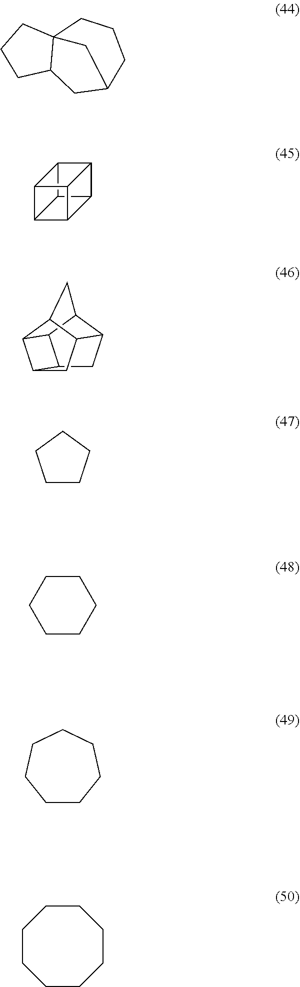

Of the above-described alicyclic moieties, preferred examples include an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group, and a cyclododecanyl group. More preferred are an adamantyl group, a decalin group, a norbornyl group, a cedrol group, a cyclohexyl group, a cycloheptyl group, a cyclooctyl group, a cyclodecanyl group, a cyclododecanyl group, and a tricyclodecanyl group.

For these alicyclic structures, examples of substituents include alkyl groups, halogen atoms, a hydroxyl group, alkoxy groups, a carboxyl group, and alkoxycarbonyl groups. The alkyl groups are preferably lower alkyl groups such as a methyl group, an ethyl group, a propyl group, an isopropyl group, and a butyl group, and more preferably a methyl group, an ethyl group, a propyl group, and an isopropyl group. The alkoxy groups are preferably alkoxy groups having 1 to 4 carbon atoms such as a methoxy group, an ethoxy group, a propoxy group, and a butoxy group. Examples of substituents that the alkyl groups and the alkoxy groups may have include a hydroxyl group, halogen atoms, and alkoxy groups (preferably having 1 to 4 carbon atoms).

Examples of the lactone ring group serving as Zₖₐ₁ include a group provided by removing a hydrogen atom from the structure represented by any one of (KA-1-1) to (KA-1-17) described later.

Examples of the aryl group serving as Zₖₐ₁ include a phenyl group and a naphthyl group.

Examples of substituents that the alkyl groups, the cycloalkyl groups, and the aryl groups serving as Zₖₐ₁ may further have include a hydroxyl group, halogen atoms (fluorine, chlorine, bromine, and iodine), a nitro group, a cyano group, the above-described alkyl groups, alkoxy groups such as a methoxy group, an ethoxy group, a hydroxyethoxy group, a propoxy group, a hydroxypropoxy group, an n-butoxy group, an isobutoxy group, a sec-butoxy group, and a t-butoxy group, alkoxycarbonyl groups such as a methoxycarbonyl group and an ethoxycarbonyl group, aralkyl groups such as a benzyl group, a phenethyl group, and a cumyl group, aralkyloxy groups, acyl groups such as a formyl group, an acetyl group, a butyryl group, a benzoyl group, a cinnamyl group, and a valeryl group, acyloxy groups such as a butyryloxy group, the above-described alkenyl groups, alkenyloxy groups such as a vinyloxy group, a propenyloxy group, an allyloxy group, and a butenyloxy group, the above-described aryl groups, aryloxy groups such as a phenoxy group, and aryloxycarbonyl groups such as a benzoyloxy group.

X in the general formula (KA-1) is preferably a carboxylic acid ester group, and the partial structure represented by the general formula (KA-1) is preferably a lactone ring, and more preferably a 5- to 7-membered lactone ring.

Note that, as described in (KA-1-1) to (KA-1-17) below, the 5- to 7-membered lactone ring serving as the partial structure represented by the general formula (KA-1) is preferably fused with another ring structure so as to form a bicyclo structure or a spiro structure.

Examples of an adjacent ring structure to which the ring structure represented by the general formula (KA-1) may be bonded include the ring structures in (KA-1-1) to (KA-1-17) below and ring structures similar to the ring structures.

The structure containing a lactone ring structure represented by the general formula (KA-1) is more preferably a structure represented by any one of (KA-1-1) to (KA-1-17) below. Note that the lactone structure may be directly bonded to the main chain. Preferred structures are (KA-1-1), (KA-1-4), (KA-1-5), (KA-1-6), (KA-1-13), (KA-1-14), and (KA-1-17).

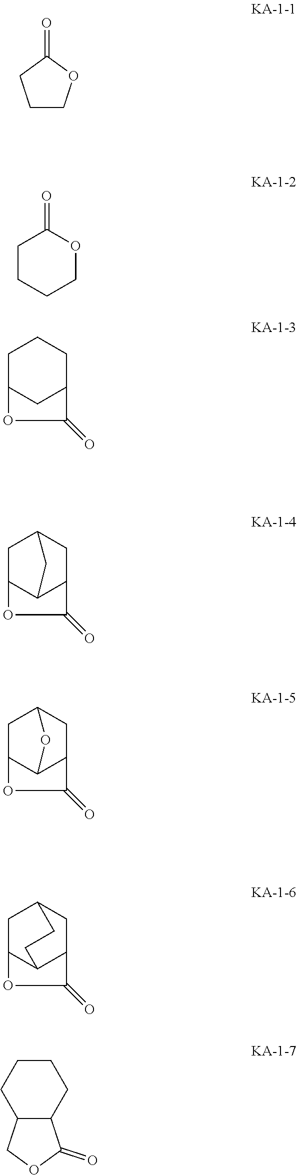

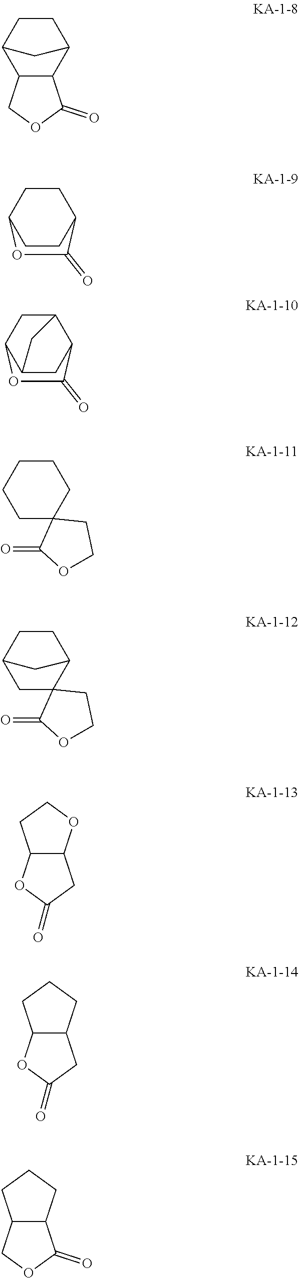

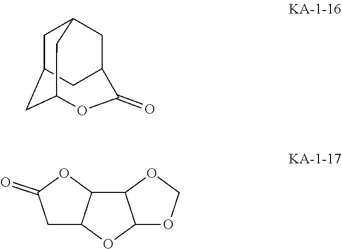

Such a lactone ring structure-containing structure may have or may not have a substituent. Preferred examples of the substituent include the same as the above-described substituents that the ring structure represented by the general formula (KA-1) may have.

Some lactone structures have optically active forms, and any of the optically active forms may be used. A single optically active form may be used alone, or a plurality of optically active forms may be mixed and used. When a single optically active form is mainly used, it preferably has an optical purity (ee) of 90% or more, more preferably 95% or more, and most preferably 98% or more.

X in the general formula (KB-1) is preferably a carboxylic acid ester group (—COO—).

Y¹ and Y² in the general formula (KB-1) each independently represent an electron-withdrawing group.

The electron-withdrawing group is preferably a partial structure represented by the following formula (EW). In the formula (EW), * represents a direct bond to (KA-1) or a direct bond to X in (KB-1).

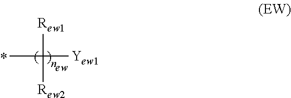

In the formula (EW),

n_{ew} represents the number of repeats of a linking group represented by —C(R_{ew1})(R_{ew2})— and represents an integer of 0 or 1. When n_{ew} is 0, a single bond is provided and Y_{ew1} is directly bonded.

Examples of Y_{ew1} include halogen atoms, a cyano group, a nitrile group, a nitro group, halo(cyclo)alkyl groups or haloaryl groups represented by —C(R_{f1})(R_{f2})—R_{f3} described later, an oxy group, a carbonyl group, a sulfonyl group, a sulfinyl group, and combinations of the foregoing; examples of the structure of the electron-withdrawing group will be described below. Note that “halo(cyclo)alkyl groups” represent alkyl groups and cycloalkyl groups that are at least partially halogenated. R_{ew3} and R_{ew4} each independently represent any structure. Even when R_{ew3} and R_{ew4} have any structures, the partial structure represented by the formula (EW) has an electron-withdrawing property; preferred are alkyl groups, cycloalkyl groups, and fluoroalkyl groups.

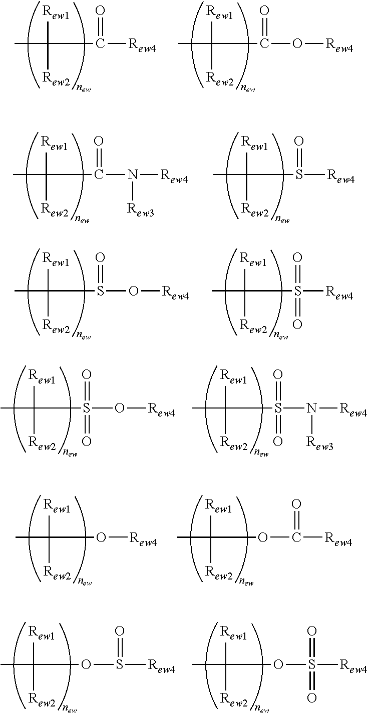

When Y_{ew1} is a di- or higher valent group, the remaining direct bond forms a bond with any atom or substituent.

Y_{ew1} is preferably a halogen atom or a halo(cyclo)alkyl group or a haloaryl group represented by —C(R_{f1})(R_{f2})—R_{f3}.

R_{ew1} and R_{ew2} each independently represent any substituent, for example, a hydrogen atom, an alkyl group, a cycloalkyl group, or an aryl group.

At least two among R_{ew1}, R_{ew2}, and Y_{ew1} may be linked together to form a ring.

R₁ represents a halogen atom, a perhaloalkyl group, a perhalocycloalkyl group, or a perhaloaryl group, more preferably a fluorine atom, a perfluoroalkyl group, or a perfluorocycloalkyl group, and still more preferably a fluorine atom or a trifluoromethyl group.

R_{f2} and R_{f3} each independently represent a hydrogen atom, a halogen atom, or an organic group, and R_{f2} and R_{f3} may be linked together to form a ring. Examples of the organic group include alkyl groups, cycloalkyl groups, and alkoxy groups, which may be substituted with a halogen atom (preferably a fluorine atom), and more preferably R_{f2} and R_{f3} are (halo)alkyl groups. More preferably, R_{f2} represents the same group as R_{f1} or is linked to R_{f3} to form a ring.

R_{f1} and R_{f3} may be linked together to form a ring, and examples of the ring formed include (halo)cycloalkyl rings and (halo)aryl rings.

Examples of the (halo)alkyl groups in R_{f1} to R_{f3} include the above-described alkyl groups in Zₖₐ₁ and halogenated structures thereof.

In R_{f1} to R_{f3} or in the ring formed by linking together R_{f2} and R_{f3}, examples of the (per)halocycloalkyl groups and the (per)haloaryl groups include structures in which the above-described cycloalkyl group in Zₖₐ₁ is halogenated; more preferred are fluorocycloalkyl groups represented by —C₍ₙ₎F₍₂ₙ₋₂₎H and perfluoroaryl groups represented by —C₍ₙ₎F₍ₙ₋₁₎. In this case, the number n of carbon atoms is not particularly limited, but is preferably 5 to 13, and more preferably 6.

The ring that may be formed by linking together at least two among R_{ew1}, R_{ew2}, and Y_{ew1} is preferably a cycloalkyl group or a heterocyclic group, and the heterocyclic group is preferably a lactone ring group. Examples of the lactone ring include structures represented by the above-described formulas (KA-1-1) to (KA-1-17).

Note that the compound (B) may have a plurality of partial structures represented by the general formula (KA-1), a plurality of partial structures represented by the general formula (KB-1), or both of a partial structure of the general formula (KA-1) and the general formula (KB-1).

Note that a part of or the entirety of the partial structure of the general formula (KA-1) may also serve as the electron-withdrawing group serving as Y¹ or Y² in the general formula (KB-1). For example, when X in the general formula (KA-1) is a carboxylic acid ester group, the carboxylic acid ester group may function as an electron-withdrawing group serving as Y¹ or Y² in the general formula (KB-1).

The group including a polarity conversion group is not particularly limited, and examples thereof include an organic group including a polarity conversion group. Examples of the organic group including a polarity conversion group include alkyl groups; alkenyl groups; cycloalkyl groups; aryl groups; halogen atoms; groups including a heteroatom such as an oxygen atom, a sulfur atom, a nitrogen atom, or a silicon atom; and groups being combinations of two or more of the foregoing that have a polarity conversion group.

The alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing are respectively the same as the alkyl groups; the alkenyl groups; the cycloalkyl groups; the aryl groups; the halogen atoms; the groups including a heteroatom such as an oxygen atom, a sulfur atom, a nitrogen atom, or a silicon atom; and the combinations of two or more of the foregoing in the specific examples of the substituents serving as R₂ to R₄.

Examples of the group including a polarity conversion group include alkyl groups including a polarity conversion group and aryl groups including a polarity conversion group.

In the alkyl groups including a polarity conversion group, examples of the alkyl groups include the same as the alkyl groups serving as R₂ to R₄.

In the aryl groups including a polarity conversion group, examples of the aryl groups include the same as the aryl groups serving as R₁ and R₅.

In the above-described general formula (1), R₁, R₃, and R₅ are preferably a group represented by the following general formula (Ar).

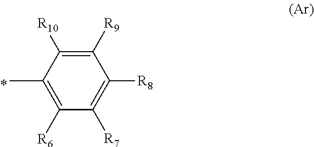

In the general formula (Ar), R₆ to R₁₀ each independently represent a hydrogen atom or a substituent. At least one of R₆ to R₁₀ is a group including a polar group, a group including a group that is decomposed by the action of an acid to provide increased polarity, or a group including a group that is decomposed by the action of an alkali developer to provide an increased degree of solubility in the alkali developer. * represents a direct bond to the benzene ring in the general formula (1).

Specific examples of the substituents serving as R₆ to R₁₀ are the same as the above-described specific examples of the substituents serving as R₂ to R₄.

At least one of R₆ to R₁₀ is a group including a polar group, a group including a group that is decomposed by the action of an acid to provide increased polarity, or a group including a group that is decomposed by the action of an alkali developer to provide an increased degree of solubility in the alkali developer.

The group including a polar group is the same as the group including a polar group serving as at least one of R₁ to R₅.

The group including a group that is decomposed by the action of an acid to provide increased polarity is the same as the group including a group that is decomposed by the action of an acid to provide increased polarity and serving as at least one of R₁ to R₅.

The group including a group that is decomposed by the action of an alkali developer to provide an increased degree of solubility in the alkali developer is the same as the group including a group that is decomposed by the action of an alkali developer to provide an increased degree of solubility in the alkali developer and serving as at least one of R₁ to R₅.

In the above-described general formula (1), R₁, R₃, and R₅ are preferably a group represented by the following general formula (Ar1).

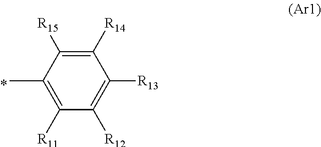

In the general formula (Ar1),

R₁₁ to R₁₅ each independently represent a hydrogen atom or a substituent, and at least one of R₁₁ to R₁₅ represents the following Substituent Y. * represents a direct bond to the benzene ring in the general formula (1).

Substituent Y: a hydroxy group, a carboxyl group, a group having a carbonyl bond, an acyloxy group, an alkoxycarbonyloxy group, an aryloxycarbonyloxy group, an aryloxycarbonyl group, an alkoxycarbonyl group, a carbamoyl group, or an imide group.

Specific examples of the substituents serving as R₁₁ to R₁₅ are the same as the above-described specific examples of the substituents serving as R₂ to R₄.

At least one of R₁₁ to R₁₅ represents the substituent Y

Specific examples of the group having a carbonyl bond and serving as the substituent Y are the same as the above-described specific examples of the group having a carbonyl bond and serving as the group having a polar group.

In the acyloxy group serving as the substituent Y, the number of carbon atoms of the acyl group is preferably 1 to 30, and more preferably 1 to 8.

In the alkoxycarbonyloxy group serving as the substituent Y, the number of carbon atoms of the alkoxy group is preferably 1 to 30, and more preferably 1 to 8.

In the aryloxycarbonyloxy group serving as the substituent Y, the number of carbon atoms of the aryl group is preferably 6 to 14, and more preferably 6 to 10.

In the aryloxycarbonyl group serving as the substituent Y, the number of carbon atoms of the aryl group is preferably 6 to 14, and more preferably 6 to 10.

In the alkoxycarbonyl group serving as the substituent Y, the number of carbon atoms of the alkoxy group is preferably 1 to 30, and more preferably 1 to 8.

The imide group serving as the substituent Y is a group provided by removing a single hydrogen atom from imide.

The group having a carbonyl bond, the acyloxy group, the alkoxycarbonyloxy group, the aryloxycarbonyloxy group, the aryloxycarbonyl group, the alkoxycarbonyl group, and the imide group that serve as the substituent Y may have an additional substituent.

Examples of the additional substituent include the groups described above as specific examples of the substituent that R₁ and R₅ above may further have.

In the anionic moiety of the general formula (1), n represents the number of anions. n represents an integer of 1 or more. The upper limit value of n is not particularly limited, and is, for example, 4.

n is preferably 1.

Mⁿ⁺ in the above-described general formula (1) represents a cation.

In the cationic moiety of the general formula (1), n represents the valence of the cation. n represents an integer of 1 or more. The upper limit value of n is not particularly limited, and is, for example, 4.

n is preferably 1.

The cation represented by Mⁿ⁺ is not particularly limited as long as it is a mono- or higher valent cation, but preferred are onium cations, and preferred is a cation represented by the following general formula (ZIA) or general formula (ZIIA).

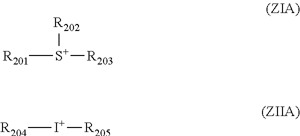

In the general formula (ZIA),

R₂₀₁, R₂₀₂, and R₂₀₃ each independently represent an organic group.

For the organic groups serving as R₂₀₁, R₂₀₂, and R₂₀₃, the number of carbon atoms is generally 1 to 30, and preferably 1 to 20.

Two among R₂₀₁ to R₂₀₃ may be bonded together to form a ring structure, and the ring may include an oxygen atom, a sulfur atom, an ester bond, an amide bond, or a carbonyl group. Examples of the group formed by bonding together two among R₂₀₁ to R₂₀₃ include alkylene groups (such as a butylene group or a pentylene group) and —CH₂—CH₂—O—CH₂—CH₂—.

Preferred examples of the cation represented by the general formula (ZIA) include a cation (ZI-11), a cation (ZI-12), a cation (cation (ZI-13)) represented by a general formula (ZI-13), and a cation (cation (ZI-14)) represented by a general formula (ZI-14), which will be described later.

In the case where n is 2 or more, the di- or higher valent cation may be a cation having a plurality of structures represented by the general formula (ZIA). Examples of such a cation include a divalent cation having a structure in which at least one of R₂₀₁ to R₂₀₃ of the cation represented by the general formula (ZIA) and at least one of R₂₀₁ to R₂₀₃ of another cation represented by the general formula (ZIA) are bonded via a single bond or a linking group.

First, the cation (ZI-11) will be described.

The cation (ZI-11) is a cation in which at least one of R₂₀₁ to R₂₀₃ in the general formula (ZIA) is an aryl group, that is, an arylsulfonium cation.

In the arylsulfonium cation, all of R₂₀₁ to R₂₀₃ may be aryl groups, or one or more of R₂₀₁ to R₂₀₃ may be aryl groups and the other may be an alkyl group or a cycloalkyl group.

Examples of the arylsulfonium cation include triarylsulfonium cations, diarylalkylsulfonium cations, aryldialkylsulfonium cations, diarylcycloalkylsulfonium cations, and aryldicycloalkylsulfonium cations.

The aryl group included in the arylsulfonium cation is preferably a phenyl group or a naphthyl group, and more preferably a phenyl group. The aryl group may be an aryl group having a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. When the arylsulfonium cation has two or more aryl groups, the two or more aryl groups may be the same or different.

The alkyl group or cycloalkyl group that the arylsulfonium cation optionally has is preferably a linear alkyl group having 1 to 15 carbon atoms, a branched alkyl group having 3 to 15 carbon atoms, or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

The aryl groups, the alkyl groups, and the cycloalkyl groups serving as R₂₀₁ to R₂₀₃ may each independently have, as a substituent, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, a lactone ring group, or a phenylthio group.

Examples of the lactone ring group include a group provided by removing a hydrogen atom from the above-described structure represented by any one of (KA-1-1) to (KA-1-17).

Hereinafter, the cation (ZI-12) will be described.

The cation (ZI-12) is a compound in which R₂₀₁ to R₂₀₃ in the formula (ZIA) each independently represent an organic group not having an aromatic ring. This aromatic ring encompasses aromatic rings including a heteroatom.

The organic groups not having an aromatic ring and serving as R₂₀₁ to R₂₀₃ generally have 1 to 30 carbon atoms, and preferably have 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

Preferred examples of the alkyl groups and the cycloalkyl groups serving as R₂₀₁ to R₂₀₃ include linear alkyl groups having 1 to 10 carbon atoms, branched alkyl groups having 3 to 10 carbon atoms (for example, a methyl group, an ethyl group, a propyl group, a butyl group, and a pentyl group), and cycloalkyl groups having 3 to 10 carbon atoms (for example, a cyclopentyl group, a cyclohexyl group, and a norbornyl group).

R²⁰¹ to R²⁰³ may be further substituted with a halogen atom, an alkoxy group (having, for example, 1 to 5 carbon atoms), a hydroxyl group, a cyano group, or a nitro group.

Hereinafter, the cation (ZI-13) will be described.

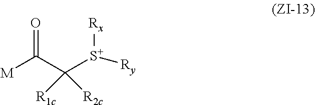

In the general formula (ZI-13), M represents an alkyl group, a cycloalkyl group, or an aryl group, and in the case of having a ring structure, the ring structure may include at least one of an oxygen atom, a sulfur atom, an ester bond, an amide bond, or a carbon-carbon double bond. R_{1c} and R_{2c} each independently represent a hydrogen atom, an alkyl group, a cycloalkyl group, a halogen atom, a cyano group, or an aryl group. R_{1c} and R₂, may be bonded together to form a ring. Rₓ and R_{y} each independently represent an alkyl group, a cycloalkyl group, or an alkenyl group. Rₓ and R_{y} may be bonded together to form a ring. At least two selected from the group consisting of M, R_{1c}, and R_{2c} may be bonded together to form a ring structure, and the ring structure may include a carbon-carbon double bond.

In the general formula (ZI-13), the alkyl group and the cycloalkyl group represented by M are preferably a linear alkyl group having 1 to 15 carbon atoms (preferably 1 to 10 carbon atoms), a branched alkyl group having 3 to 15 carbon atoms (preferably 3 to 10 carbon atoms), or a cycloalkyl group having 3 to 15 carbon atoms (preferably 1 to 10 carbon atoms), and specific examples thereof include a methyl group, an ethyl group, a propyl group, an n-butyl group, a sec-butyl group, a t-butyl group, a cyclopropyl group, a cyclobutyl group, a cyclohexyl group, and a norbornyl group.

The aryl group represented by M is preferably a phenyl group or a naphthyl group, and more preferably a phenyl group. The aryl group may be an aryl group having a heterocyclic structure having an oxygen atom, a sulfur atom, or the like. Examples of the heterocyclic structure include a furan ring, a thiophene ring, a benzofuran ring, and a benzothiophene ring.

M above may further have a substituent. In this case, examples of M include a benzyl group.

Note that, when M has a cyclic structure, the cyclic structure may include at least one of an oxygen atom, a sulfur atom, an ester bond, an amide bond, or a carbon-carbon double bond.

Examples of the alkyl groups, the cycloalkyl groups, and the aryl groups represented by R_{1c} and R_{2c} are the same as those of M described above, and preferred examples thereof are also the same. R_{1c} and R_{2c} may be bonded together to form a ring.

Examples of the halogen atoms represented by R_{1c} and R_{2c} include a fluorine atom, a chlorine atom, a bromine atom, and an iodine atom.

Examples of the alkyl groups and the cycloalkyl groups represented by Rₓ and R_{y} are the same as those of M described above, and preferred examples thereof are also the same.

The alkenyl groups represented by Rₓ and R_{y} are preferably an allyl group or a vinyl group.

Rₓ and R_{y} above may further have a substituent. In this case, examples of Rx and R_{y} include 2-oxoalkyl groups and alkoxycarbonylalkyl groups.

Examples of the 2-oxoalkyl groups represented by Rₓ and R_{y} include those having 1 to 15 carbon atoms (preferably 1 to 10 carbon atoms), and specific examples thereof include a 2-oxopropyl group and a 2-oxobutyl group.

Examples of the alkoxycarbonylalkyl groups represented by Rx and R_{y} include those having 1 to 15 carbon atoms (preferably 1 to 10 carbon atoms). Rx and R_{y} may be bonded together to form a ring.

The ring structure formed by the linking together Rₓ and R_{y} may include an oxygen atom, a sulfur atom, an ester bond, an amide bond, or a carbon-carbon double bond.

In the general formula (ZI-13), M and R_{1c} may be bonded together to form a ring structure, and the formed ring structure may include a carbon-carbon double bond.

In particular, the cation (ZI-13) is preferably a cation (ZI-13A).

The cation (ZI-13A) is a phenacylsulfonium cation represented by the following general formula (ZI-13A).

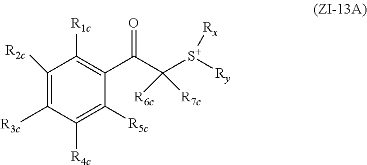

In the general formula (ZI-13A),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} have the same meanings as the above-described R_{1c} and R_{2c} in the general formula (ZI-13), and preferred examples thereof are also the same.

Rₓ and R_{y} have the same meanings as the above-described Rₓ and R_{y} in the general formula (ZI-13), and preferred examples thereof are also the same.

Any two or more among R_{1c} to R_{5c} and Rₓ and R_{y} may be bonded together to form ring structures, and the ring structures may each independently include an oxygen atom, a sulfur atom, an ester bond, an amide bond, or a carbon-carbon double bond. R_{5c} and R_{6c}, and R_{5c} and Rₓ may be bonded together to form ring structures, and the ring structures may each independently include a carbon-carbon double bond. R_{6c} and R_{7c} may be bonded together to form a ring structure.

Examples of the ring structures include aromatic or non-aromatic hydrocarbon rings, aromatic or non-aromatic heterocycles, and polycyclic fused rings that are combinations of two or more of the foregoing rings. Examples of the ring structures include 3- to 10-membered rings, preferred are 4- to 8-membered rings, and more preferred are 5- or 6-membered rings.

Examples of the groups formed by bonding together any two or more among R_{1c} to R_{5c}, R_{6c} and R_{7c}, and Rₓ and R_{y} include a butylene group and a pentylene group.

The groups formed by bonding together R_{5c} and R_{6c}, and R_{5c} and Rₓ are preferably single bonds or alkylene groups. Examples of the alkylene groups include a methylene group and an ethylene group.

Hereinafter, the cation (ZI-14) will be described.

The cation (ZI-14) is represented by the following general formula (ZI-14).

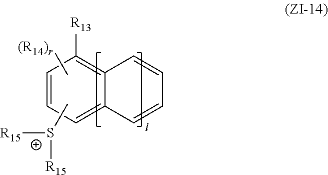

In the general formula (ZI-14),

l represents an integer of 0 to 2.

r represents an integer of 0 to 8.

R₁₃ represents a hydrogen atom, a fluorine atom, a hydroxyl group, an alkyl group, a cycloalkyl group, an alkoxy group, an alkoxycarbonyl group, or a group having a monocyclic or polycyclic cycloalkyl skeleton. These groups may have a substituent.

When a plurality of R₁₄'s are present, R₁₄'s each independently represent an alkyl group, a cycloalkyl group, an alkoxy group, an alkylsulfonyl group, a cycloalkylsulfonyl group, an alkylcarbonyl group, an alkoxycarbonyl group, or an alkoxy group having a monocyclic or polycyclic cycloalkyl skeleton. These groups may have a substituent.

R₁₅'s each independently represent an alkyl group, a cycloalkyl group, or a naphthyl group. These groups may have a substituent. Two R₁₅'s may be bonded together to form a ring. When two R₁₅'s are bonded together to form a ring, the ring skeleton may include a heteroatom such as an oxygen atom or a nitrogen atom. In an example, two R₁₅'s are preferably alkylene groups and bonded together to form a ring structure.

In the general formula (ZI-14), the alkyl groups of R₁₃, R₁₄, and R₁₅ are linear or branched. Such an alkyl group preferably has 1 to 10 carbon atoms. The alkyl group is more preferably a methyl group, an ethyl group, an n-butyl group, a t-butyl group, or the like.

Hereinafter, the general formula (ZIIA) will be described.

In the general formula (ZIIA), R₂₀₄ and R₂₀₅ each independently represent an aryl group, an alkyl group, or a cycloalkyl group.

For R²⁰⁴ and R²⁰⁵, the aryl group is preferably a phenyl group or a naphthyl group, more preferably a phenyl group. For R₂₀₄ and R₂₀₅, the aryl group may be an aryl group having a heterocyclic structure having an oxygen atom, a nitrogen atom, a sulfur atom, or the like. Examples of the skeleton of the aryl group having a heterocyclic structure include pyrrole, furan, thiophene, indole, benzofuran, and benzothiophene.

For R₂₀₄ and R₂₀₅, the alkyl group and the cycloalkyl group are preferably a linear alkyl group having 1 to 10 carbon atoms or a branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, and a norbornyl group).

For R₂₀₄ and R₂₀₅, the aryl group, the alkyl group, and the cycloalkyl group may each independently have a substituent. Examples of substituents that the aryl groups, the alkyl groups, and the cycloalkyl groups of R₂₀₄ to R₂₀₇ may have include alkyl groups (for example, having 1 to 15 carbon atoms), cycloalkyl groups (for example, having 3 to 15 carbon atoms), aryl groups (for example, having 6 to 15 carbon atoms), alkoxy groups (for example, having 1 to 15 carbon atoms), halogen atoms, a hydroxyl group, lactone ring groups, and a phenylthio group.

Examples of the lactone ring groups include a group provided by removing a hydrogen atom from the above-described structure represented by any one of (KA-1-1) to (KA-1-17).

Preferred examples of Mⁿ⁺ (cation) in the general formula (1) will be described below; however, the present invention is not limited thereto. Me represents a methyl group, and Bu represents an n-butyl group.

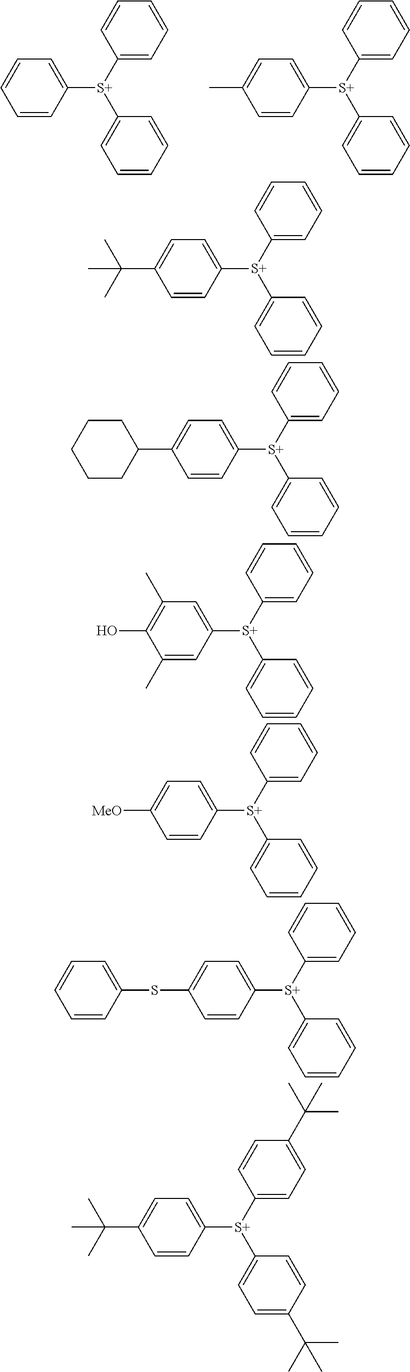

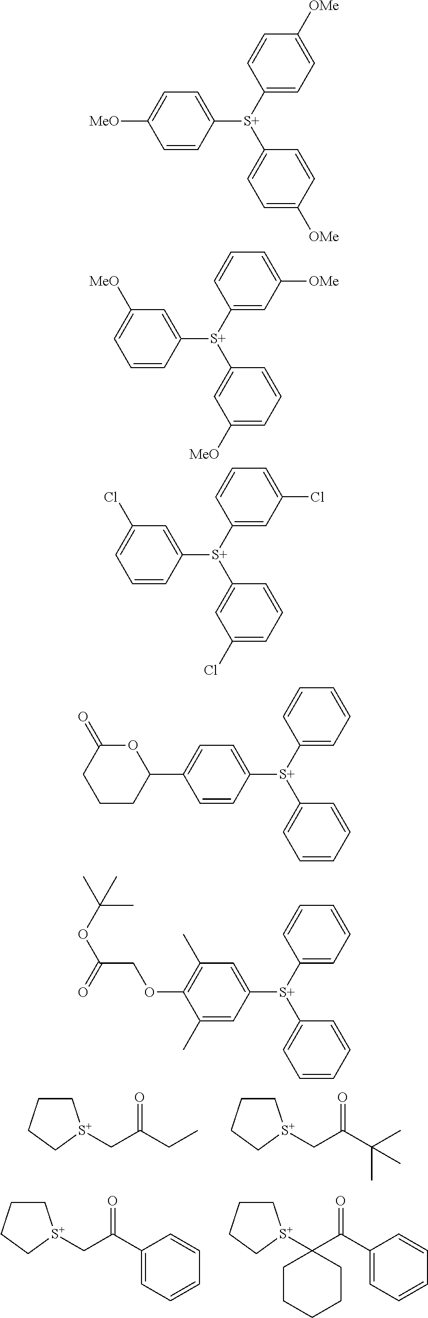

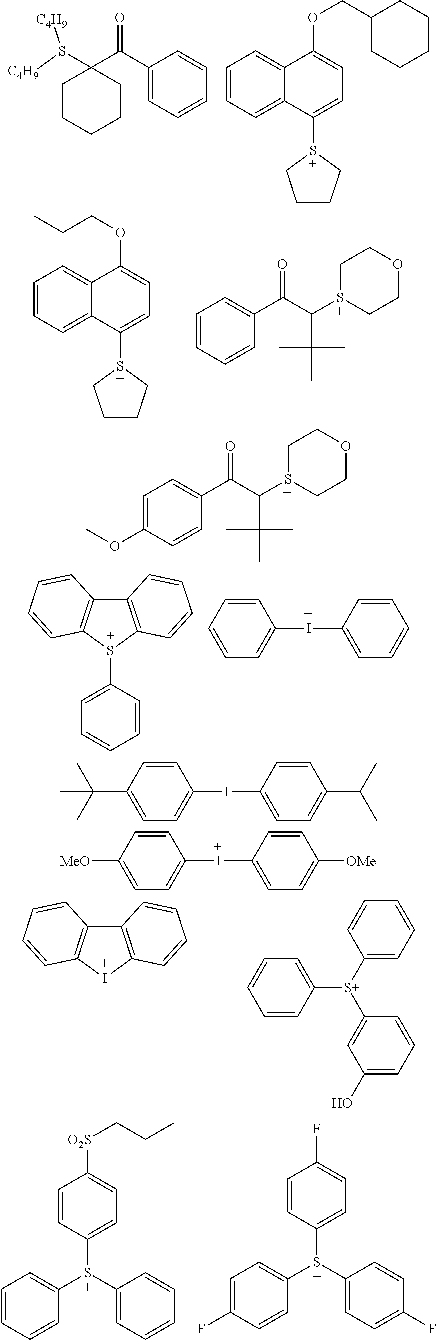

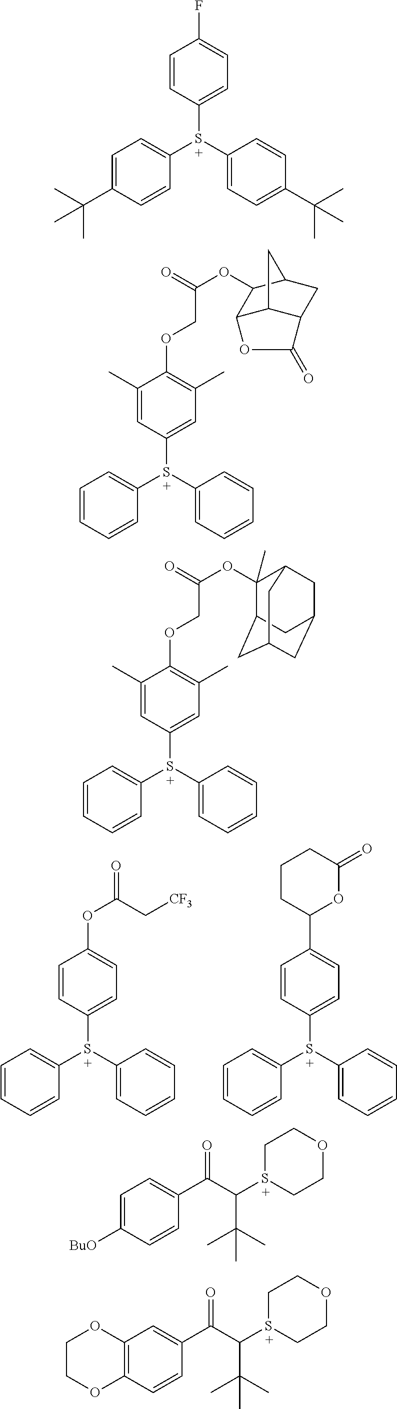

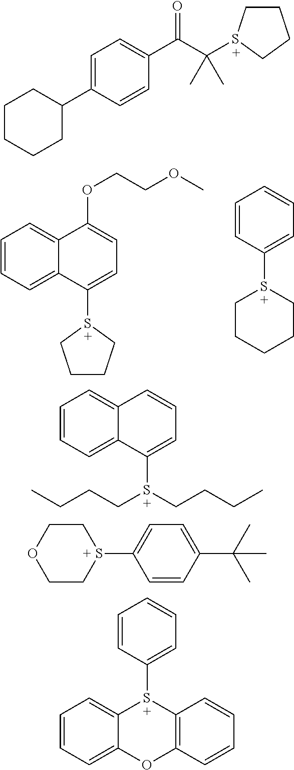

Preferred examples of the anionic moiety in the general formula (1) will be described below; however, the present invention is not limited thereto. Me represents a methyl group.

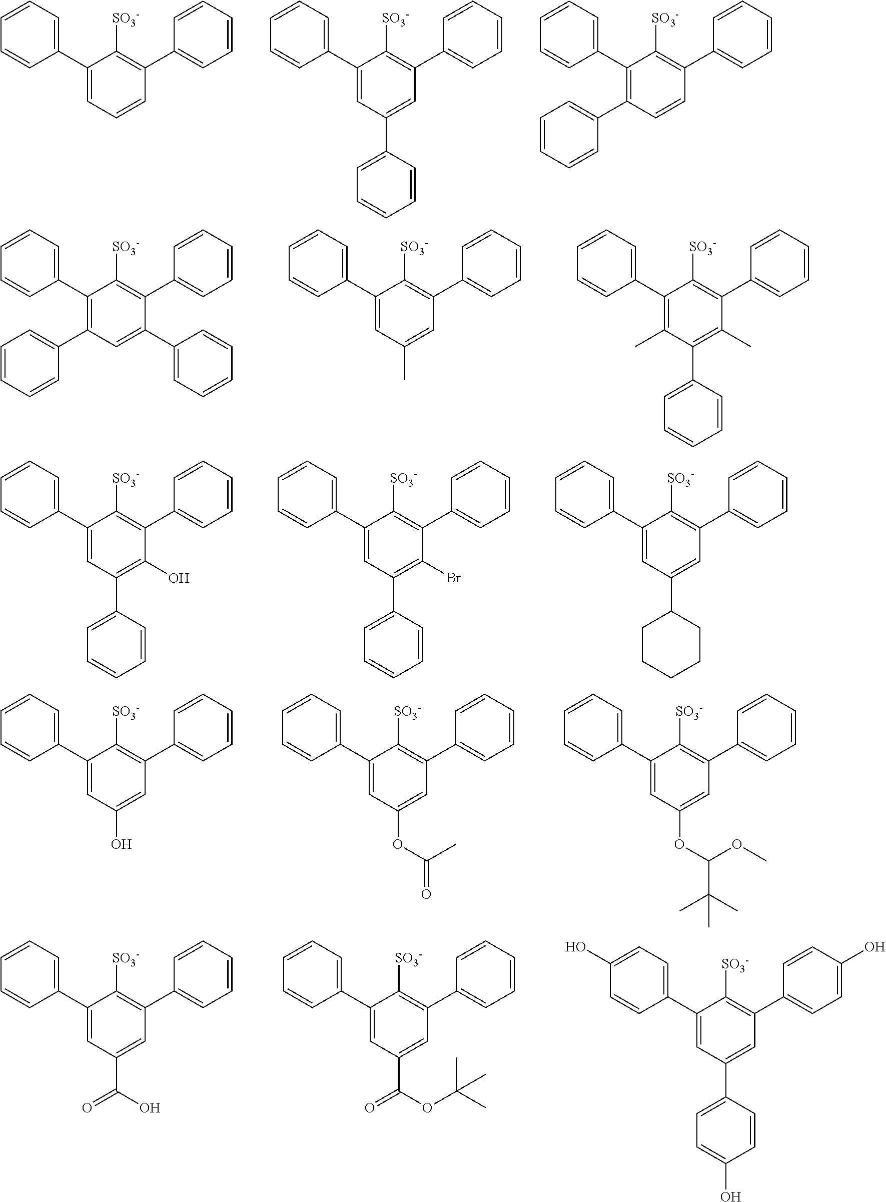

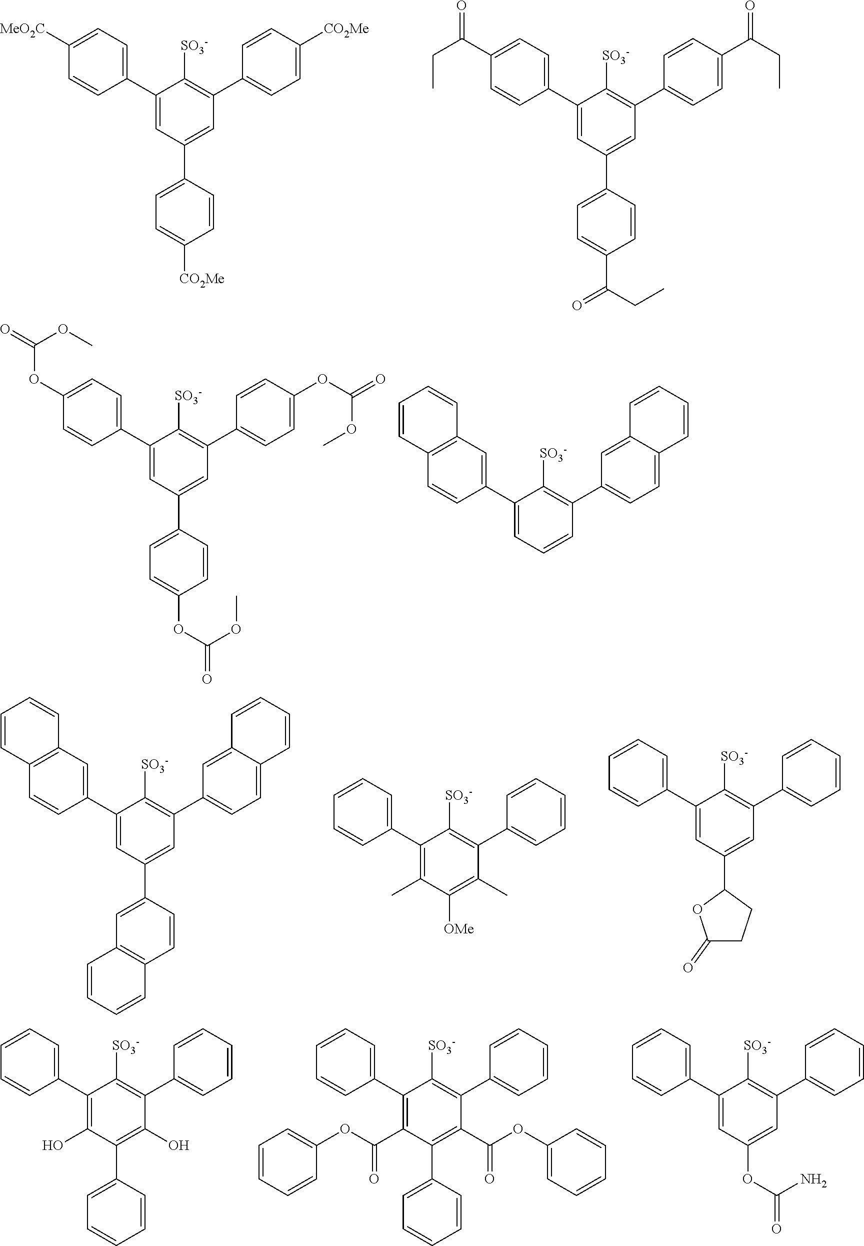

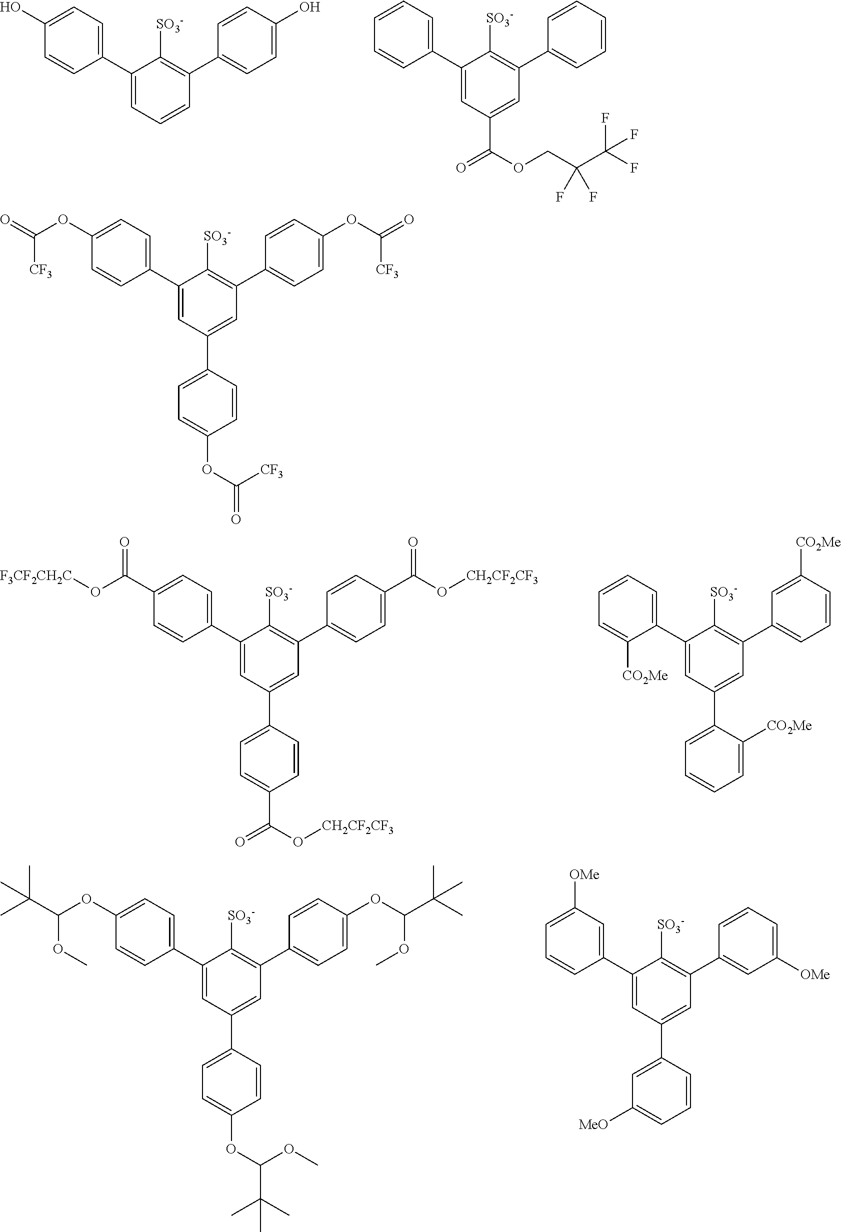

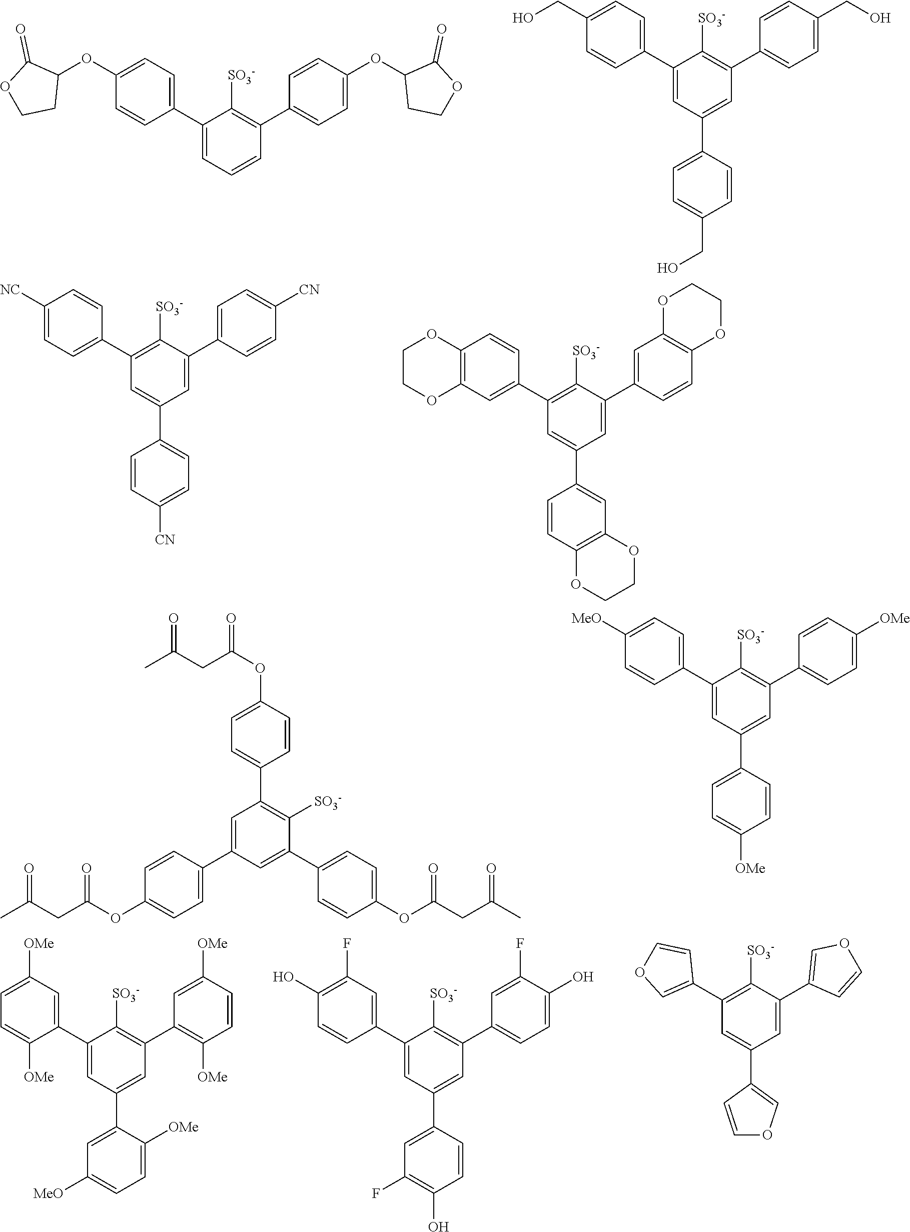

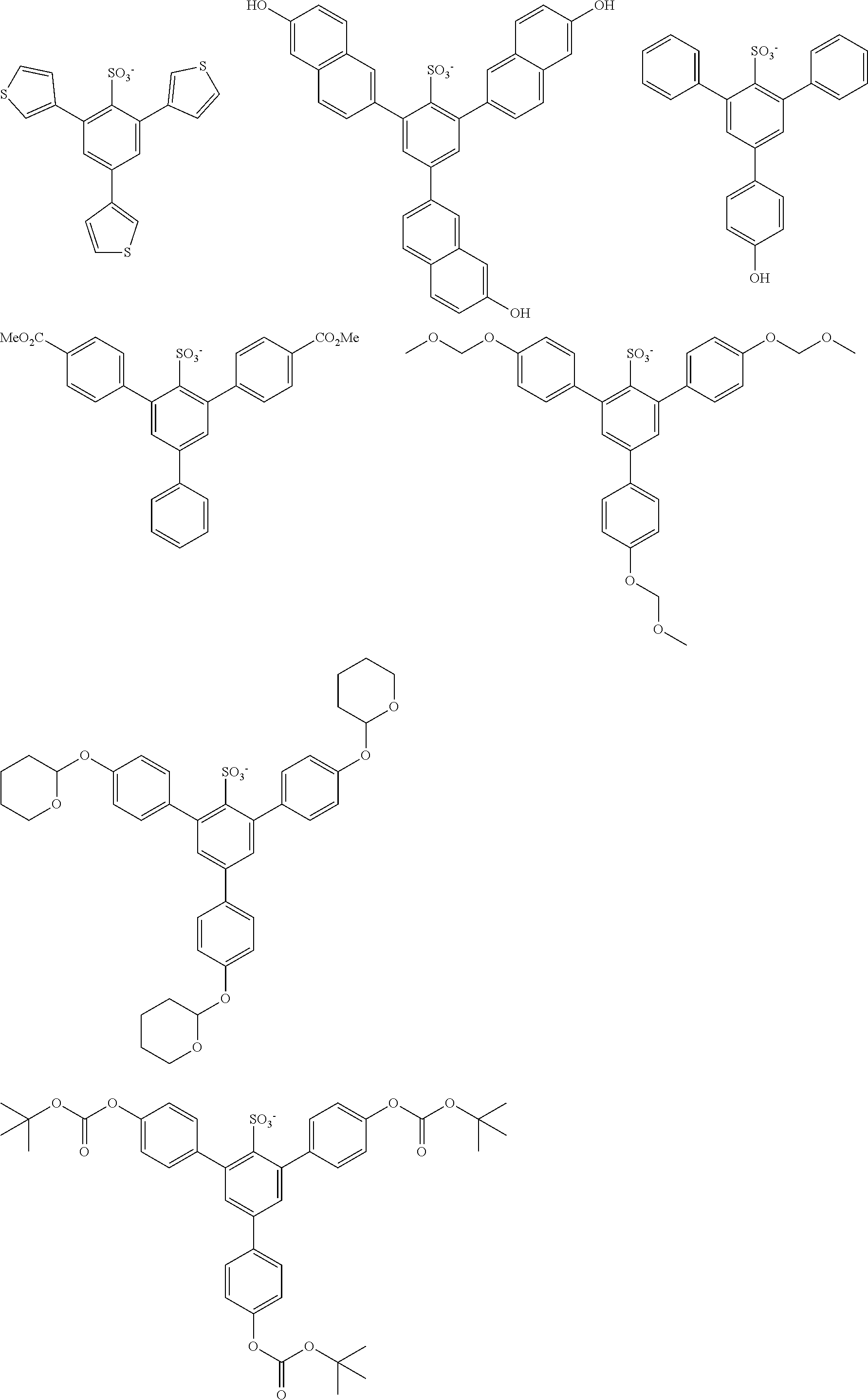

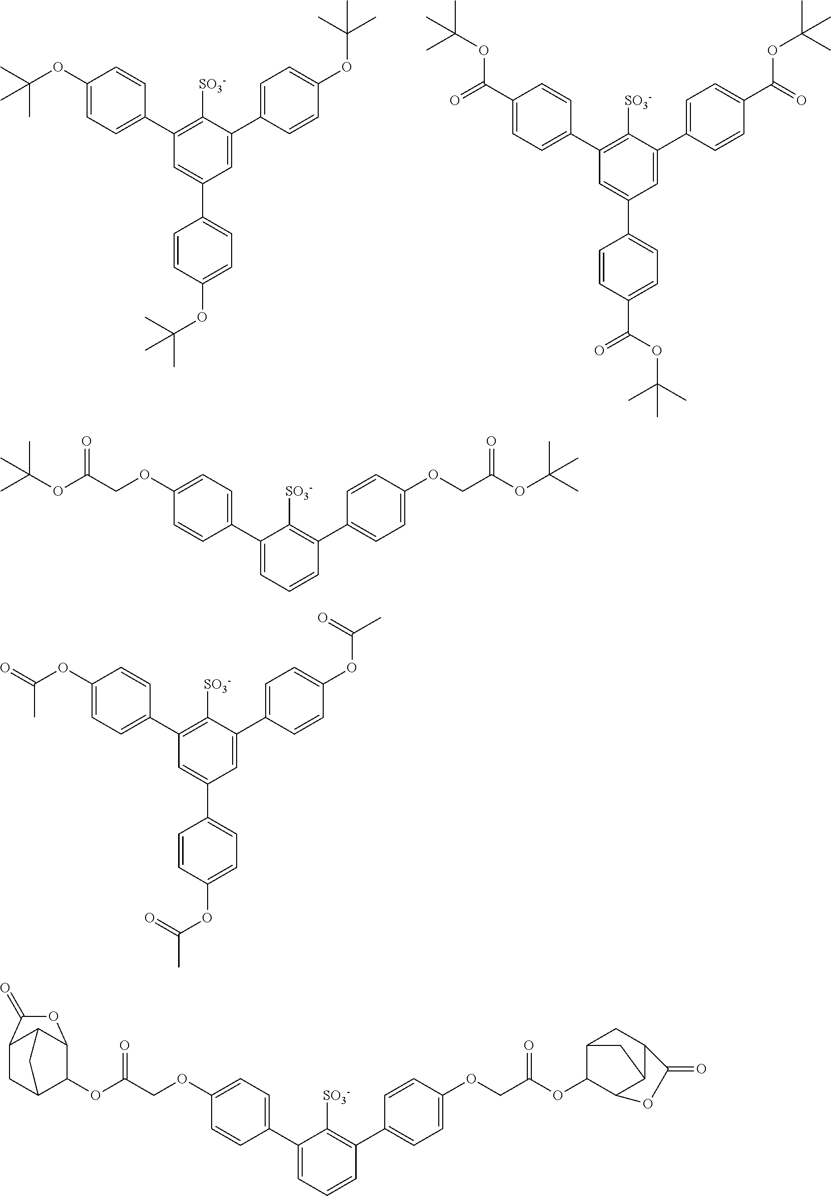

The acid generated from the compound (B) preferably has a pKa of −10 or more and 5 or less.

Preferred examples of the compound (B) will be described below; however, the present invention is not limited thereto. Me represents a methyl group. Preferred examples of the compound (B) also include compounds provided by combining the above-described anions with the above-described cations.

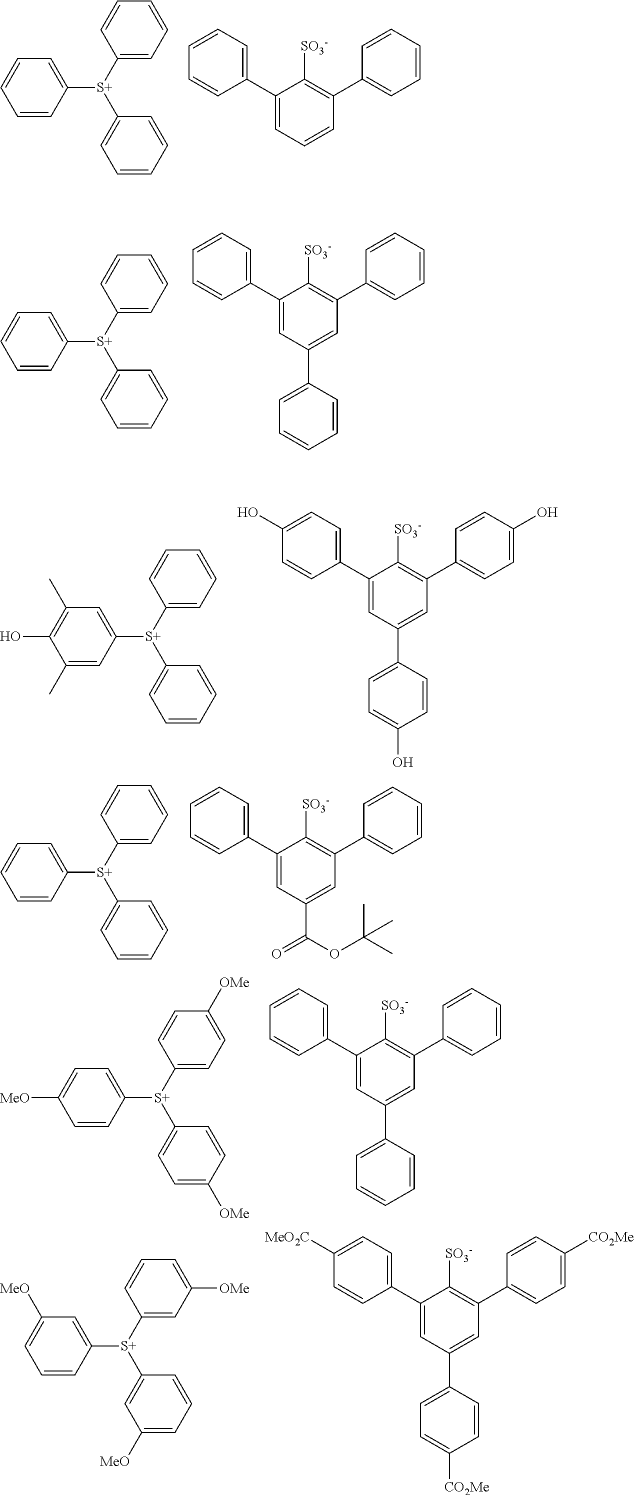

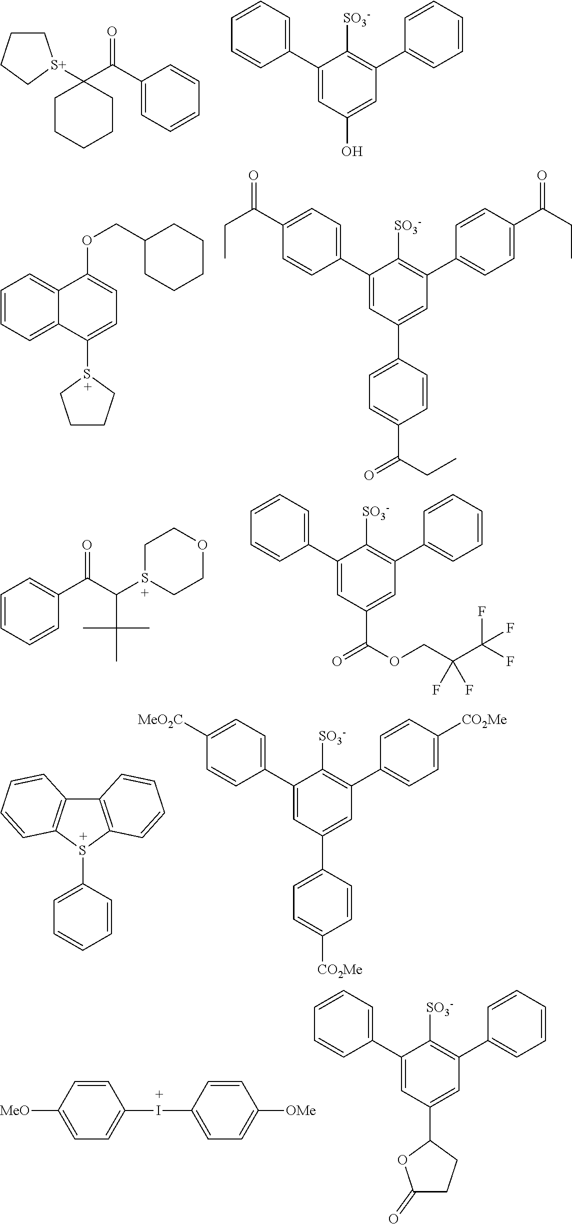

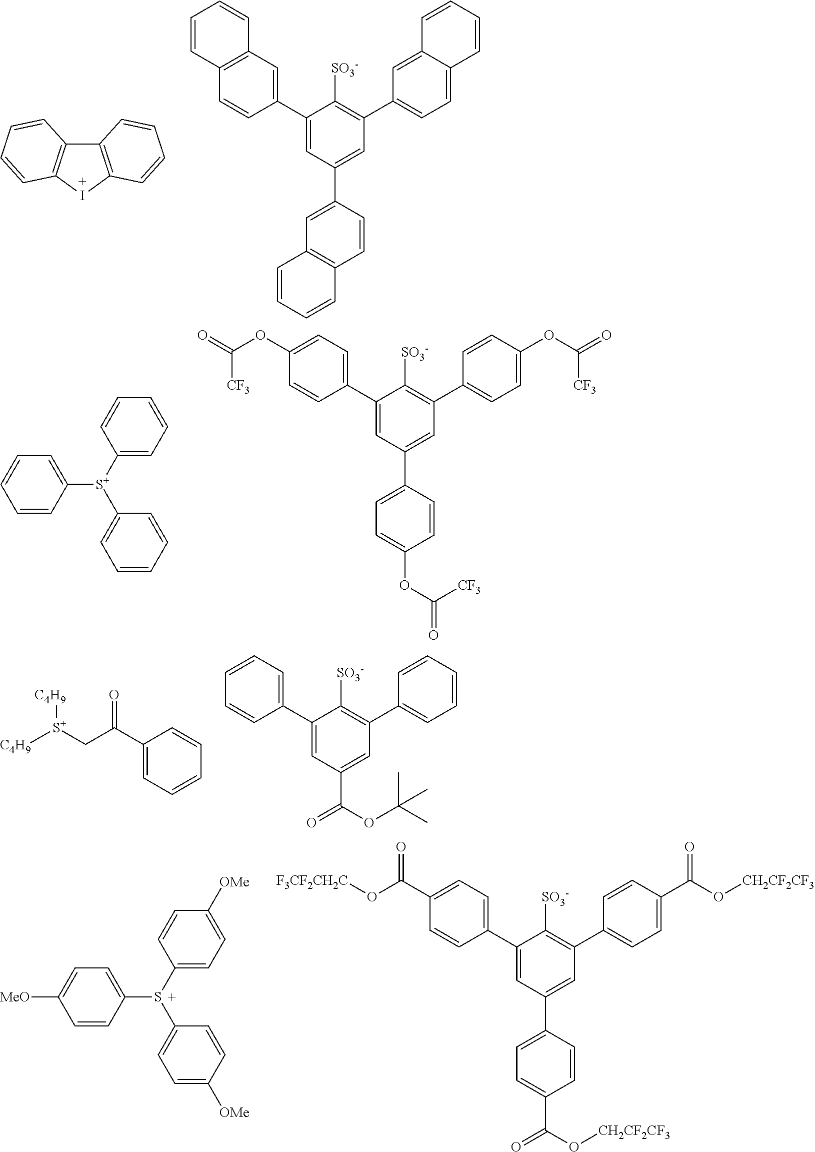

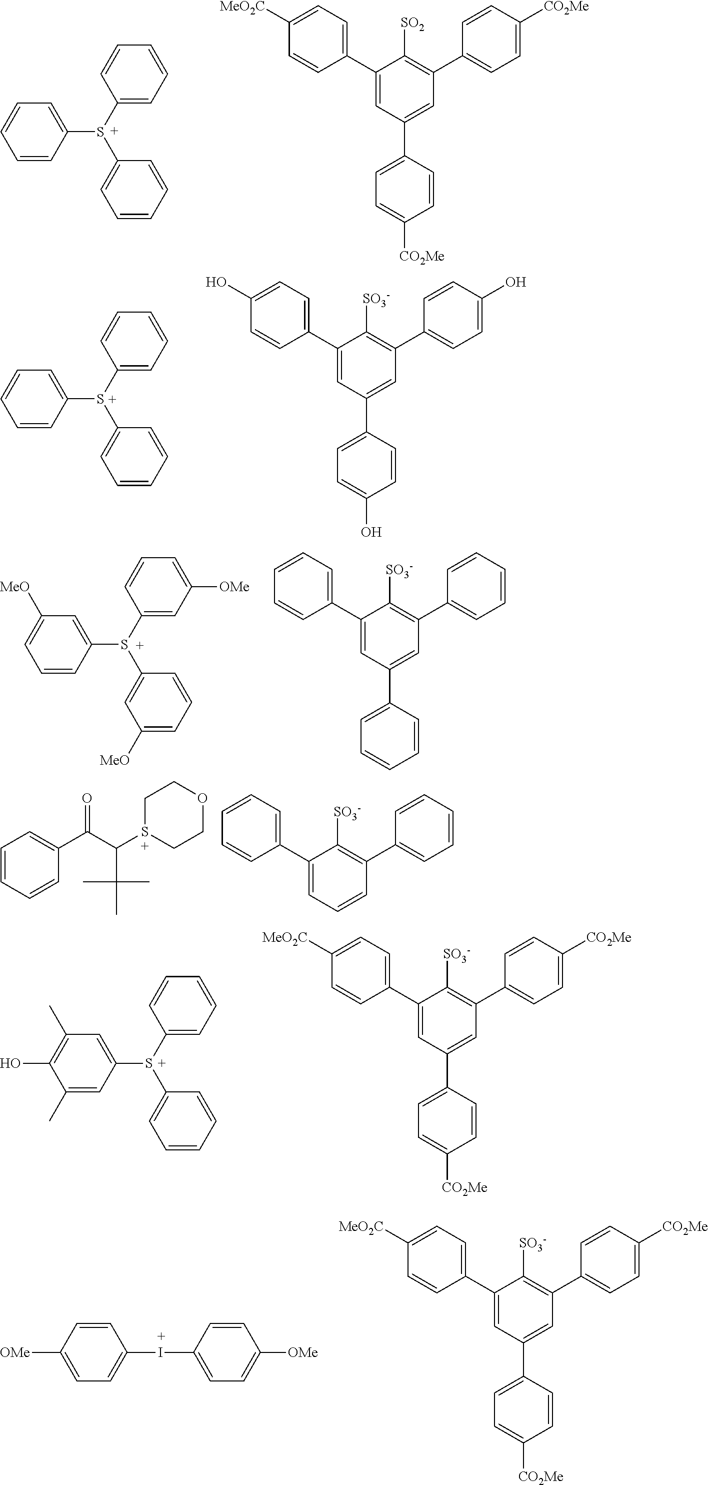

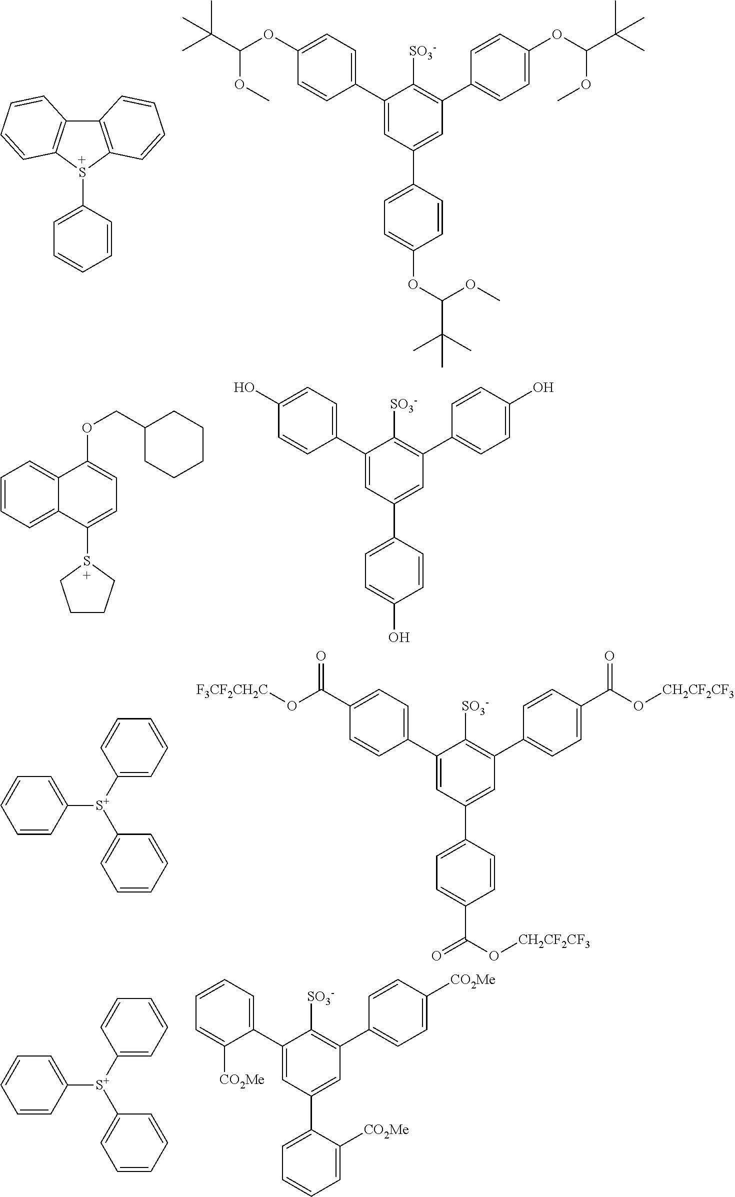

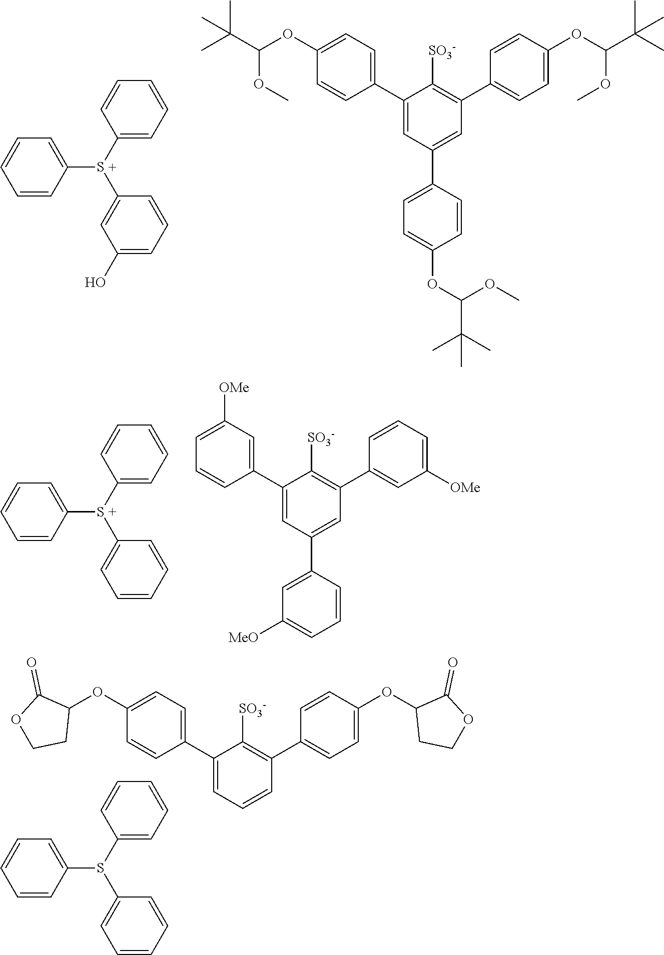

The compound (B) can be synthesized by, for example, a method using a coupling reaction.

For the coupling reaction, for example, Suzuki coupling or the like can be applied. The counter cation can be converted into a desired cation M⁺ by, for example, as described in JP1994-184170A (JP-H6-184170A) or the like, the publicly known anion exchange method or conversion method using an ion exchange resin.

The coupling reaction may be, for example, as follows.

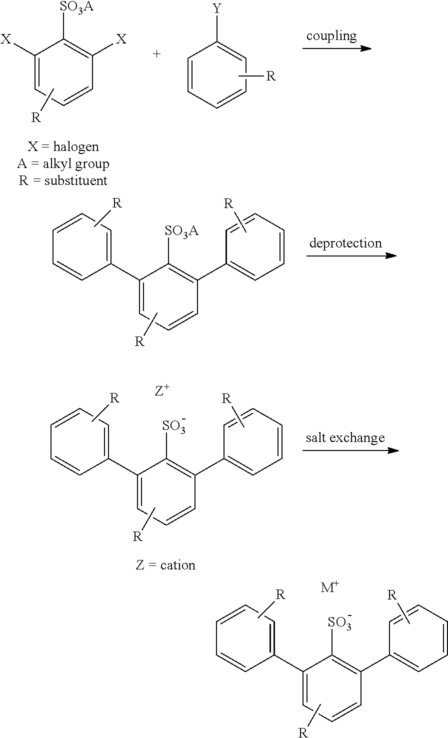

X represents a halogen atom, and A represents an alkyl group. R represents a substituent.

Y represents a group that forms a compound XY as a result of the coupling reaction.

Such compounds (B) may be used alone or in combination of two or more thereof.

In the composition of the present invention, the content of the compound (B) (when a plurality of the compounds (B) are present, the total content thereof) is, relative to the total solid content of the composition, preferably 0.1 to 35 mass %, more preferably 0.5 to 25 mass %, still more preferably 1 to 20 mass %, and particularly preferably 5 to 20 mass %.

(B′) Compound, Other than the Compound (B), that Generates Acid Upon Irradiation with Actinic Ray or Radiation

The composition of the present invention may contain a compound, other than the compound (B), that generates an acid upon irradiation with an actinic ray or a radiation as long as advantages of the present invention are not impaired.

### Acid Diffusion Control Agent

The composition of the present invention preferably contains an acid diffusion control agent. The acid diffusion control agent acts as a quencher that traps an acid generated from a photoacid generator or the like upon exposure and suppresses the reaction of the acid decomposable resin in the unexposed regions due to an excess of the generated acid.

For the acid diffusion control agent, for example, a basic compound (DA), a basic compound (DB) that undergoes reduction or loss of the basicity upon irradiation with an actinic ray or a radiation, an onium salt (DC) that serves as a weak acid relative to the acid generator, a low molecular weight compound (DD) having a nitrogen atom and having a group that leaves by the action of an acid, or an onium salt compound (DE) having a nitrogen atom in the cationic moiety can be used as the acid diffusion control agent. In the composition of the present invention, a publicly known acid diffusion control agent can be appropriately used. For example, publicly known compounds disclosed in paragraphs [0627] to [0664] of US2016/0070167A1, paragraphs [0095] to [0187] of US2015/0004544A1, paragraphs [0403] to [0423] of US2016/0237190A1, and paragraphs [0259] to [0328] of US2016/0274458A1 can be suitably used as the acid diffusion control agent.

As the basic compound (DA), compounds having structures represented by the following general formulas (A) to (E) are preferred.

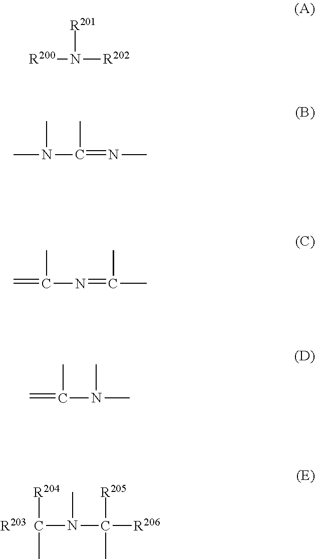

In the general formulas (A) and (E),

R²⁰⁰, R²⁰¹, and R²⁰² may be the same or different, and each independently represent a hydrogen atom, an alkyl group (preferably having 1 to 20 carbon atoms), a cycloalkyl group (preferably having 3 to 20 carbon atoms), or an aryl group (having 6 to 20 carbon atoms); R²⁰¹ and R²⁰² may be bonded together to form a ring; and

R²⁰³, R²⁰⁴, R²⁰⁵, and R²⁰⁶ may be the same or different, and each independently represent an alkyl group having 1 to 20 carbon atoms.

The alkyl groups in the general formulas (A) and (E) may have a substituent or may be unsubstituted.

For such an alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in the general formulas (A) and (E) are more preferably unsubstituted.

The basic compound (DA) is preferably thiazole, benzothiazole, oxazole, benzoxazole, guanidine, aminopyrrolidine, pyrazole, pyrazoline, piperazine, aminomorpholine, aminoalkylmorpholine, piperidine, or a compound having such a structure, and more preferably, for example, a compound having a thiazole structure, a benzothiazole structure, an oxazole structure, a benzoxazole structure, an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, or an aniline derivative having a hydroxyl group and/or an ether bond.

The basic compound (DB) that undergoes reduction or loss of the basicity upon irradiation with an actinic ray or a radiation (hereinafter, also referred to as “compound (DB)”) is a compound that has a proton acceptor functional group and is decomposed upon irradiation with an actinic ray or a radiation to undergo reduction or loss of the proton acceptor property or change from the proton acceptor property to acidity.

The proton acceptor functional group is a group that electrostatically interacts with a proton or a functional group having an electron, and means, for example, a functional group having a macrocyclic structure such as cyclic polyether, or a functional group having a nitrogen atom having an unshared electron pair that does not contribute to π-conjugation. The nitrogen atom having an unshared electron pair that does not contribute to π-conjugation is, for example, nitrogen atoms having partial structures represented by the following formulas.

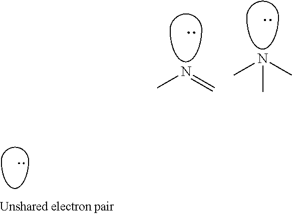

Preferred examples of the partial structure of the proton acceptor functional group include crown ether structures, azacrown ether structures, primary to tertiary amine structures, a pyridine structure, an imidazole structure, and a pyrazine structure.

The compound (DB) is decomposed upon irradiation with an actinic ray or a radiation to generate a compound that has undergone reduction or loss of the proton acceptor property or change from the proton acceptor property to acidity. The phrase “reduction or loss of the proton acceptor property or change from the proton acceptor property to acidity” is a change in the proton acceptor property caused by the addition of a proton to the proton acceptor functional group, and specifically means that, when a proton adduct is generated from the compound (DB) having a proton acceptor functional group and a proton, the equilibrium constant in the chemical equilibrium decreases.

The proton acceptor property can be confirmed by pH measurement.

The compound generated as a result of decomposition of the compound (DB) upon irradiation with an actinic ray or a radiation has an acid dissociation constant pKa that preferably satisfies pKa<−1, more preferably satisfies −13<pKa<−1, and still more preferably satisfies −13<pKa<−3.

In the composition of the present invention, the onium salt (DC) that serves as a weak acid relative to the photoacid generator can be used as an acid diffusion control agent.

In such a case of using a mixture of the photoacid generator and the onium salt that generates an acid that is weak relative to the acid generated from the photoacid generator, when the acid generated from the photoacid generator upon irradiation with an actinic ray or a radiation collides with the onium salt having an unreacted weak acid anion, the weak acid is released by salt exchange to generate an onium salt having a strong acid anion. In this process, the strong acid is exchanged with the weak acid having a lower catalytic activity, so that the acid is apparently deactivated and the acid diffusion can be controlled.

As the onium salt that serves as a weak acid relative to the photoacid generator, preferred are compounds represented by the following general formulas (d1-1) to (d1-3).

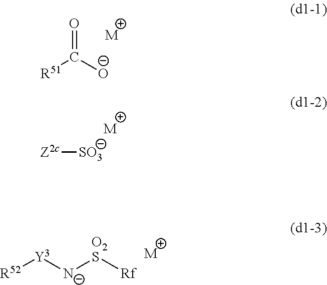

In the formulas, R⁵¹ is a hydrocarbon group that may have a substituent, Z^{2c} is a hydrocarbon group that may have a substituent and has 1 to 30 carbon atoms (with the proviso that the carbon atom adjacent to S is not substituted with fluorine atoms), R⁵² is an organic group, Y³ is a linear, branched, or cyclic alkylene group or an arylene group, Rf is a hydrocarbon group including a fluorine atom, and M⁺'s are each independently an ammonium cation, a sulfonium cation, or an iodonium cation.

Preferred examples of the sulfonium cation or the iodonium cation represented by M⁺ include the sulfonium cation exemplified in the general formula (ZI) and the iodonium cation exemplified in the general formula (ZII).

The onium salt (DC) that serves as a weak acid relative to the photoacid generator may be a compound (hereinafter, also referred to as “compound (DCA)”) that has a cationic moiety and an anionic moiety in the same molecule and in which the cationic moiety and the anionic moiety are linked together via a covalent bond.

The compound (DCA) is preferably a compound represented by any one of the following general formulas (C-1) to (C-3).

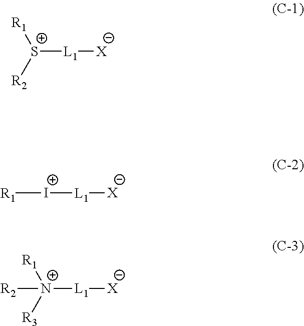

In the general formulas (C-1) to (C-3),

R₁, R₂, and R₃ each independently represent a substituent having 1 or more carbon atoms.

L₁ represents a divalent linking group or a single bond that links together the cationic moiety and the anionic moiety.

—X⁻ represents an anionic moiety selected from the group consisting of —COO⁻, —SO₃⁻, —SO₂⁻, and —N⁻—R₄. R₄ represents a monovalent substituent having, at the linking site to the adjacent N atom, at least one of a carbonyl group (—C(═O)—), a sulfonyl group (—S(═O)₂—), or a sulfinyl group (—S(═O)—).

R₁, R₂, R₃, R₄, and L₁ may be bonded together to form a ring structure. In the general formula (C-3), two among R₁ to R₃ may collectively represent a single divalent substituent, and may be bonded to the N atom via a double bond.

For R₁ to R₃, examples of the substituent having 1 or more carbon atoms include alkyl groups, cycloalkyl groups, aryl groups, alkyloxycarbonyl groups, cycloalkyloxycarbonyl groups, aryloxycarbonyl groups, alkylaminocarbonyl groups, cycloalkylaminocarbonyl groups, and arylaminocarbonyl groups. Preferred are alkyl groups, cycloalkyl groups, and aryl groups.

Examples of L₁ serving as a divalent linking group include linear or branched alkylene groups, cycloalkylene groups, arylene groups, a carbonyl group, an ether bond, an ester bond, an amide bond, a urethane bond, a urea bond, and groups that are combinations of two or more of the foregoing. L₁ is preferably an alkylene group, an arylene group, an ether bond, an ester bond, or a group that is a combination of two or more of the foregoing.

The low molecular weight compound (DD) having a nitrogen atom and having a group that leaves by the action of an acid (hereinafter, also referred to as “compound (DD)”) is preferably an amine derivative having, on the nitrogen atom, a group that leaves by the action of an acid.

The group that leaves by the action of an acid is preferably an acetal group, a carbonate group, a carbamate group, a tertiary ester group, a tertiary hydroxyl group, or a hemiaminal ether group, and more preferably a carbamate group or a hemiaminal ether group.

The molecular weight of the compound (DD) is preferably 100 to 1,000, more preferably 100 to 700, and still more preferably 100 to 500.

The compound (DD) may have, on the nitrogen atom, a carbamate group having a protecting group. The protecting group constituting the carbamate group is represented by the following general formula (d-1).

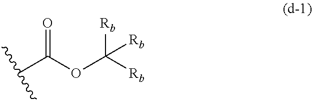

In the general formula (d-1),

Rb's each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). Rb's may be bonded together to form a ring.

The alkyl groups, the cycloalkyl groups, the aryl groups, and the aralkyl groups represented by Rb's may each independently be substituted with a functional group such as a hydroxyl group, a cyano group, an amino group, a pyrrolidino group, a piperidino group, a morpholino group, or an oxo group, an alkoxy group, or a halogen atom. The same applies to the alkoxyalkyl groups represented by Rb's.

Rb is preferably a linear or branched alkyl group, a cycloalkyl group, or an aryl group, and more preferably a linear or branched alkyl group or a cycloalkyl group.

Examples of the ring formed by linking together two Rb's include alicyclic hydrocarbons, aromatic hydrocarbons, heterocyclic hydrocarbons, and derivatives of the foregoing.

Specific examples of the structure of the group represented by the general formula (d-1) include, but are not limited to, the structures disclosed in paragraph [0466] of US2012/0135348A1.

The compound (DD) preferably has a structure represented by the following general formula (6).

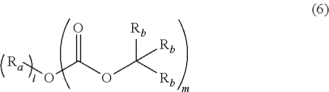

In the general formula (6),

l represents an integer of 0 to 2, m represents an integer of 1 to 3, and 1+m=3 is satisfied.

Ra represents a hydrogen atom, an alkyl group, a cycloalkyl group, an aryl group, or an aralkyl group. When 1 is 2, two Ra's may be the same or different, and two Ra's may be linked together to form a heterocycle together with the nitrogen atom in the formula. The heterocycle may include a heteroatom other than the nitrogen atom in the formula.

Rb has the same definition as Rb in the above-described general formula (d-1), and preferred examples thereof are also the same.

In the general formula (6), the alkyl group, the cycloalkyl group, the aryl group, and the aralkyl group serving as Ra may each independently be substituted with the same groups as the groups described above as the groups with which the alkyl group, the cycloalkyl group, the aryl group, and the aralkyl group serving as Rb's may be substituted.

For Ra above, specific examples of the alkyl group, the cycloalkyl group, the aryl group, and the aralkyl group (these groups may be substituted with the above-described groups) include the same groups as the specific examples described above for Rb.

Particularly preferred, specific examples of the compound (DD) in the present invention include, but are not limited to, the compounds disclosed in paragraph [0475] of US2012/0135348A1.

The onium salt compound (DE) having a nitrogen atom in the cationic moiety (hereinafter, also referred to as “compound (DE)”) is preferably a compound having a basic moiety including a nitrogen atom in the cationic moiety. The basic moiety is preferably an amino group, and more preferably an aliphatic amino group. Still more preferably, all of the atoms adjacent to the nitrogen atom in the basic moiety are hydrogen atoms or carbon atoms. From the viewpoint of improving basicity, an electron-withdrawing functional group (a carbonyl group, a sulfonyl group, a cyano group, a halogen atom, or the like) is preferably not directly bonded to the nitrogen atom.

Specific preferred examples of the compound (DE) include, but are not limited to, the compounds disclosed in paragraph [0203] of US2015/0309408A1.

Preferred examples of the acid diffusion control agent will be described below; however, the present invention is not limited thereto. Me represents a methyl group.

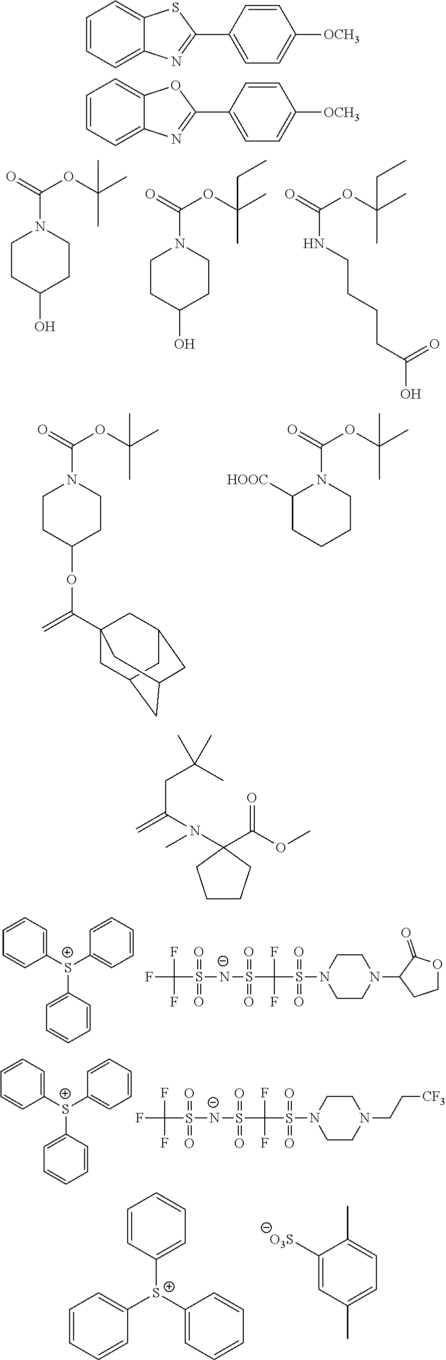

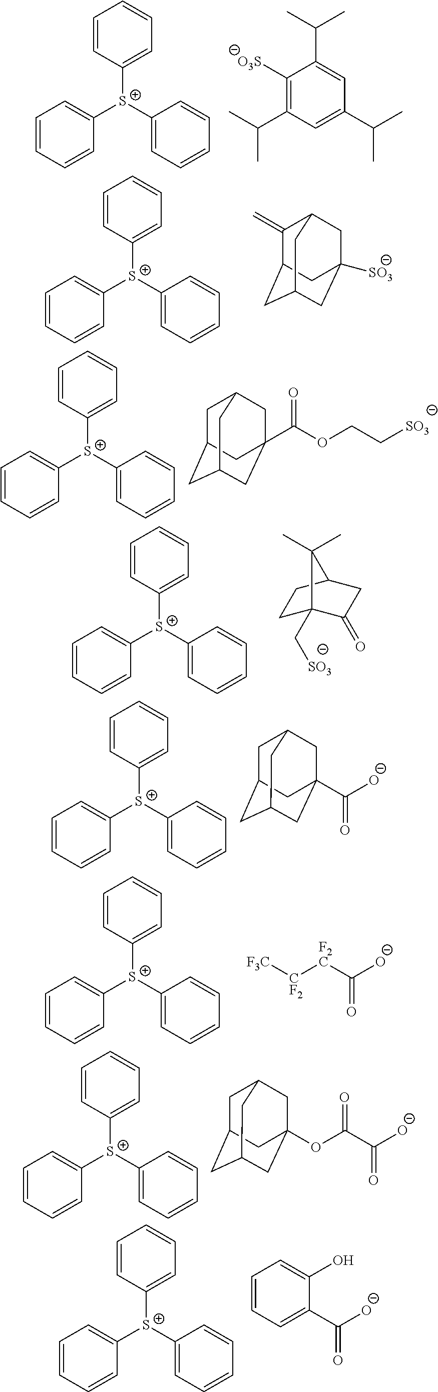

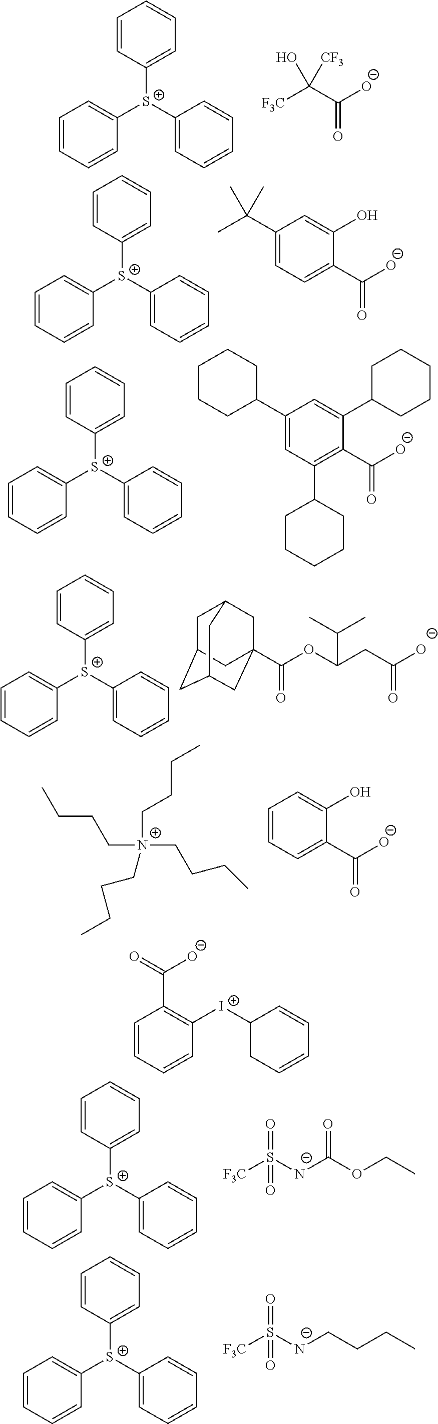

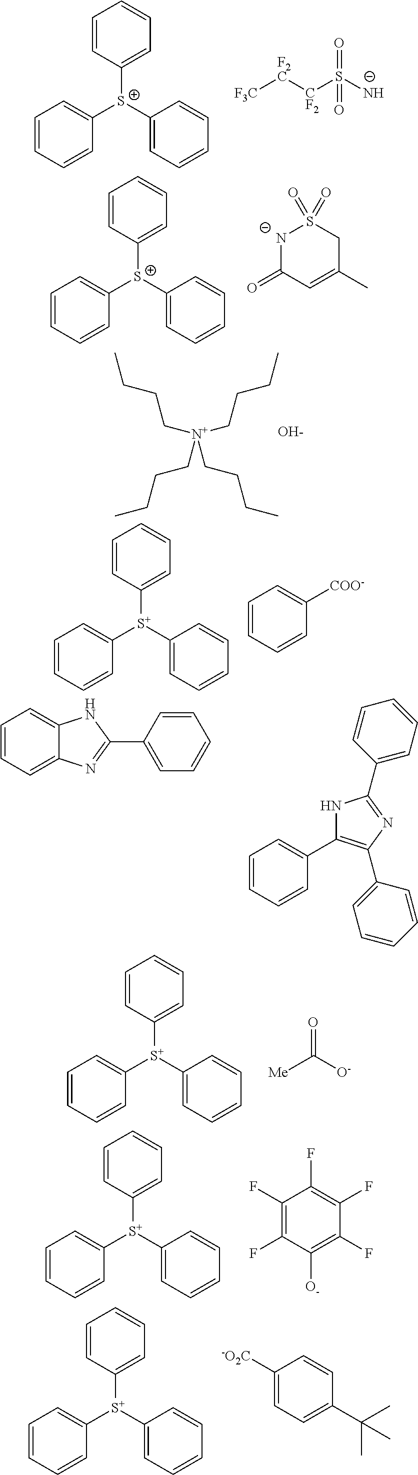

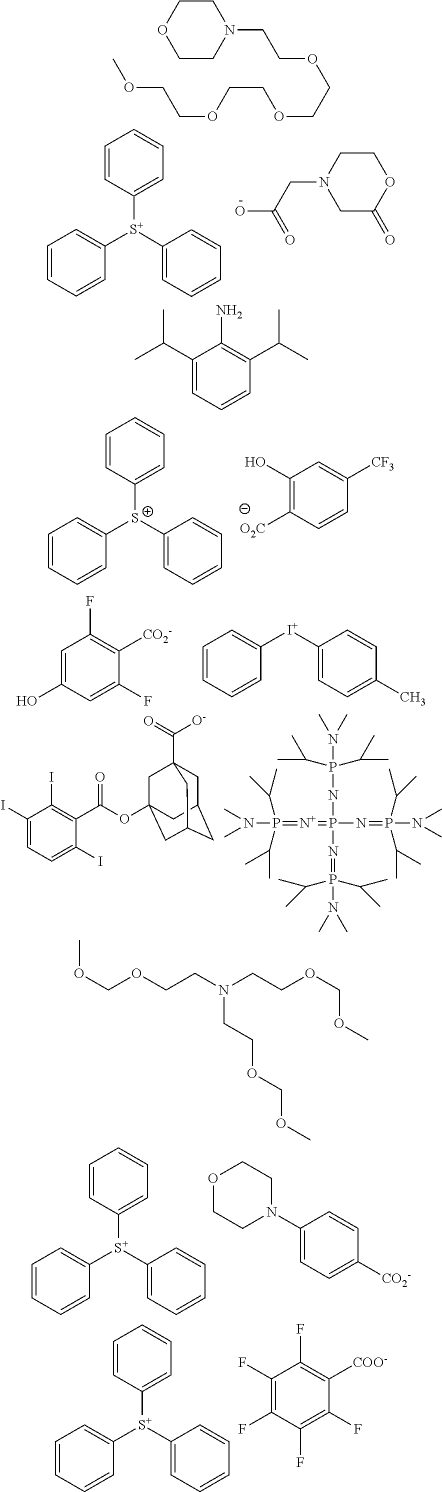

In the composition of the present invention, such acid diffusion control agents may be used alone or in combination of two or more thereof.

The content of the acid diffusion control agent in the composition of the present invention (in the case where a plurality of acid diffusion control agents are present, the total content thereof) is, relative to the total solid content of the composition, preferably 0.001 to 20 mas and more preferably 0.01 to 10 mass %.

### Solvent

The composition of the present invention preferably contains a solvent.

In the composition of the present invention, a publicly known resist solvent can be appropriately used. For example, publicly known solvents disclosed in paragraphs [0665] to [0670] of US2016/0070167A1, paragraphs [0210] to [0235] of US2015/0004544A1, paragraphs [0424] to [0426] of US2016/0237190A1, and paragraphs [0357] to [0366] of US2016/0274458A1 can be suitably used.

Examples of the solvent that can be used in the preparation of the composition include organic solvents such as alkylene glycol monoalkyl ether carboxylates, alkylene glycol monoalkyl ethers, alkyl lactates, alkyl alkoxypropionates, cyclic lactones (preferably having 4 to 10 carbon atoms), monoketone compounds (preferably having 4 to 10 carbon atoms) that may have a ring, alkylene carbonates, alkyl alkoxyacetates, and alkyl pyruvates.

As such an organic solvent, a mixed solvent provided by mixing together a solvent having a hydroxyl group in the structure and a solvent not having a hydroxyl group may be used. The solvent having a hydroxyl group and the solvent not having a hydroxyl group can be appropriately selected from the group consisting of the above-described exemplary compounds, but the solvent including a hydroxyl group is preferably an alkylene glycol monoalkyl ether, an alkyl lactate, or the like, and more preferably propylene glycol monomethyl ether (PGME: 1-methoxy-2-propanol), propylene glycol monoethyl ether (PGEE), methyl 2-hydroxyisobutyrate, or ethyl lactate. The solvent not having a hydroxyl group is preferably, for example, an alkylene glycol monoalkyl ether acetate, an alkylalkoxypropionate, a monoketone compound that may have a ring, a cyclic lactone, or an alkyl acetate; of these, more preferred are propylene glycol monomethyl ether acetate (PGMEA: 1-methoxy-2-acetoxypropane), ethyl ethoxypropionate, 2-heptanone, γ-butyrolactone, cyclohexanone, cyclopentanone, or butyl acetate; still more preferred is propylene glycol monomethyl ether acetate, γ-butyrolactone, ethyl ethoxypropionate, cyclohexanone, cyclopentanone, or 2-heptanone. The solvent not having a hydroxyl group is also preferably propylene carbonate.

The mixing ratio (mass ratio) of the solvent having a hydroxyl group and the solvent not having a hydroxyl group is 1/99 to 99/1, preferably 10/90 to 90/10, and more preferably 20/80 to 60/40. A mixed solvent containing 50 mass % or more of a solvent not having a hydroxyl group is preferred from the viewpoint of coating uniformity.

The solvent preferably contains propylene glycol monomethyl ether acetate, and may be a single solvent of propylene glycol monomethyl ether acetate or may be a mixed solvent of two or more solvents containing propylene glycol monomethyl ether acetate.

### Surfactant

The composition of the present invention may include a surfactant. When a surfactant is contained, use of an exposure light source having a wavelength of 250 nm or less, particularly 220 nm or less, can form, at high sensitivity and at high resolution, a pattern with less adhesiveness and less development defects.

The surfactant employed is particularly preferably a fluorine-based and/or silicone-based surfactant.

Examples of the fluorine-based and/or silicone-based surfactants include the surfactants described in [0276] of US2008/0248425A. Alternatively, also usable is EFTOP EF301 or EF303 (manufactured by Shin Akita Chemicals Corp.); Fluorad FC430, 431, or 4430 (manufactured by Sumitomo 3m Limited); MEGAFACE F171, F173, F176, F189, F113, F110, F177, F120, or R₀₈ (manufactured by DIC Corporation); SURFLON S-382, SC101, 102, 103, 104, 105, or 106 (manufactured by Asahi Glass Co., Ltd.); Troysol S-366 (manufactured by Troy Chemical Corporation); GF-300 or GF-150 (manufactured by TOAGOSEI CO., LTD.); SURFLON S-393 (manufactured by Seimi Chemical Co., Ltd.); EFTOP EF121, EF122A, EF122B, RF122C, EF125M, EF135M, EF351, EF352, EF801, EF802, or EF601 (manufactured by JEMCO Inc.); PF636, PF656, PF6320, or PF6520 (manufactured by OMNOVA Solutions Inc.); or FTX-204G, 208G, 218G, 230G, 204D, 208D, 212D, 218D, or 222D (manufactured by NEOS COMPANY LIMITED). Note that polysiloxane polymer KP-341 (manufactured by Shin-Etsu Chemical Co., Ltd.) can also be used as the silicone-based surfactant.

In addition to the above-described publicly known surfactants, the surfactant may be synthesized using a fluoroaliphatic compound produced by the telomerization method (also referred to as the telomer method) or the oligomerization method (also referred to as the oligomer method). Specifically, a polymer including a fluoroaliphatic group derived from the fluoroaliphatic compound may be used as the surfactant. The fluoroaliphatic compound can be synthesized by, for example, the method described in JP2002-90991A.

The surfactants that are described in [0280] of US2008/0248425A and are not fluorine-based and/or silicone-based surfactants may also be used.

These surfactants may be used alone or in combination of two or more thereof.

When the composition of the present invention includes a surfactant, the content thereof relative to the total solid content of the resist composition is preferably 0.00001 to 2 mass %, more preferably 0.0001 to 2 mass %, and still more preferably 0.0005 to 1 mass %.

### Other Additives

In addition to the above-described components, the composition of the present invention may appropriately contain a carboxylic acid, a carboxylic acid onium salt, a dissolution inhibiting compound having a molecular weight of 3000 or less described in Proceeding of SPIE, 2724, 355 (1996) or the like, a dye, a plasticizer, a photosensitizer, a light absorber, an antioxidant, or the like.

In particular, the carboxylic acid can be suitably used to improve the performance. The carboxylic acid is preferably an aromatic carboxylic acid such as benzoic acid or naphthoic acid.

When the composition of the present invention includes a carboxylic acid, the content of the carboxylic acid relative to the total solid content of the composition is preferably 0.01 to 10 mass %, more preferably 0.01 to 5 mass %, still more preferably 0.01 to 3 mass %.

The composition of the present invention is, from the viewpoint of improving the resolving power, preferably used at a film thickness of 10 to 250 nm, more preferably used at a film thickness of 20 to 200 nm, and still more preferably used at a film thickness of 30 to 100 nm. Such a film thickness can be provided by setting the solid content concentration in the composition in an appropriate range to provide an appropriate viscosity, to thereby improve the coatability and the film formability.

The solid content concentration of the composition of the present invention is ordinarily 1.0 to 10 mass %, preferably 2.0 to 5.7 mass %, and more preferably 2.0 to 5.3 mass %. When the solid content concentration is set in such a range, the resist solution can be uniformly applied onto a substrate, and a resist pattern excellent in line width roughness can be formed.

The solid content concentration is a mass percentage of, relative to the total mass of the composition, the mass of the non-solvent components.

### Applications

The composition of the present invention is an actinic ray-sensitive or radiation-sensitive resin composition that reacts upon irradiation with an actinic ray or a radiation to undergo change in a property. More specifically, the composition of the present invention relates to an actinic ray-sensitive or radiation-sensitive resin composition used in a process for producing semiconductors such as ICs (integrated circuits), production of a circuit board for liquid crystal, a thermal head, or the like, production of a mold structure for imprinting, other photofabrication processes, or production of a lithographic printing plate or an acid-curable composition. The pattern formed in the present invention can be used in an etching step, an ion implantation step, a bump electrode forming step, a redistribution forming step, MEMS (Micro Electro Mechanical Systems), and the like.

### Actinic Ray-Sensitive or Radiation-Sensitive Film

The present invention also relates to an actinic ray-sensitive or radiation-sensitive film (preferably a resist film) formed from the actinic ray-sensitive or radiation-sensitive composition of the present invention. Such a film is formed by, for example, applying the composition of the present invention onto a support such as a substrate. This film preferably has a thickness of 0.02 to 0.1 μm. For the method of applying it onto the substrate, it is applied onto the substrate by an appropriate coating method such as spin coating, roll coating, flow coating, dip coating, spray coating, or doctor coating; and preferred is spin coating in which the number of rotations is preferably 1,000 to 3000 rpm (rotations per minute). The coating film is pre-baked at 60 to 150° C. for 1 to 20 minutes, preferably at 80 to 120° C. for 1 to 10 minutes, to form a thin film.

For the material forming the substrate to be processed and the uppermost layer thereof, in a case of a semiconductor wafer, a silicon wafer can be used; examples of the material of the uppermost layer include Si, SiO₂, SiN, SiON, TiN, WSi, BPSG (Boron Phosphorus Silicon Glass), SOG (Spin on Glass), and organic antireflection films.

Before the formation of the actinic ray-sensitive or radiation-sensitive film, an antireflection film may be formed by application onto the substrate in advance.

The antireflection film may be an inorganic film formed of titanium, titanium dioxide, titanium nitride, chromium oxide, carbon, amorphous silicon, or the like or an organic film formed of a light absorber and a polymer material. Other organic antireflection films that can be employed are commercially available organic antireflection films such as DUV30 series and DUV-40 series manufactured by Brewer Science, Inc, and AR-2, AR-3, and AR-5 manufactured by Shipley Company L. L. C.

### Pattern Forming Method

The present invention also relates to a pattern forming method including an actinic ray-sensitive or radiation-sensitive film forming step of forming an actinic ray-sensitive or radiation-sensitive film from the actinic ray-sensitive or radiation-sensitive resin composition of the present invention, an exposure step of exposing the actinic ray-sensitive or radiation-sensitive film, and a development step of developing the exposed actinic ray-sensitive or radiation-sensitive film using a developer.

In the present invention, the exposure is preferably performed using an electron beam, an ArF excimer laser, or extreme ultraviolet rays, more preferably performed using an electron beam or extreme ultraviolet rays, and still more preferably performed using an electron beam. That is, in the exposure step, an electron beam is preferably used as the exposure light source.

In the production of a precision integrated circuit element or the like, the exposure (pattern forming step) on the actinic ray-sensitive or radiation-sensitive film is preferably performed by firstly irradiating patternwise the resist film with an ArF excimer laser, an electron beam, or extreme ultraviolet rays (EUV). The exposure is performed at an exposure dose of, in the case of an ArF excimer laser, about 1 to about 100 mJ/cm², and preferably about 20 to about 60 mJ/cm²; in the case of an electron beam, about 0.1 to about 20 μC/cm², and preferably about 3 to about 10 μC/cm²; and, in the case of extreme ultraviolet rays, about 0.1 to about 20 mJ/cm², and preferably about 3 to about 15 mJ/cm².

Subsequently, post-exposure baking is performed on a hot plate preferably at 60 to 150° C. for 5 seconds to 20 minutes, more preferably at 80 to 120° C. for 15 seconds to 10 minutes, and still more preferably at 80 to 120° C. for 1 to 10 minutes, and subsequently, development, rinsing, and drying are performed to form a pattern. The post-exposure baking is appropriately adjusted depending on the acid decomposability of the repeating unit having an acid decomposable group in the resin (A). When the acid decomposability is low, the post-exposure baking is also preferably performed at a temperature of 110° C. or more and for a baking time of 45 seconds or more.

The developer is appropriately selected, but is preferably an alkali developer (typically an alkaline aqueous solution) or a developer containing an organic solvent (also referred to as an organic-based developer). When the developer is an alkaline aqueous solution, development is carried out with a 0.1 to 5 mass %, preferably 2 to 3 mass %, alkaline aqueous solution of tetramethylammonium hydroxide (TMAH), tetrabutylammonium hydroxide (TBAH), or the like for 0.1 to 3 minutes, preferably 0.5 to 2 minutes, by a standard method such as a dipping method, a puddling method, or a spraying method. To the alkali developer, an appropriate amount of an alcohol and/or a surfactant may be added. Thus, in the formation of a negative-type pattern, the film in the unexposed regions dissolves and the exposed regions are less likely to dissolve in the developer, or, in the formation of a positive-type pattern, the film in the exposed regions dissolves and the film in the unexposed regions is less likely to dissolve in the developer, so that a desired pattern is formed on the substrate.

In the case where the pattern forming method of the present invention has a step of performing development using an alkali developer, examples of the alkali developer include alkaline aqueous solutions of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcoholamines such as dimethylethanolamine and triethanolamine; tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide; quaternary ammonium salts such as trimethylphenylammonium hydroxide, trimethylbenzylammonium hydroxide, triethylbenzylammonium hydroxide, and dimethylbis(2-hydroxyethyl) ammonium hydroxide; and cyclic amines such as pyrrole and piperidine.

Further, such an alkaline aqueous solution to which an appropriate amount of an alcohol or a surfactant is added can be used.

The alkali developer has an alkali concentration of ordinarily 0.1 to 20 mass %.

The alkali developer has a pH of ordinarily 10.0 to 15.0.

In particular, a 2.38 mass % aqueous solution of tetramethylammonium hydroxide is desirable.

As the rinsing solution in the rinsing treatment performed after the alkaline development, pure water can be used and an appropriate amount of a surfactant can be added thereto.

After the developing treatment or the rinsing treatment, a treatment of removing, using a supercritical fluid, the developer or the rinsing solution adhering to the pattern can be performed.

In a case where the pattern forming method of the present invention has a step of performing development using a developer containing an organic solvent, the developer in the step (hereinafter, also referred to as the organic-based developer) can be a polar solvent and hydrocarbon-based solvent such as a ketone-based solvent, an ester-based solvent, an alcohol-based solvent, an amide-based solvent, or an ether-based solvent.

In the present invention, the ester-based solvent is a solvent having an ester group in the molecule; the ketone-based solvent is a solvent having a ketone group in the molecule; the alcohol-based solvent is a solvent having an alcoholic hydroxyl group in the molecule; the amide-based solvent is a solvent having an amide group in the molecule; and the ether-based solvent is a solvent having an ether bond in the molecule. These include a solvent having a plurality of such functional group species in a single molecule; in this case, it is regarded as belonging to any solvent species including the functional groups that the solvent has. For example, diethylene glycol monomethyl ether belongs to, of the above-described classifications, both the alcohol-based solvent and the ether-based solvent. The hydrocarbon-based solvent is a hydrocarbon solvent not having a substituent.

In particular, the developer is preferably a developer containing at least one solvent selected from the group consisting of a ketone-based solvent, an ester-based solvent, an alcohol-based solvent, and an ether-based solvent.

The developer is, from the viewpoint of achieving suppression of the swelling of the resist film, preferably an ester-based solvent having 7 or more (preferably 7 to 14, more preferably 7 to 12, and still more preferably 7 to 10) carbon atoms and 2 or less heteroatoms.

The heteroatom of the ester-based solvent is an atom other than a carbon atom and a hydrogen atom, and examples thereof include an oxygen atom, a nitrogen atom, and a sulfur atom. The number of heteroatoms is preferably 2 or less.

Preferred examples of the ester-based solvent having 7 or more carbon atoms and 2 or less heteroatoms include amyl acetate, isoamyl acetate, 2-methylbutyl acetate, 1-methylbutyl acetate, hexyl acetate, pentyl propionate, hexyl propionate, heptyl propionate, butyl butanoate, and isobutyl isobutanoate; and particularly preferred are isoamyl acetate and isobutyl isobutanoate.

For the developer, instead of the above-described ester-based solvent having 7 or more carbon atoms and 2 or less heteroatoms, a mixed solvent of the ester-based solvent and the hydrocarbon-based solvent, or a mixed solvent of the ketone-based solvent and the hydrocarbon solvent may be used. Also in this case, swelling of the resist film is effectively suppressed.

In the case where an ester-based solvent and a hydrocarbon-based solvent are used in combination, the ester-based solvent is preferably isoamyl acetate. The hydrocarbon-based solvent is, from the viewpoint of adjusting the solubility of the resist film, preferably a saturated hydrocarbon solvent (for example, octane, nonane, decane, dodecane, undecane, or hexadecane).

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, 2,5-dimethyl-4-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate; and particularly preferred are diisobutyl ketone and 2,5-dimethyl-4-hexanone.

Examples of the ester-based solvent include methyl acetate, butyl acetate, ethyl acetate, isopropyl acetate, pentyl acetate, isoamyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, methyl formate, ethyl formate, butyl formate, propyl formate, ethyl lactate, butyl lactate, propyl lactate, butyl butyrate, and methyl 2-hydroxyisobutyrate.

Examples of the alcohol-based solvent include alcohols such as methyl alcohol, ethyl alcohol, n-propyl alcohol, isopropyl alcohol, n-butyl alcohol, sec-butyl alcohol, 4-methyl-2-pentanol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; and glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethylbutanol.

Examples of the ether-based solvent include, in addition to the glycol ether-based solvents, anisole, dioxane, and tetrahydrofuran.

Examples of the amide-based solvent include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene, and aliphatic hydrocarbon-based solvents such as pentane, hexane, octane, decane, and undecane.

Note that such an aliphatic hydrocarbon-based solvent, which is a hydrocarbon-based solvent, may be a mixture of compounds having the same number of carbon atoms but having different structures. For example, in the case of using, as the aliphatic hydrocarbon-based solvent, decane, compounds having the same number of carbon atoms but having different structures such as 2-methylnonane, 2,2-dimethyloctane, 4-ethyloctane, or isooctane may be included in the aliphatic hydrocarbon-based solvent.

For the compounds having the same number of carbon atoms but having different structures, a single compound alone may be included, or a plurality of compounds may be included as described above.

For the above-described solvents, two or more thereof may be mixed together, or such a solvent may be mixed with a solvent other than those described above or water and used. Note that, in order to fully provide advantages of the present invention, the moisture content of the entire developer is preferably less than 10 mass %, and, more preferably, the developer substantially does not contain water.

The concentration of the organic solvent (in the case of a mixture of a plurality of solvents, the total concentration thereof) in the organic-based developer is preferably 50 mass % or more, more preferably 50 to 100 mass %, still more preferably 85 to 100 mass %, yet more preferably 90 to 100 mass %, and particularly preferably 95 to 100 mass %. Most preferably, it consists essentially of an organic solvent. Note that the case where it consists essentially of an organic solvent includes the cases where it contains a small amount of a surfactant, an antioxidant, a stabilizer, an anti-foaming agent, or the like.

In particular, the organic-based developer is preferably a developer containing at least one organic solvent selected from the group consisting of a ketone-based solvent, an ester-based solvent, an alcohol-based solvent, an amide-based solvent, and an ether-based solvent.

The vapor pressure of the organic-based developer at 20° C. is preferably 5 kPa or less, more preferably 3 kPa or less, and particularly preferably 2 kPa or less. When the vapor pressure of the organic-based developer is set to 5 kPa or less, the evaporation of the developer on the substrate or in the developing cup is suppressed, the wafer in-plane temperature uniformity is improved, and as a result, the wafer in-plane dimensional uniformity is improved.

Specific examples having a vapor pressure of 5 kPa or less include ketone-based solvents such as 1-octanone, 2-octanone, 1-nonanone, 2-nonanone, 2-heptanone (methyl amyl ketone), 4-heptanone, 2-hexanone, diisobutyl ketone, cyclohexanone, methylcyclohexanone, phenylacetone, and methyl isobutyl ketone; ester-based solvents such as butyl acetate, pentyl acetate, isoamyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate, and propyl lactate; alcohol-based solvents such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethylbutanol; ether-based solvents such as tetrahydrofuran; amide-based solvents such as N-methyl-2-pyrrolidone, N,N-dimethylacetamide, and N,N-dimethylformamide; aromatic hydrocarbon-based solvents such as toluene and xylene; and aliphatic hydrocarbon-based solvents such as octane and decane.

Specific examples having a vapor pressure of 2 kPa or less, which is a particularly preferred range, include ketone-based solvents such as 1-octanone, 2-octanone, 1-nonanone, 2-nonanone, 2-heptanone, 4-heptanone, 2-hexanone, diisobutyl ketone, cyclohexanone, methylcyclohexanone, and phenylacetone; ester-based solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate, and propyl lactate; alcohol-based solvents such as n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethylbutanol; amide-based solvents such as N-methyl-2-pyrrolidone, N,N-dimethylacetamide, and N,N-dimethylformamide; aromatic hydrocarbon-based solvents such as xylene; and aliphatic hydrocarbon-based solvents such as octane, decane, and undecane.

The organic-based developer may include a basic compound. Specific examples and preferred examples of the basic compound that the developer used in the present invention can include are the same as those in the basic compound that the above-described actinic ray-sensitive or radiation-sensitive composition can include.

To the organic-based developer, an appropriate amount of a surfactant can be added as needed.

The surfactant is not particularly limited, and for example, an ionic or nonionic fluorine-based and/or silicone-based surfactant can be used. Examples of such fluorine-based and/or silicone-based surfactants include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A), U.S. Pat. Nos. 5,405,720A, 5,360,692A, 5,529,881A, 5,296,330A, 5,436,098A, 5,576,143A, 5,294,511A, and 5,824,451A; preferred are nonionic surfactants. Such a nonionic surfactant is not particularly limited, but more preferably a fluorine-based surfactant or a silicone-based surfactant is used.

The amount of the surfactant used relative to the total amount of the developer is preferably 0.0001 to 2 mass %, more preferably 0.0001 to 1 mass %, and particularly preferably 0.0001 to 0.1 mass %.

The developing method that can be applied is, for example, a method of immersing the substrate in a tank filled with the developer for a certain period of time (dipping method), a method of puddling the substrate surface with the developer by surface tension and leaving the developer at rest for a certain period of time to perform development (puddling method), a method of spraying the developer on the substrate surface (spraying method), or a method of continuously ejecting the developer while the substrate rotating at a certain rate is scanned with a developer ejection nozzle at a certain rate (dynamic dispensing method).

In the case where the above-described various developing methods include a step of ejecting the developer from a developing nozzle of a developing apparatus toward a resist film, the ejection pressure of the developer ejected (flow rate per unit area of the developer ejected) is preferably 2 mL/sec/mm² or less, more preferably 1.5 mL/sec/mm² or less, and still more preferably 1 mL/sec/mm² or less. The lower limit of the flow rate is not particularly limited, but is preferably 0.2 mL/sec/mm² or more from the viewpoint of throughput.

When the ejection pressure of the developer ejected is set to such a range, defects of the pattern derived from the resist scum after development can be markedly reduced.

This mechanism has not been specifically clarified; however, inferentially, the ejection pressure is set to such a range, so that the pressure applied to the resist film by the developer is reduced, which inferentially suppresses unintended wear or collapse of the resist film and pattern.

Note that the ejection pressure of the developer (mL/sec/mm²) is a value at the outlet of the developing nozzle in the developing apparatus.

Examples of the method of adjusting the ejection pressure of the developer include a method of adjusting the ejection pressure using a pump or the like, and a method of changing the ejection pressure by adjusting the pressure on the basis by supply from a pressure tank.

After the step of performing development using the developer including an organic solvent, a step of stopping the development while the developer is replaced with another solvent may be performed.

After the step of performing development using the developer including the organic solvent, a step of performing cleaning using a rinsing solution may be included, but from the viewpoint of throughput (productivity), the amount of rinsing solution used, and the like, the step of performing cleaning using a rinsing solution may not be included.

The rinsing solution used in the rinsing step after the step of performing development using a developer including an organic solvent is not particularly limited as long as it does not dissolve the resist pattern, and a solution including a general organic solvent can be used. As the rinsing solution, a rinsing solution containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent include the same as those described in the developer including an organic solvent; and particularly preferred are butyl acetate and methylisobutylcarbinol.

More preferably, the step of performing development using the developer including an organic solvent is followed by a step of performing cleaning using a rinsing solution containing at least one organic solvent selected from the group consisting of an ester-based solvent, an alcohol-based solvent, and a hydrocarbon-based solvent, and still more preferably followed by a step of performing cleaning using a rinsing solution containing an alcohol-based solvent or a hydrocarbon-based solvent.

The organic solvent included in the rinsing solution is also preferably, of organic solvents, a hydrocarbon-based solvent, and more preferably an aliphatic hydrocarbon-based solvent. The aliphatic hydrocarbon-based solvent used in the rinsing solution is preferably, from the viewpoint of providing its effect further improved, an aliphatic hydrocarbon-based solvent having 5 or more carbon atoms (for example, pentane, hexane, octane, decane, undecane, dodecane, or hexadecane), preferably an aliphatic hydrocarbon-based solvent having 8 or more carbon atoms, and more preferably an aliphatic hydrocarbon-based solvent having 10 or more carbon atoms.

The upper limit value of the number of carbon atoms of the aliphatic hydrocarbon-based solvent is not particularly limited, and is, for example, 16 or less, preferably 14 or less, and more preferably 12 or less.

Of the above-described aliphatic hydrocarbon-based solvents, particularly preferred are decane, undecane, and dodecane; and most preferred is undecane.

In such a case of using, as the organic solvent included in the rinsing solution, a hydrocarbon-based solvent (in particular, an aliphatic hydrocarbon-based solvent), the developer that has slightly permeated the resist film after development is washed away, and the effects of further suppressing swelling and suppressing pattern collapse are further exerted.

Of the above-described components, two or more thereof may be mixed together, or a component may be mixed with an organic solvent other than those described above and used.

The moisture content in the rinsing solution is preferably 10 mass % or less, more preferably 5 mass % or less, and particularly preferably 3 mass % or less. When the moisture content is set to 10 mass % or less, good development characteristics can be provided.

The rinsing solution used after the step of performing development using the developer including an organic solvent preferably has a vapor pressure at 20° C. of 0.05 kPa or more and 5 kPa or less, more preferably 0.1 kPa or more and 5 kPa or less, and most preferably 0.12 kPa or more and 3 kPa or less. When the vapor pressure of the rinsing solution is set to 0.05 kPa or more and 5 kPa or less, the wafer in-plane temperature uniformity is improved, and further, the swelling caused by permeation of the rinsing solution is suppressed, and the wafer in-plane dimensional uniformity is improved.

Such a rinsing solution to which an appropriate amount of a surfactant is added can be used.

In the rinsing step, the wafer having been subjected to development using the developer including an organic solvent is subjected to a cleaning treatment using the above-described rinsing solution including an organic solvent. The method of performing the cleaning treatment is not particularly limited, and for example, a method of continuously ejecting the rinsing solution onto the substrate rotating at a constant rate (spin coating method), a method of immersing the substrate in a tank filled with the rinsing solution for a certain period of time (dipping method), a method of spraying the rinsing solution on the substrate surface (spraying method), or the like can be applied; of these, preferably, the spin coating method is used to perform the cleaning treatment, and the cleaned substrate is rotated at a rotational rate of 2000 rpm to 4000 rpm to remove the rinsing solution from the substrate. After the rinsing step, a heating step (PostBake) is preferably included. The baking results in removal of the developer and the rinsing solution remaining between the pattern portions and inside the pattern. The heating step after the rinsing step is carried out at ordinarily 40 to 160° C., preferably 70 to 95° C., for ordinarily 10 seconds to 3 minutes, preferably 30 seconds to 90 seconds.

In the case of not having the step of performing cleaning using a rinsing solution, for example, the developing treatment method described in paragraphs [0014] to [0086] of JP2015-216403A can be employed.

The pattern forming method of the present invention may have a development step using an organic-based developer and a development step using an alkali developer. The development using an organic-based developer results in removal of regions subjected to a low exposure intensity, and the development using an alkali developer also results in removal of regions subjected to a high exposure intensity. Such a multiple developing process in which developments are performed a plurality of times is performed, so that only regions subjected to an intermediate exposure intensity are not dissolved to form a pattern, which results in formation of a finer pattern (by the same mechanism as in paragraph [0077] of JP2008-292975A).

The actinic ray-sensitive or radiation-sensitive composition in the present invention and various materials used in the pattern forming method of the present invention (for example, a developer, a rinsing solution, a composition for forming an antireflection film, and a composition for forming a topcoat) preferably do not include impurities such as metals, metal salts including halogens, acids, alkalis, and components including sulfur atoms or phosphorus atoms. Examples of the impurities including metal atoms include Na, K, Ca, Fe, Cu, Mn, Mg, Al, Cr, Ni, Zn, Ag, Sn, Pb, Li, and salts of the foregoing.

The content of the impurities included in the materials is preferably 1 ppm or less, more preferably 1 ppb (parts per billion) or less, still more preferably 100 ppt (parts per trillion) or less, particularly preferably 10 ppt or less; and most preferably the impurities are substantially not included (the content is equal to or less than the detection limit of the measurement apparatus).

The method for removing impurities such as metals from various materials is, for example, filtration using a filter. For the filter pore size, the pore size is preferably 10 nm or less, more preferably 5 nm or less, and still more preferably 3 nm or less. For the material of the filter, a filter formed of polytetrafluoroethylene, polyethylene, or nylon is preferred. The filter may be a composite material that is a combination of such a material and ion exchange media. The filter that is washed with an organic solvent in advance may be used. In the filter filtration step, a plurality of filters connected in series or in parallel may be used. In the case of using a plurality of filters, filters that are different in pore sizes and/or materials may be used in combination. Various materials may be filtered a plurality of times, and the step of performing filtration a plurality of times may be a circulation filtration step.

Examples of the method of reducing impurities such as metals included in various materials include a method of selecting raw materials having a low metal content as raw materials for constituting various materials, a method of filtering raw materials for constituting various materials through a filter, and a method of performing distillation under a condition in which contamination is suppressed as much as possible by, for example, lining the inside of an apparatus with TEFLON (registered trademark). Preferred conditions for the filter filtration of the raw materials for constituting various materials are the same as the above-described conditions.

In addition to the filter filtration, removal of impurities using an adsorbent may be performed, and the filter filtration and the adsorbent may be used in combination. For the adsorbent, publicly known adsorbents can be used, and, for example, an inorganic adsorbent such as silica gel or zeolite, or an organic adsorbent such as activated carbon can be used.

Examples of the method of reducing impurities such as metals included in the organic solvent (also referred to as “organic treatment solution”) that can be used in the developer and rinsing solution of the present invention include a method of selecting raw materials having a low metal content as raw materials for constituting various materials, a method of filtering raw materials for constituting various materials through a filter, and a method of performing distillation under a condition in which contamination is suppressed as much as possible by, for example, lining the inside of an apparatus with TEFLON (registered trademark). Preferred conditions for the filter filtration of the raw materials for constituting various materials are the same as the above-described conditions.

In addition to the filter filtration, removal of impurities using an adsorbent may be performed, or the filter filtration and the adsorbent may be used in combination. For the adsorbent, publicly known adsorbents can be used, and, for example, an inorganic adsorbent such as silica gel or zeolite, or an organic adsorbent such as activated carbon can be used.

A conductive compound may be added to the organic treatment solution of the present invention in order to prevent failures of chemical pipes and various parts (such as filters, 0-rings, and tubes) due to electrostatic charging and subsequent electrostatic discharge. The conductive compound is not particularly limited, and is, for example, methanol. The addition amount is not particularly limited, but is, from the viewpoint of maintaining preferable development characteristics, preferably 10 mass % or less, and more preferably 5 mass % or less. For members of the chemical pipes, various pipes formed of SUS (stainless steel), or coated with polyethylene, polypropylene, or a fluororesin (such as polytetrafluoroethylene or a perfluoroalkoxy resin) subjected to an antistatic treatment can be used. Similarly, for the filters and the O-rings, polyethylene, polypropylene, or a fluororesin (such as polytetrafluoroethylene or a perfluoroalkoxy resin) subjected to an antistatic treatment can be used.

Note that, in general, the developer and the rinsing solution after use are collected through a pipe into a waste liquid tank. In this case, when a hydrocarbon-based solvent is used as the rinsing solution, in order to prevent eduction of the resist dissolved in the developer and adhesion to the back surface of the wafer, the side surface of the pipe, and the like, a method of passing the solvent in which the resist is dissolvable through the pipe again may be used. Examples of the method of passing through the pipe include a method of, after washing with the rinsing solution, washing the back surface of the substrate, the side surface, and the like with the solvent in which the resist is dissolvable to pass the solvent, and a method of passing the solvent in which the resist is dissolvable through the pipe without bringing the solvent into contact with the resist.

The solvent that is passed through the pipe is not particularly limited as long as it is a solvent in which the resist is dissolvable, and examples thereof include the above-described organic solvents and include propylene glycol monomethyl ether acetate (PGMEA), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, ethylene glycol monoethyl ether acetate, propylene glycol monomethyl ether (PGME), propylene glycol monoethyl ether, propylene glycol monopropyl ether, propylene glycol monobutyl ether, ethylene glycol monomethyl ether, ethylene glycol monoethyl ether, 2-heptanone, ethyl lactate, 1-propanol, and acetone. Of these, preferably used are PGMEA, PGME, and cyclohexanone.

### Method for Producing Electronic Device

In addition, the present invention also relates to a method for producing an electronic device, the method including the above-described pattern forming method. The electronic device produced by the method for producing an electronic device of the present invention is suitably mounted on electric and electronic apparatuses (for example, home appliances, OA (Office Automation)-related apparatuses, media-related apparatuses, optical apparatuses, and communication apparatuses).

### EXAMPLES

Hereinafter, the present invention will be described further in detail with reference to Examples. The materials, usage amounts, ratios, details of treatments, and procedures of treatments described in the following Examples can be appropriately changed without departing from the spirit and scope of the present invention. Therefore, the scope of the present invention should not be construed as being limited to the following Examples.

Various components used in the resist compositions of Examples and Comparative Examples will be described below.

### Resin (A)

### Synthesis Example 1: Synthesis of Monomer (a-1)

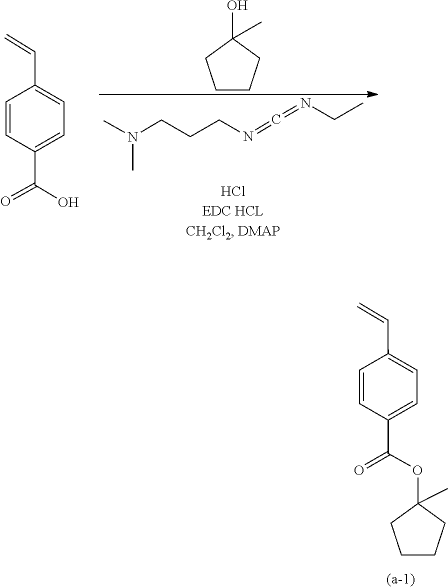

4-Vinylbenzoic acid (50.0 g, 337 mmol), 1-methylcyclopentanol (40.6 g, 405 mmol), 500 ml of methylene chloride, and 4-dimethylaminopyridine (45.3 g, 371 mmol) were charged, and cooled to −10° C. At −10° C., 1-(3-dimethylaminopropyl)-3-ethylcarbodiimide hydrochloride (71.1 g, 371 mmol) was added, and warming to room temperature (23° C.) was performed and subsequently stirring for 15 hours was performed. The organic phase was washed with pure water, and subsequently the solvent was distilled off under a reduced pressure. The residue was purified by silica gel column chromatography (eluant:ethyl acetate/n-hexane=3/97) to provide 60 g of a monomer (a-1). The compound was identified by ESI-MS.

MS-ESI (positive) m/z=229.1 [M]⁺

### Synthesis Example 2: Synthesis of Monomer (a-13)

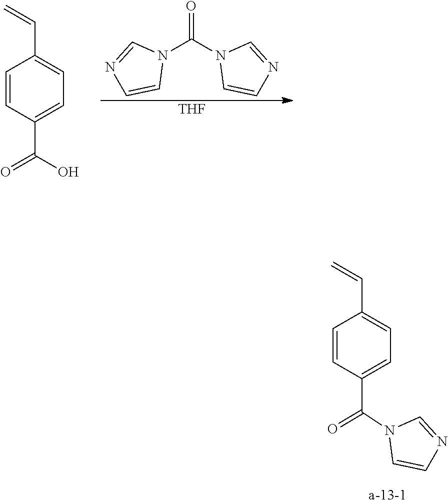

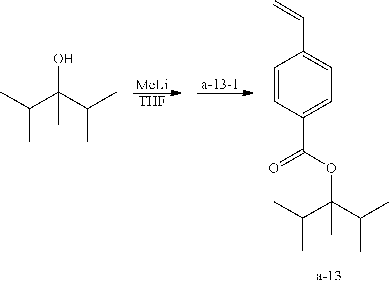

Synthesis of Intermediate (a-13-1)

4-Vinylbenzoic acid (2.00 g, 13.5 mmol) was dissolved in 10 mL of THF, 1,1′-carbonyldiimidazole (2.23 g, 13.8 mmol) was added, and subsequently stirring was performed at room temperature for 2 hours to provide a THF solution of (a-13-1) (about 14 mL). This intermediate (a-13-1) solution was used for the subsequent reaction without further purification.

Synthesis of Monomer (a-13)

2,3,4-Trimethylpentanol (5.46 g, 41.9 mmol) and 25 mL of tetrahydrofuran were mixed together and cooled to −78° C. under a nitrogen atmosphere. Methyl lithium (1.4 M cyclopentyl methyl ether solution) (28.9 ml (40 mmol)) was added dropwise, and stirring was further performed at room temperature for 1 hour. To the reaction solution cooled to −10° C., the THF solution of the intermediate (a-13-1) (about 14 mL) was added dropwise. After stirring at 60° C. for 1 hour, 100 mL of n-hexane and 100 mL of distillated water were added, and extraction procedures were performed. The solvent of the organic layer was distilled off under a reduced pressure. The residue was purified by silica gel column chromatography (eluant:ethyl acetate/n-hexane=3/97) to provide 2.5 g of a monomer (a-13). The compound was identified by ESI-MS.

MS-ESI (positive) m/z=259.2 [M]⁺

### Synthesis Example 3: Synthesis of Resin (A-1)

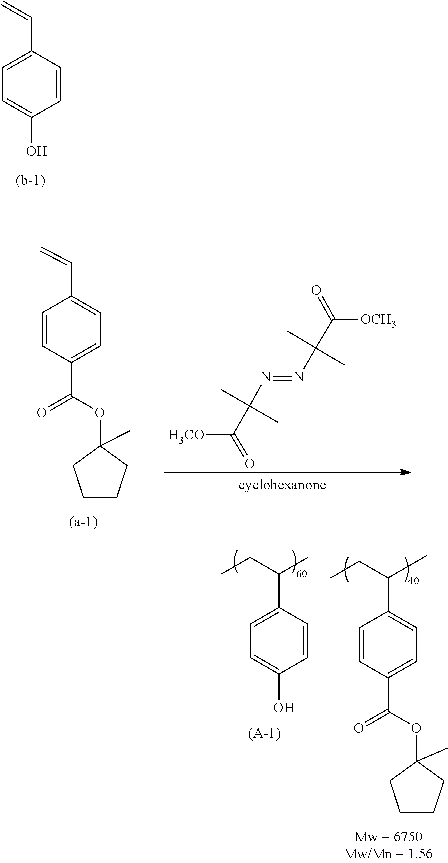

(b-1) and (a-1) were employed as monomers and the monomers were mixed together in a molar ratio of (b-1):(a-1)=60/40; cyclohexanone was added so as to provide a solution having a monomer concentration of 30 mass %, and dimethyl-2,2′-azobis(2-methylpropionate) serving as an initiator was added in an amount of 8 mol %, to prepare a monomer solution. Under a nitrogen atmosphere, cyclohexanone in an amount of 0.1 times by mass the monomer solution was heated to 85° C., the monomer solution was added dropwise over 2 hours, and subsequently a reaction was caused at 85° C. for 2 hours. The resultant resin solution was added dropwise to a mixed solvent of ethyl acetate:n-heptane=1:9 to cause precipitation of the resin; the resin was filtered, collected, and subsequently dried in a vacuum to provide a resin (A-1) in a yield of 66%.

For resins A-2 to A-46, resins synthesized by the same method as described above were employed. Table 1 describes the types and contents (content ratios (mol %)) of repeating units, weight-average molecular weight (Mw), and dispersity (Mw/Mn).

In Table 1, repeating units (a-1) to (a-35) described in Repeating unit 2 and corresponding to the repeating unit (a) are respectively repeating units derived from raw material monomers (a-1) to (a-35) described later.

For resins A-1 to A-46, the weight-average molecular weight (Mw) and the dispersity (Mw/Mn) were measured by GPC (carrier: tetrahydrofuran (THF)) (in terms of polystyrene). The ratios of the repeating units were measured by ¹³C-NMR (nuclear magnetic resonance).

TABLE 1

| | | | | | Composition ratio | Weight-average | |
|---|---|---|---|---|---|---|---|
| | Repeating | Repeating | Repeating | Repeating | (molar ratio) | molecular | |
| Resin | unit 1 | unit 2 | unit 3 | unit 4 | from the left | weight | Dispersity |
| A-1 | b-1 | a-1 | | | 60/40 | 6750 | 1.56 |
| A-2 | b-1 | a-2 | | | 65/35 | 7520 | 1.68 |
| A-3 | b-2 | a-3 | c-4 | | 65/30/5 | 7900 | 1.55 |
| A-4 | b-3 | a-4 | | d-1 | 45/35/20 | 11230 | 1.8 |
| A-5 | b-4 | a-5 | | | 66/34 | 10650 | 1.72 |
| A-6 | b-5 | a-6 | c-2 | | 61/33/6 | 5990 | 1.54 |
| A-7 | b-6 | a-7 | | d-4 | 55/29/16 | 8120 | 1.6 |
| A-8 | b-7 | a-8 | c-1 | | 30/45/25 | 9600 | 1.57 |
| A-9 | b-8 | a-9 | | d-6 | 70/24/6 | 12000 | 1.49 |
| A-10 | b-9 | a-10 | c-3 | d-7 | 39/38/11/12 | 10780 | 1.85 |
| A-11 | b-10 | a-11 | | | 57/43 | 9320 | 1.72 |
| A-12 | b-11 | a-12 | c-5 | d-9 | 39/35/12/14 | 8120 | 1.73 |
| A-13 | b-12 | a-13 | | | 61/39 | 6880 | 1.63 |
| A-14 | b-3 | a-14 | c-7 | d-11 | 38/40/12/10 | 7020 | 1.58 |
| A-15 | b-10 | a-15 | | | 69/31 | 6520 | 1.49 |
| A-16 | b-1 | a-16 | | | 59/41 | 6880 | 1.52 |
| A-17 | b-11 | a-17 | c-1 | d-2 | 35/30/22/13 | 7360 | 1.55 |
| A-18 | b-4 | a-18 | | | 55/45 | 7200 | 1.64 |
| A-19 | b-1 | a-19 | | | 54/46 | 6180 | 1.68 |
| A-20 | b-2 | a-20 | c-6 | d-3 | 58/32/6/4 | 10650 | 1.71 |
| A-21 | b-3 | a-21 | | | 52/48 | 5990 | 1.59 |
| A-22 | b-1 | a-22 | | | 62/38 | 8120 | 1.63 |
| A-23 | b-2 | a-23 | | d-5 | 59/38/3 | 9600 | 1.64 |
| A-24 | b-9 | a-24 | c-8 | | 55/40/5 | 7630 | 1.69 |
| A-25 | b-10 | a-25 | | | 63/37 | 7180 | 1.7 |
| A-26 | b-1 | a-26 | | | 60/40 | 6550 | 1.52 |
| A-27 | b-9 | a-27 | c-2 | d-8 | 73/20/3/4 | 6470 | 1.53 |
| A-28 | b-1 | a-28 | | | 67/33 | 6910 | 1.6 |
| A-29 | b-9 | a-29 | c-9 | | 45/45/10 | 7820 | 1.54 |
| A-30 | b-1 | a-30 | | | 63/37 | 6850 | 1.65 |
| A-31 | b-3 | a-31 | | | 71/29 | 8880 | 1.65 |
| A-32 | b-3 | a-32 | | | 72/38 | 9320 | 1.24 |
| A-33 | b-4 | a-33 | | d-12 | 59/28/13 | 7320 | 1.32 |
| A-34 | b-10 | a-34 | | | 58/42 | 5980 | 1.56 |
| A-35 | b-7 | a-35 | | d-10 | 59/30/11 | 7620 | 1.72 |
| A-36 | b-1 | a-13 | | | 64/36 | 7780 | 1.32 |
| A-37 | b-4 | a-5 | | | 67/33 | 6990 | 1.58 |
| A-38 | b-1 | a-14 | | | 62/38 | 6170 | 1.43 |
| A-39 | b-4 | a-27 | | | 71/29 | 6820 | 1.46 |
| A-40 | b-1 | a-21 | | | 63/37 | 8130 | 1.68 |
| A-41 | b-4 | a-20 | c-8 | | 50/40/10 | 8960 | 1.58 |
| A-42 | b-9 | a-13 | | | 71/29 | 7530 | 1.69 |
| A-43 | b-1 | a-19 | | | 55/45 | 11200 | 1.47 |
| A-44 | b-9 | a-8 | c-7 | | 55/35/10 | 9230 | 1.44 |
| A-45 | b-4 | a-15 | | | 64/36 | 7220 | 1.63 |
| A-46 | b-6 | a-7 | | d-4 | 55/13/32 | 8880 | 1.65 |
| A-47 | b-2 | a-36 | | | 70/30 | 7820 | 1.62 |
| A-48 | b-1 | a-37 | c-1 | | 68/28/4 | 6630 | 1.69 |
| A-49 | b-4 | a-38 | | | 79/21 | 8850 | 1.56 |
| A-50 | b-1 | a-39 | | | 65/35 | 5860 | 1.58 |
| A-51 | b-10 | a-40 | | | 69/31 | 6950 | 1.63 |
| A-52 | b-2 | a-41 | c-4 | | 65/30/5 | 7010 | 1.70 |
| A-53 | b-3 | a-42 | | | 70/30 | 6820 | 1.63 |
| A-54 | b-11 | a-43 | | | 72/28 | 6320 | 1.65 |
| A-55 | b-4 | a-44 | c-1 | | 69/27/4 | 6110 | 1.68 |
| A-56 | b-11 | a-45 | | | 68/32 | 6970 | 1.61 |

The structural formulas of the repeating units described in Table 1 will be described below. For repeating units described in Repeating unit 2 and corresponding to the repeating unit (a), the structural formulas of corresponding raw material monomers will be described.

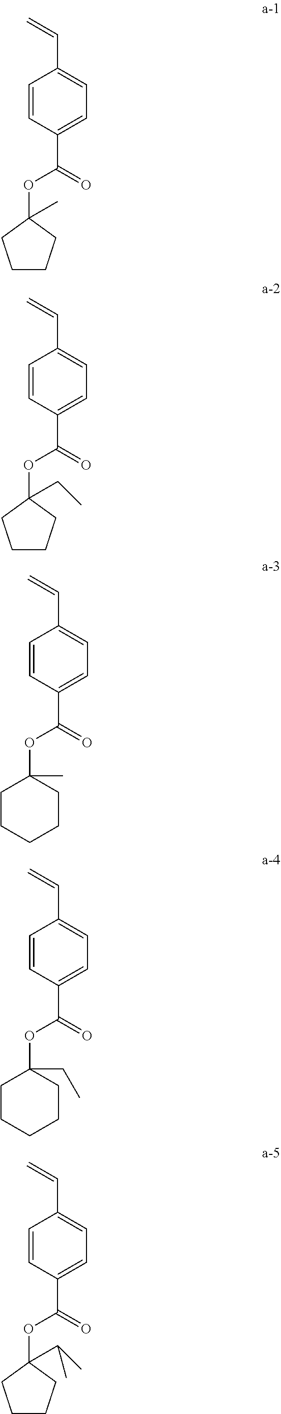

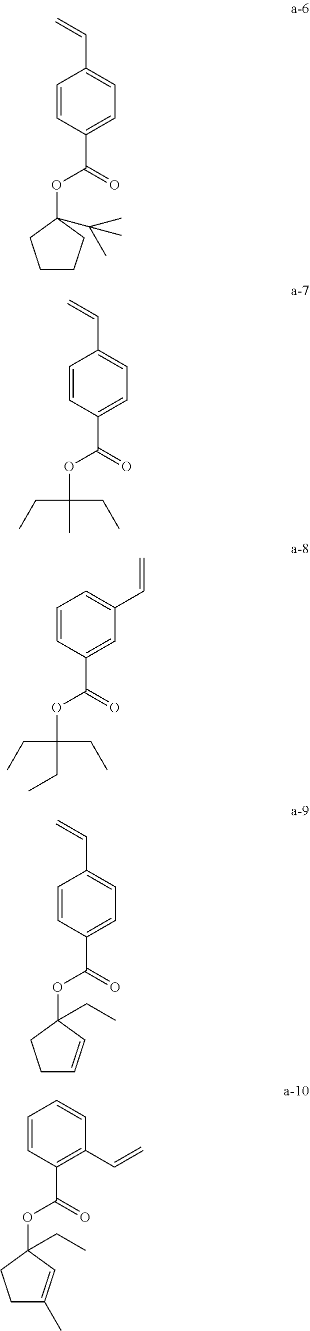

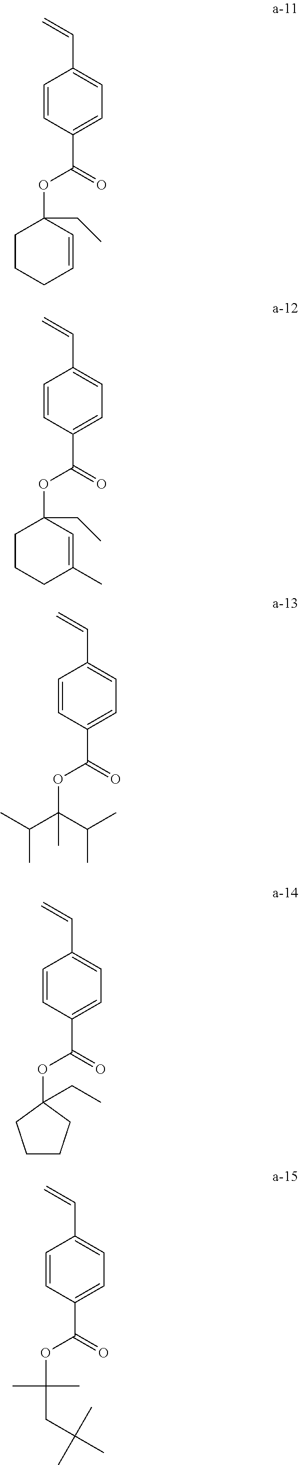

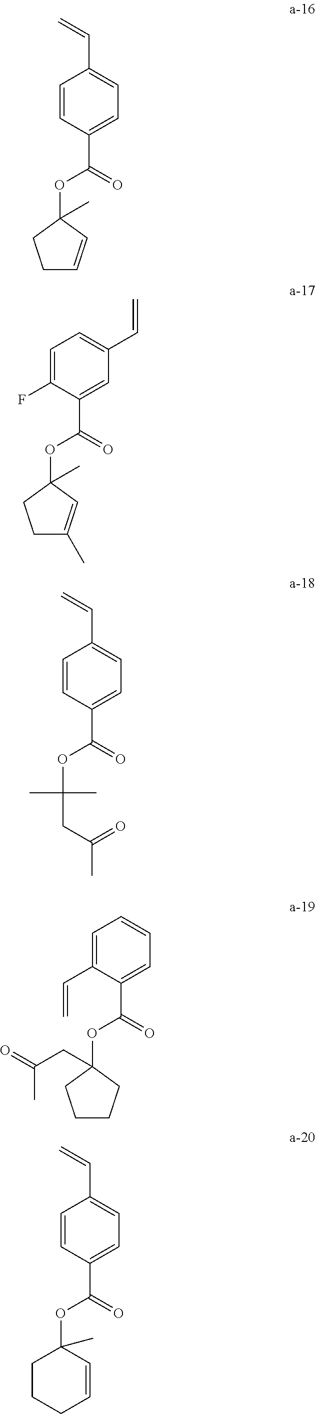

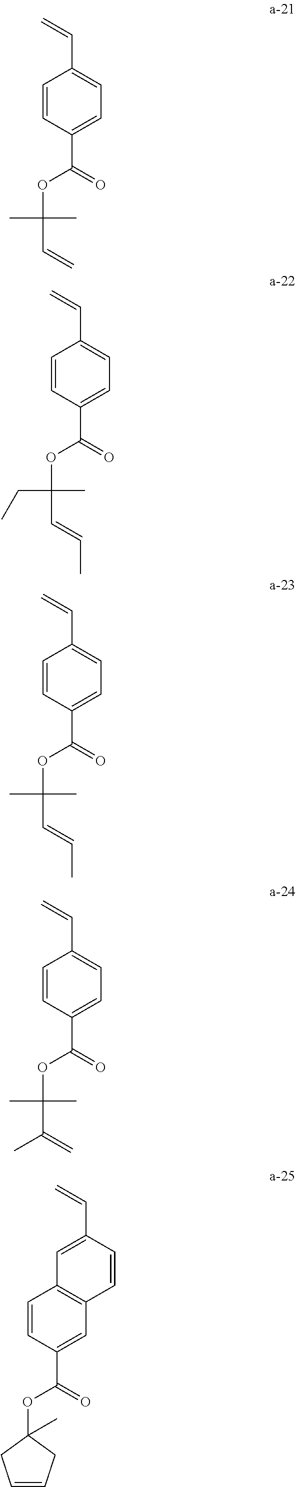

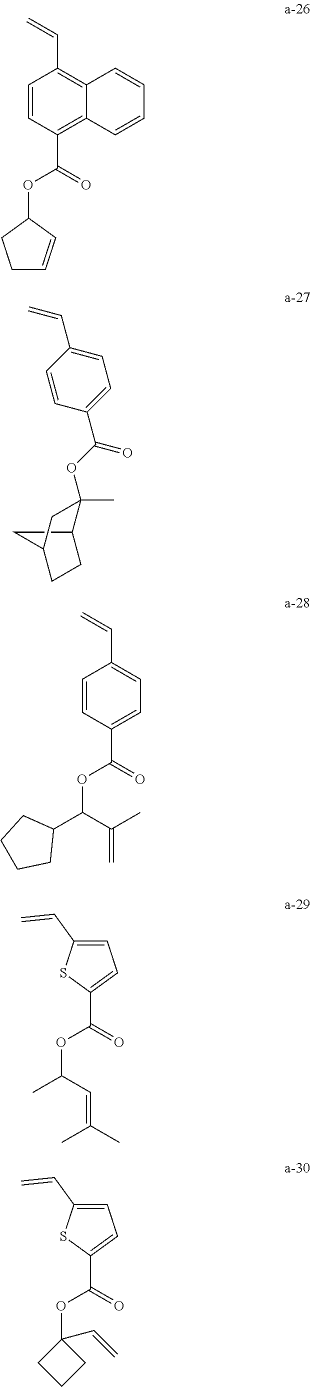

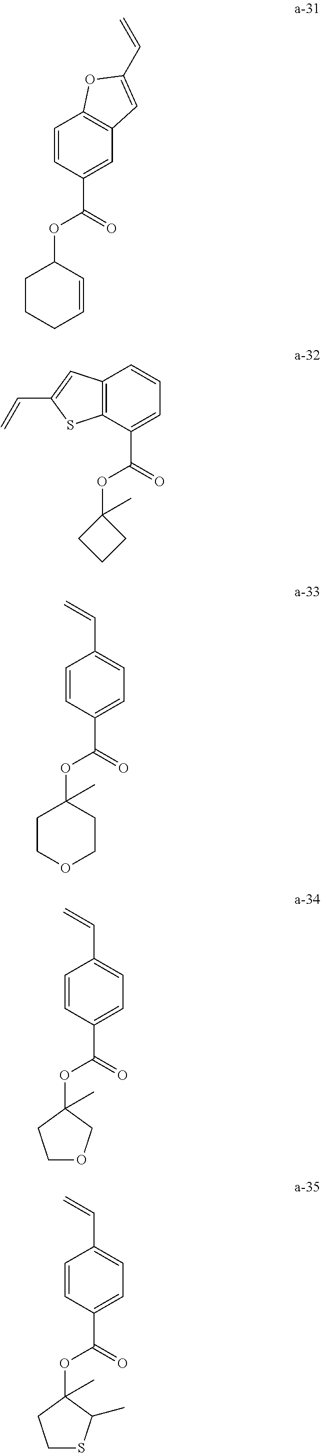

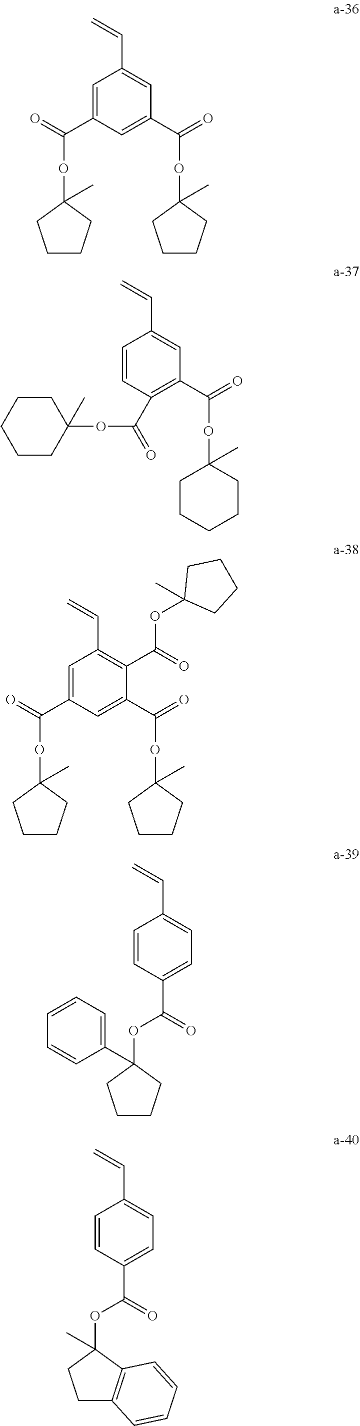

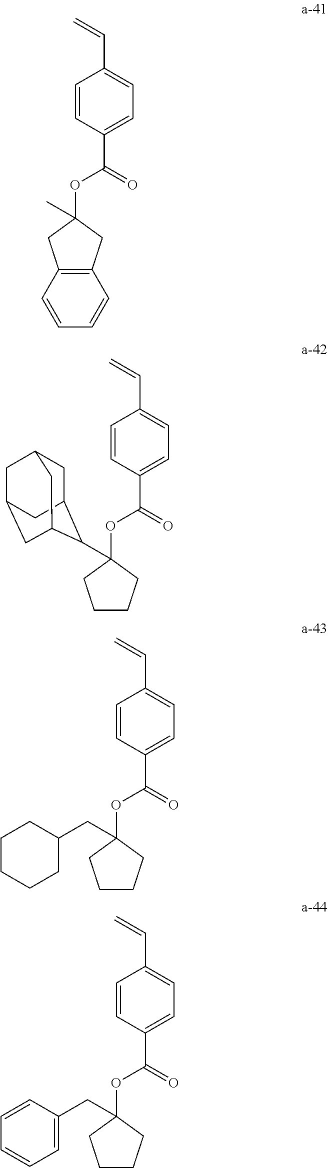

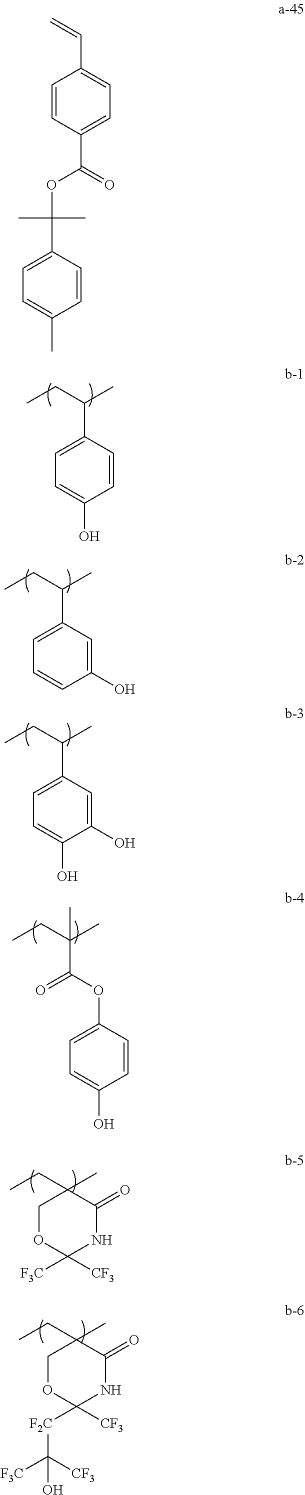

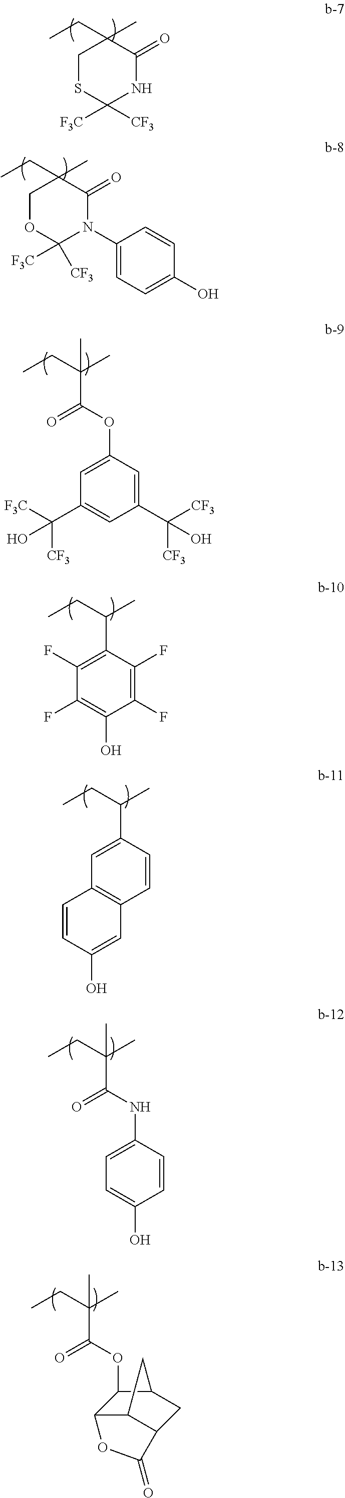

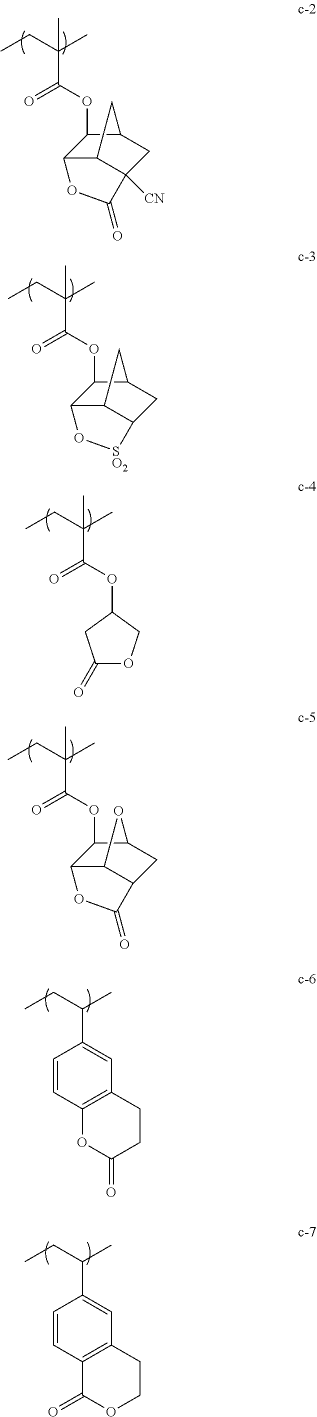

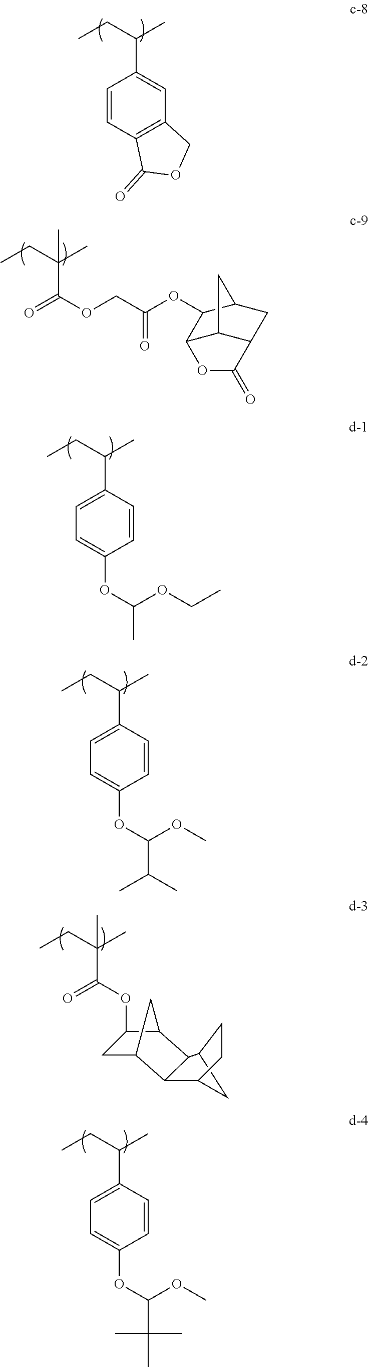

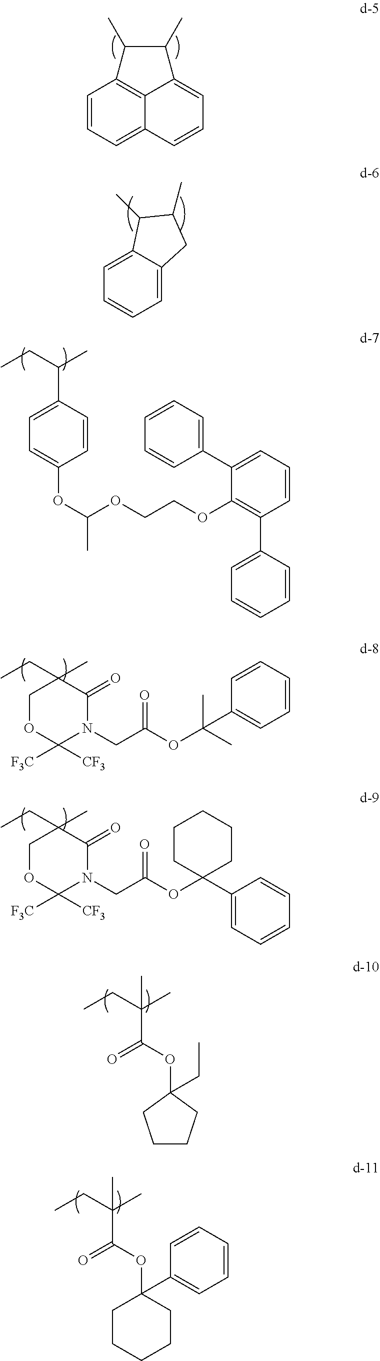

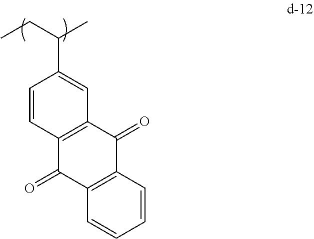

For Comparative Examples, the following Resins (AX-1) to (AX-5) were used.

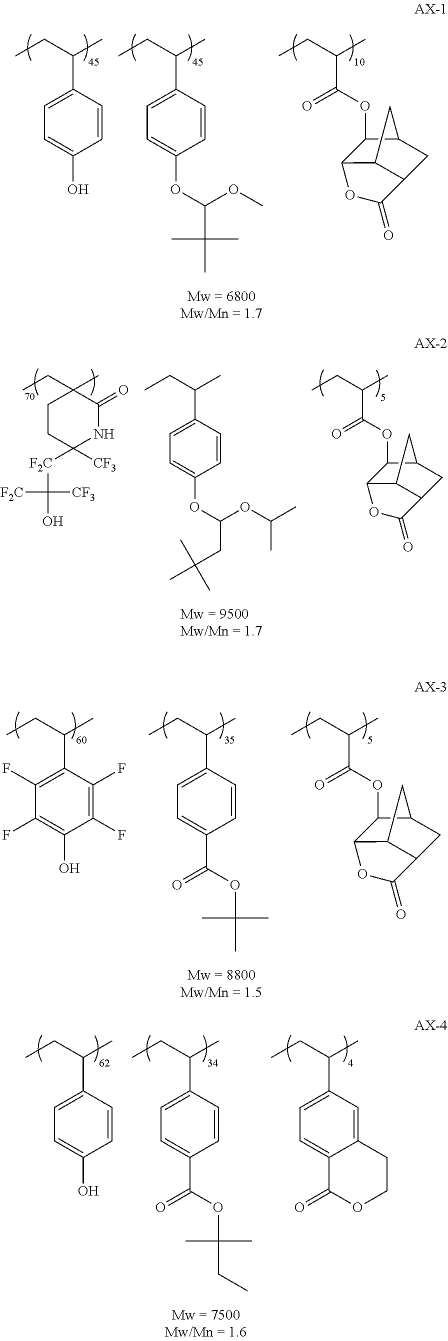

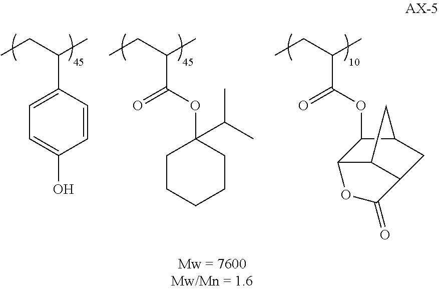

### Photoacid Generator (B)

### Synthesis Example 4: Synthesis of Photoacid Generator (B-2) (1) (Synthesis of B-2-1)

2,4,6-Trichlorobenzenesulfonyl chloride (40.0 g) was dissolved in 222 g of chloroform and cooled to 0° C.; subsequently, 15.9 g of isobutylalcohol and 19.2 g of pyridine were added, and stirring was performed at room temperature for 6 hours. To the reaction mixture, 1 N hydrochloric acid was added for extraction; the organic layer was washed with 1 N hydrochloric acid, a saturated aqueous solution of sodium hydrogen carbonate, and saturated brine; and subsequently anhydrous magnesium sulfate was added and drying was performed. Filtration was performed, and subsequently the solvent in the filtrate was distilled off under a reduced pressure; and drying in a vacuum was performed to provide 32.3 g of a compound (B-2-1).

### (2) Synthesis of B-2-2

The compound (B-2-1) (5.00 g), 17.0 g of 4-(methoxycarbonyl)phenylboronic acid, 20.1 g of potassium phosphate, 645 mg of Sphos, 100 g of tetrahydrofuran, and 30 g of pure water were charged and degassed. Subsequently, 177 mg of palladium acetate was added and stirring was performed at 80° C. for 10 hours. To the reaction mixture, ethyl acetate was added for extraction, and the organic layer was washed with saturated brine; and subsequently, anhydrous magnesium sulfate was added and drying was performed. Filtration was performed, and subsequently the filtrate was passed through silica gel and washed with ethyl acetate. The solvent was distilled off under a reduced pressure; subsequently, to the crude product, 40 ml of chloroform was added to dissolve the crude product; 200 mg of activated carbon ANOX2 (manufactured by Osaka Gas Chemicals Co., Ltd.) and 100 mg of trimercaptotriazine were added and stirring was performed at room temperature for 2 hours (the activated carbon and trimercaptotriazine adsorb palladium serving as a catalyst). Filtration was performed to remove activated carbon ANOX2; the chloroform organic layer was washed with a 10 wt % aqueous sodium hydrogen carbonate solution, subsequently washed twice with a 0.1 mol/L aqueous hydrochloric acid solution, and further washed twice with ultrapure water. The solvent was distilled off under a reduced pressure, subsequently 50 ml of ethyl acetate was added and distilled off under a reduced pressure to thereby azeotropically dehydrate water. The resultant crude product was recrystallized from ethyl acetate/n-hexane and dried in a vacuum to provide 3.52 g of a compound (B-2-2).

### (3) Synthesis of B-2-3

The compound (B-2-2) (2.00 g), 40 g of acetonitrile, and 534 mg of sodium iodide were charged and stirred at 80° C. for 8 hours. The solid was filtered off and washed with acetone and hexane. Drying in a vacuum provided 1.54 g of a compound (B-2-3).

### (4) Synthesis of B-2

The compound (B-2-3) (1.50 g), 882 mg of triphenylsulfonium bromide, 10 g of methylene chloride, and 10 g of pure water were charged, and stirred at room temperature for 3 hours. The organic phase was washed with pure water; subsequently, the solvent was distilled off under a reduced pressure, and isopropyl ether was used to cause azeotropy. The resultant crude product was recrystallized from ethyl acetate/isopropyl ether, and dried in a vacuum to provide a compound (B-2) (2.10 g).

Note that the ¹H-NMR spectrum (400 MHz, DMSO-d6) of the compound (B-2) was 6=8.05-7.69 (m, 27H), 7.47 (s, 2H), 3.88 (s, 6H), 3.86 (s, 3H).

### Synthesis Example 5: Synthesis of Photoacid Generator (B-3)

The same method as in the synthesis of Compound (B-2) was performed except that 17.0 g of 4-(methoxycarbonyl)phenylboronic acid was changed to 13.0 g of 4-hydroxyphenylboronic acid, to provide 2.23 g of a compound (B-3).

Note that the ¹H-NMR spectrum (400 MHz, DMSO-d6) of the compound (B-3) was 6=9.53 (s, 1H), 9.12 (s, 2H), 7.90-7.19 (m, 21H), 7.14 (s, 2H), 6.84-6.63 (m, 6H).

Hereinafter, the same method was used to synthesize compounds (B-1) and (B-4) to (B-80). The above-described Software package 1 was used to confirm that the compounds (B-1) to (B-80) generated acids having a pKa of −10 or more and 5 or less. Note that Me represents a methyl group.

The compounds (B-1) to (B-80) are combinations of a cation described in Table 2 and an anion described in Table 2.

Compositions were prepared using, of the above-described compounds, the compounds (B-1) to (B-4), (B-6), (B-7), (B-9) to (B-22), (B-24) to (B-28), (B-30), (B-32), (B-34) to (B-37), (B-39), (B-41) to (B-45), (B-47) to (B-50), (B-51), (B-53), (B-62), (B-65), (B-66), (B-69), (B-72), and (B-78).

For Comparative Examples, the following Compounds (BX-1) and (BX-2) were used.

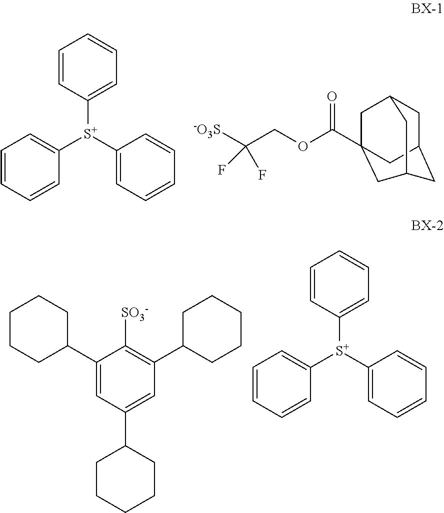

TABLE 2

| | | Cation | | | | | | | | | | | | | |
|---|---|---|---|---|---|---|---|---|---|---|---|---|---|---|---|
| PAG | | 1 | 2 | 3 | 4 | 5 | 6 | 7 | 8 | 9 | 10 | 11 | 12 | 13 | 14 |
| Anion | 1 | B-64 | B-78 | B-65 | | | | B-66 | | | | | | | |
| | 2 | B-73 | | | | | | | | | | | | | |
| | 3 | B-1 | B-4 | | | | | | | | | | | | |
| | 1 | B-3 | | | B-57 | | | | B-37 | | | | | | |
| | 5 | B-2 | B-43 | B-6 | | | | | | | B-59 | | | | |
| | 6 | | B-48 | | | | | | | | | | | | |
| | 7 | | B-32 | | | | | | | | | | | B-27 | |
| | 8 | B-28 | | | | | | | | | | | | | |
| | 9 | | | | B-80 | | | | | | | B-50 | | | |
| | 10 | B-53 | B-31 | | | | B-26 | | | B-56 | | | | | |
| | 11 | B-55 | | | | B-54 | | | | | | | | | |
| | 12 | | B-17 | | | | | B-61 | | | | | | | |
| | 13 | B-47 | | | | | | | | | | | | | |
| | 14 | B-79 | | | | | | | | | | | | | |
| | 15 | | | | B-70 | | | | | | | | | | |
| | 16 | | B-23 | | | | | | | | B-25 | | | | |
| | 17 | B-29 | | | | | | | | | | B-44 | | | B-24 |
| | 18 | | B-46 | | | | | | | | | | | | |
| | 19 | B-35 | | | B-33 | | B-58 | | | | | | | | |
| | 20 | B-75 | B-72 | | | | | B-36 | | | | | | | |
| | 21 | B-76 | B-18 | | | | | | | | | | | | |
| | 22 | | | | | | | | | | | B-19 | | | |
| | 23 | B-52 | B-34 | | | | | | | | | | | | |
| | 24 | | B-38 | | B-14 | | | | | | | | | | |
| | 25 | | | | | | | | | | | | B-20 | | |
| | 26 | B-62 | B-67 | | | | | | | | | | | | |
| | 27 | B-8 | | | | | | | | | | | | | |
| | 28 | B-12 | | | | | | | | B-45 | | | | | |
| | 29 | B-16 | | | | | | | | | | | B-49 | | |
| | 30 | | | B-69 | | | | | B-51 | | | B-71 | | | |
| | 31 | B-13 | B-68 | | | | | | | | | | | | |
| | 32 | B-15 | | | B-63 | | | | | | | | | | |
| | | | Cation | | | | | | | | | | | | |
| | PAG | | 15 | 16 | 17 | 18 | 19 | 20 | 21 | 22 | 23 | 24 | 25 | 26 | 27 |
| | Anion | 1 | B-77 | B-5 | | | | | | | | B-42 | | | |
| | | 2 | | B-74 | B-7 | | | | | | | | | | |
| | | 3 | | | | | | | B-39 | | | | | | B-40 |
| | | 1 | | | | B-11 | | | | | | | | | |
| | | 5 | | | | | | | | | | | B-9 | | |
| | | 6 | | | | | | | | | | | | | |
| | | 7 | | | | | | | | | | | | | |
| | | 8 | | | | | | | | | B-22 | | | | |
| | | 9 | | | | | | | | B-21 | | | | | |
| | | 10 | | | | | | | | | | | | | |
| | | 11 | | | | | B-60 | | | | | | | | |
| | | 12 | | | | | | | | | | | | | |
| | | 13 | | | | | | | | | | | | | |
| | | 14 | | | | | | | | | | | | | |
| | | 15 | | | | | | | | | | | | | |
| | | 16 | | | | | | | | | | | | | |
| | | 17 | | | | | | | | | | | | | |
| | | 18 | | | | | | | | | | | | | |
| | | 19 | | | | | | | | | | | | | |
| | | 20 | | | | | | | | | | | | | |
| | | 21 | | | | | | | | | | | | | |
| | | 22 | | | | | | | | | | | | | |
| | | 23 | | | | | | | | | | | | | |
| | | 24 | | | | | | | B-10 | | | | | | |
| | | 25 | | | | | | | | | | | | | |
| | | 26 | | | | | | | | | | | | | |
| | | 27 | | | | | | | | | | | | B-41 | |
| | | 28 | | | | | | | | | | | | | |
| | | 29 | B-30 | | | | | | | | | | | | |
| | | 30 | | | | | | | | | | | | | |
| | | 31 | | | | | | | | | | | | | |
| | | 32 | | | | | | | | | | | | | |

The structures of the cations described in Table 2 will be described below. Me represents a methyl group, and Bu represents an n-butyl group.

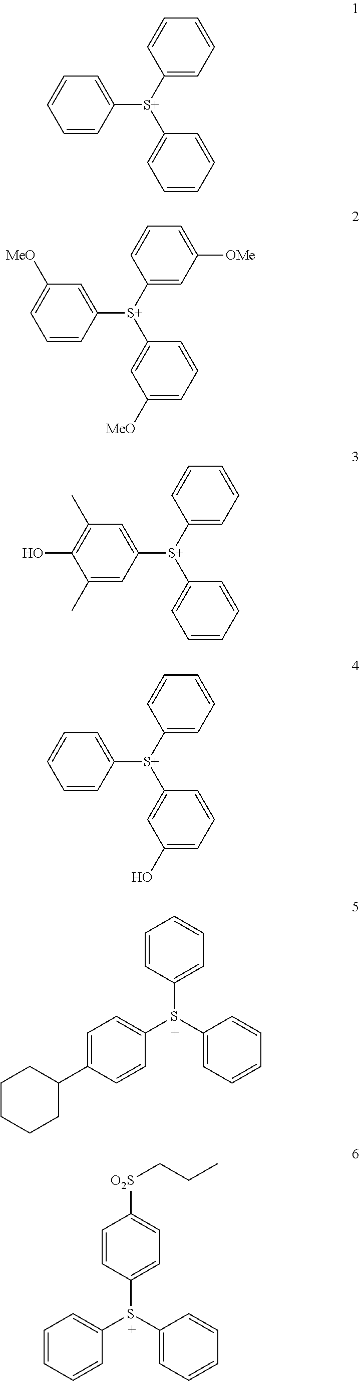

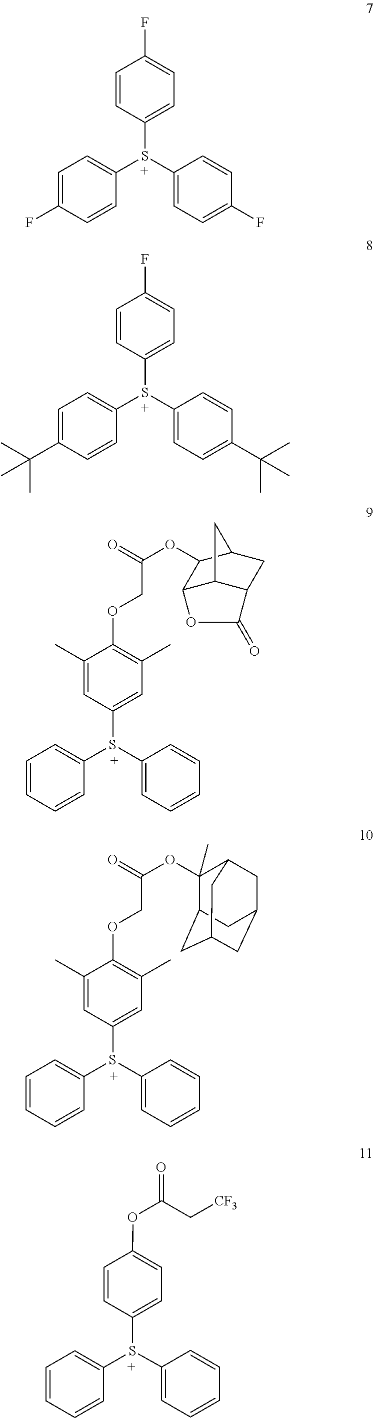

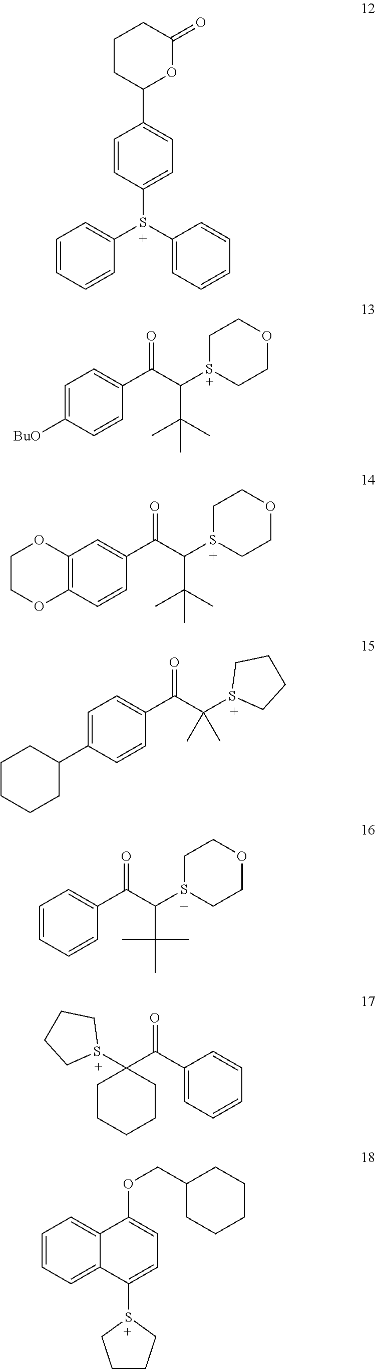

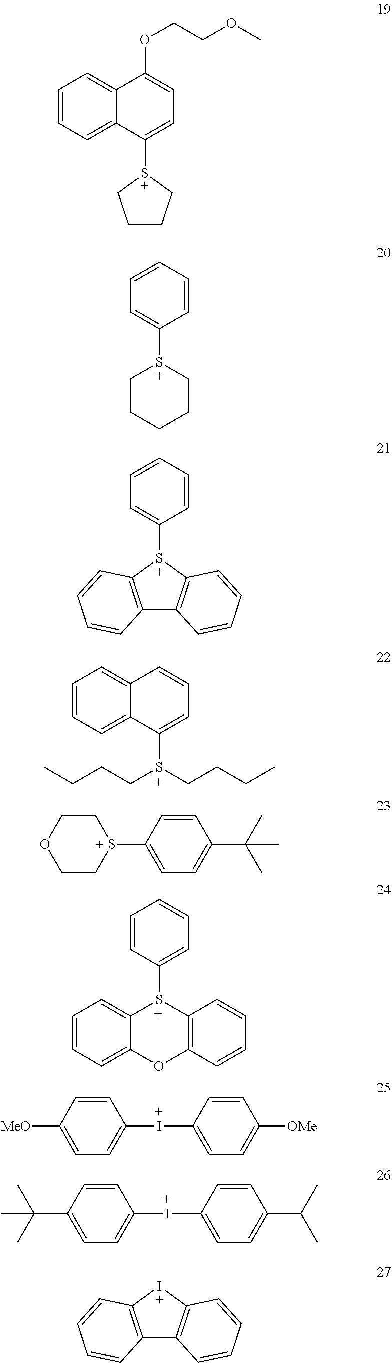

The structures of the anions described in Table 2 will be described below. Me represents a methyl group, and Bu represents an n-butyl group.

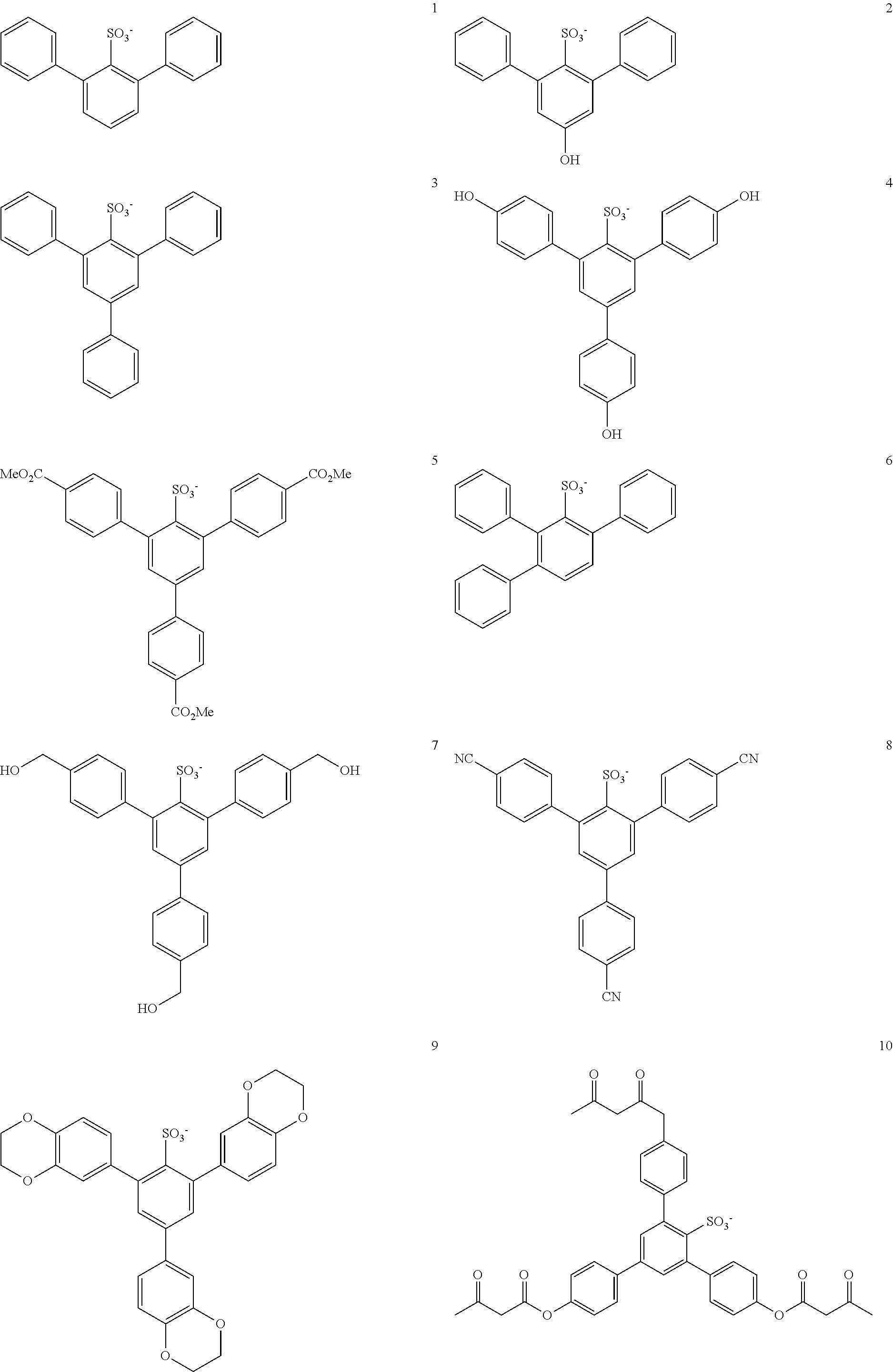

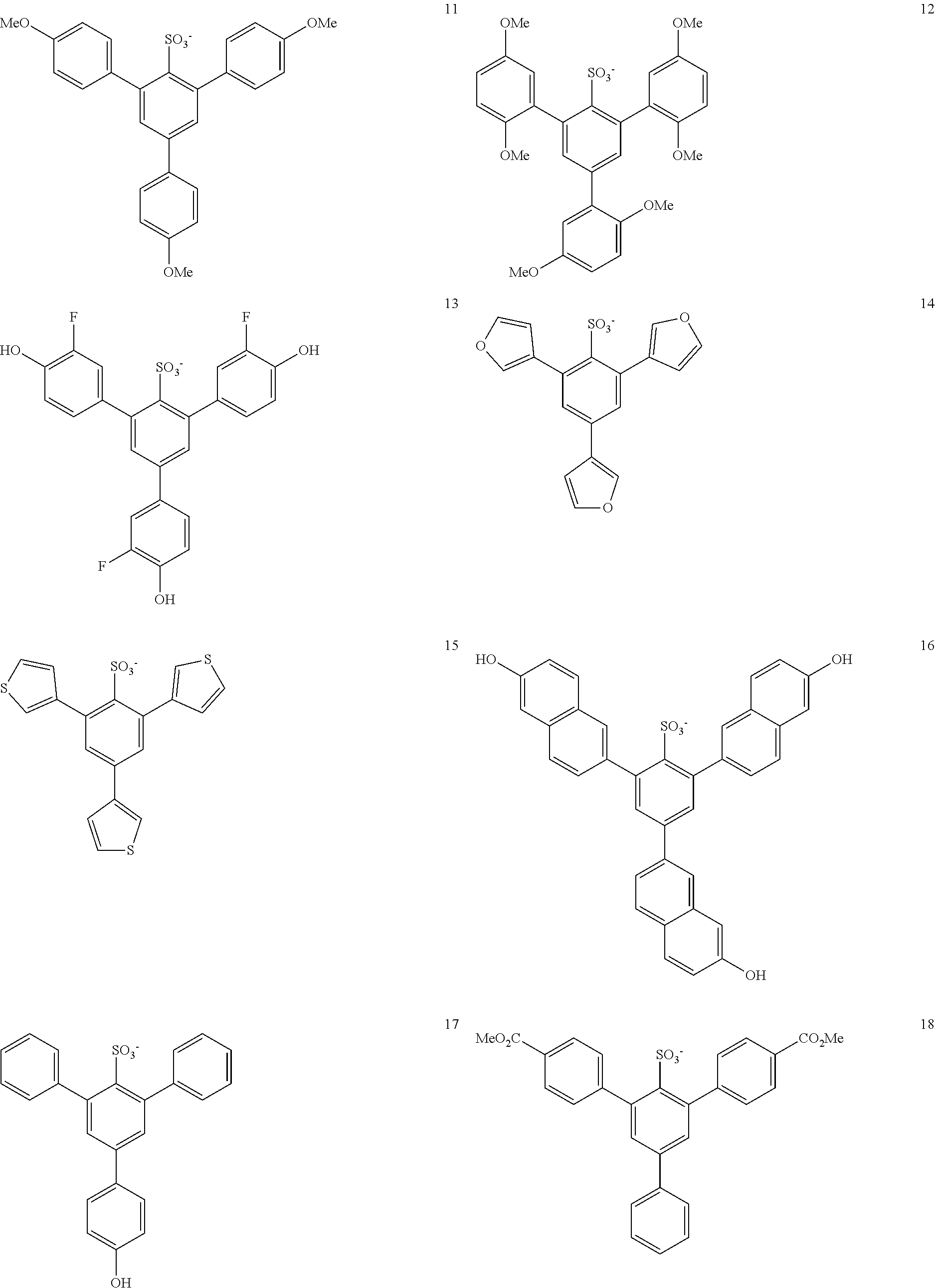

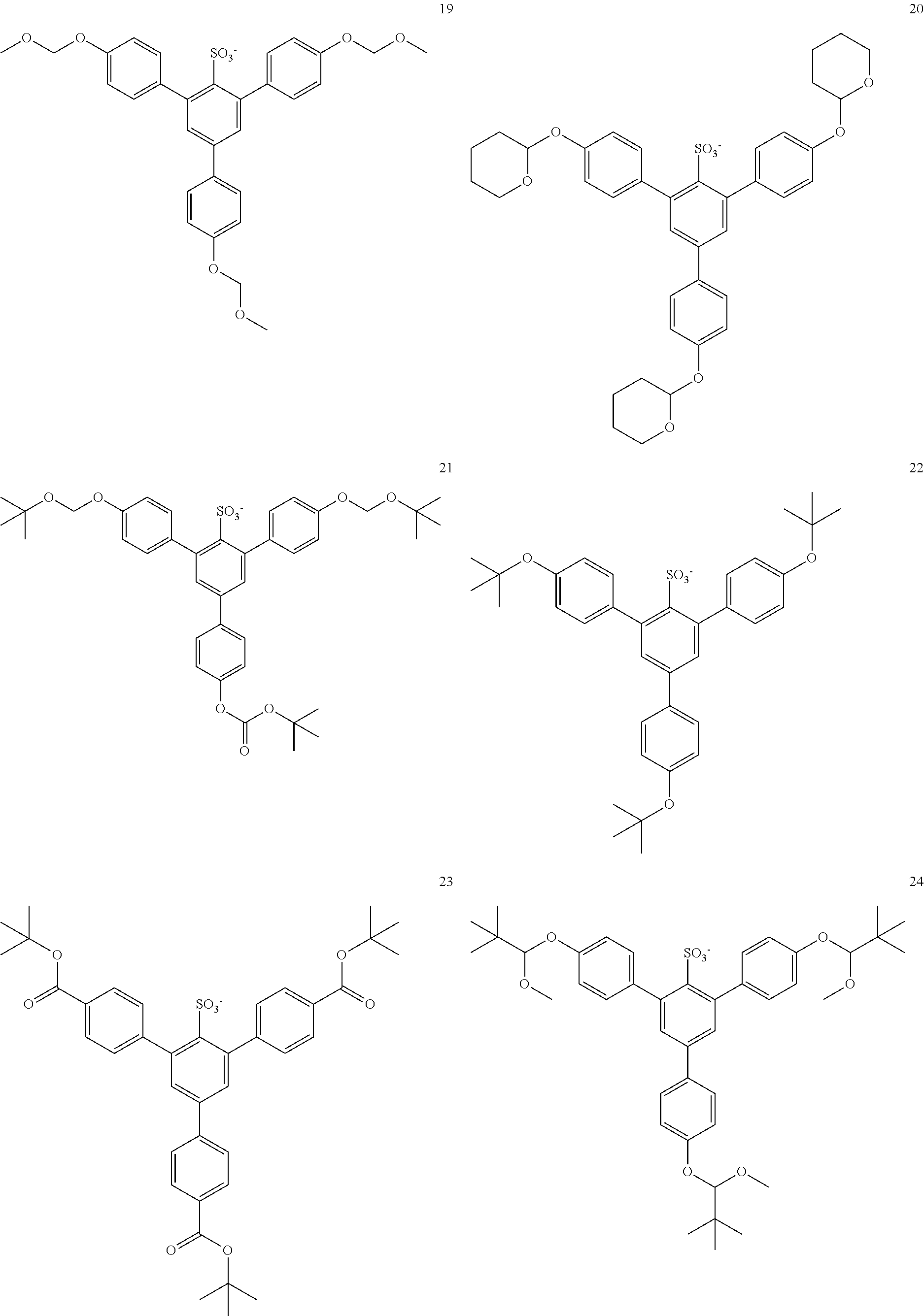

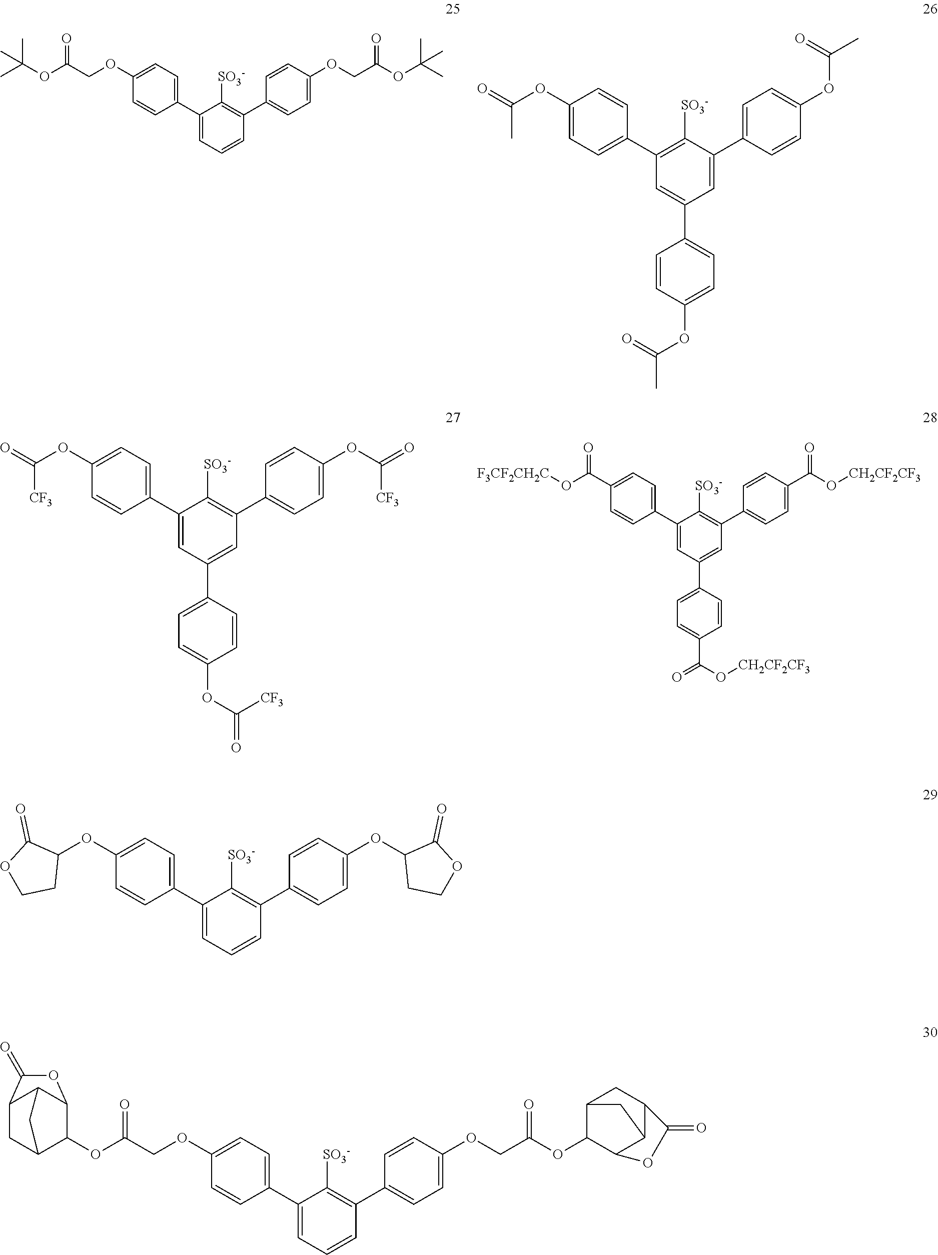

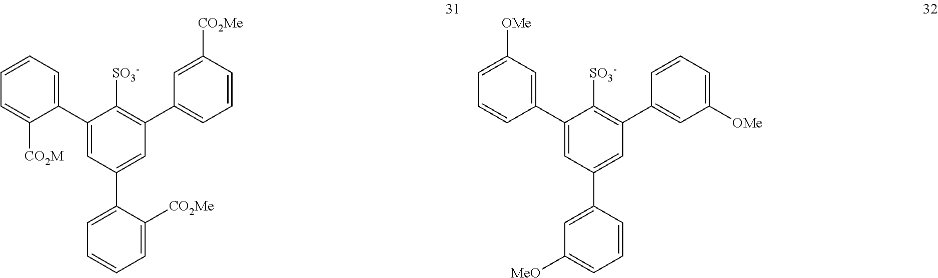

### Acid Diffusion Control Agent

The structures of the acid diffusion control agents used will be described below.

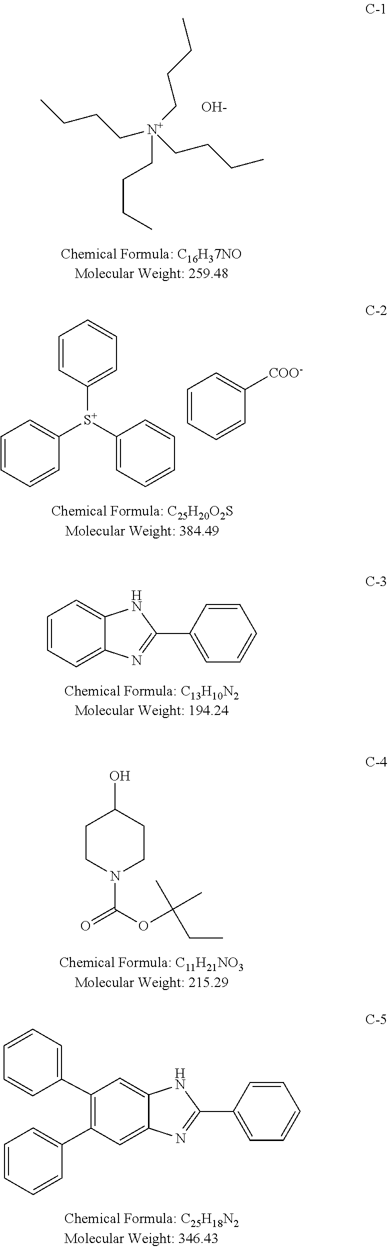

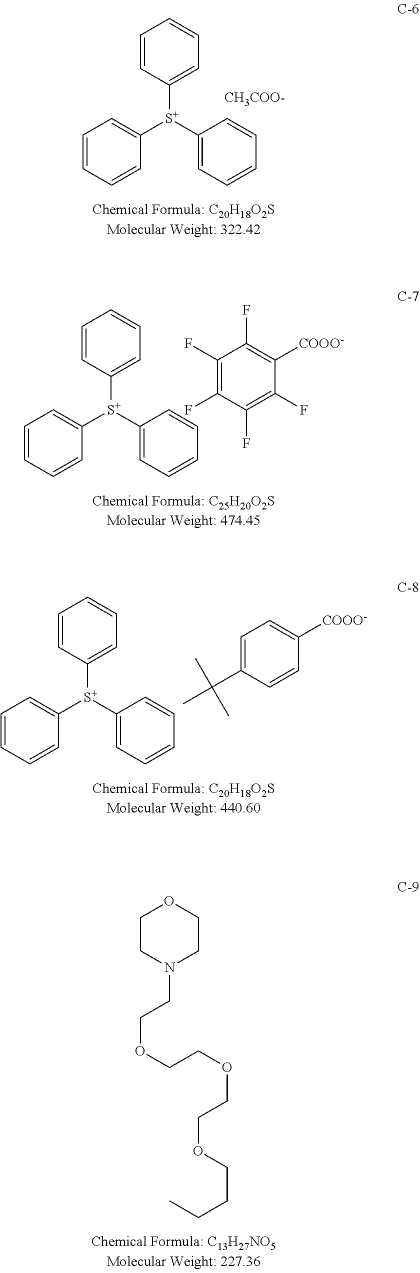

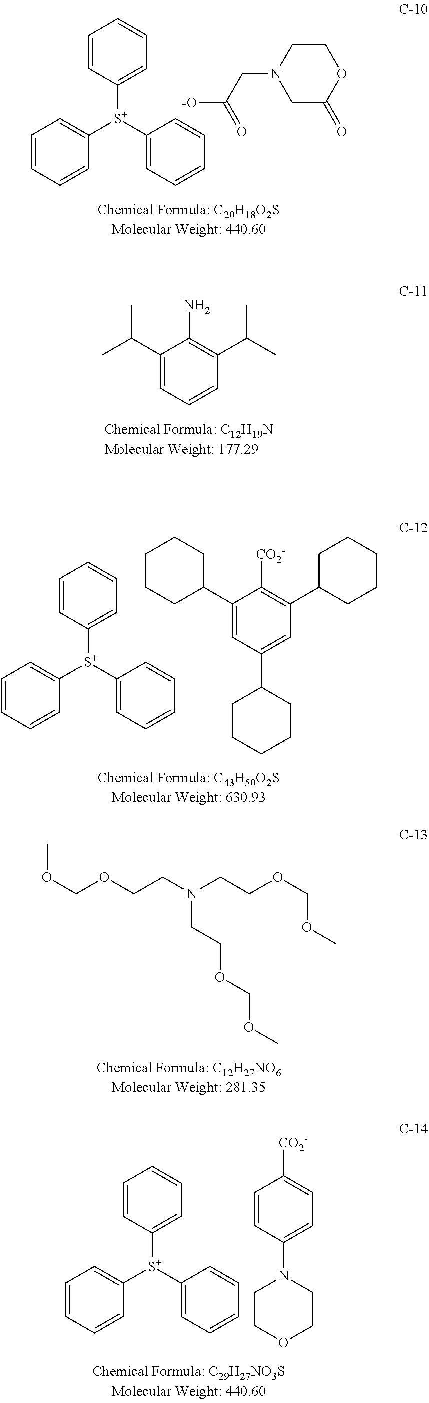

### Surfactant

As surfactants, the following W-1 to W-4 were used.
W-1: MEGAFACE R08 (manufactured by Dainippon Ink and Chemicals, Inc. fluorine and silicone-based)
W-2: polysiloxane polymer KP-341 (manufactured by Shin-Etsu Chemical Co., Ltd.; silicone-based)
W-3: Troysol 5-366 (manufactured by Troy Chemical Corporation; fluorine-based)
W-4: PF6320 (manufactured by OMNOVA Solutions Inc.; fluorine-based)

### Solvent

The solvents used will be described below.
S-1: diacetone alcohol (DAA)
S-2: propylene glycol monomethyl ether acetate (PGMEA)
S-3: propylene glycol monomethyl ether (PGME)
S-4: ethyl lactate (EL)
S-5: ethyl 3-ethoxypropionate (EEP)
S-6: 2-heptanone (MAK)
S-7: methyl 3-methoxypropionate (MMP)
S-8: 3-methoxybutyl acetate
S-9: γ-butyrolactone

### Preparation and Application of Coating Liquid of Resist Composition

### (1) Preparation of Support

An 8-inch wafer on which Cr oxynitride was vapor-deposited (wafer used for an ordinary photo mask blank and having been subjected to the shielding-film treatment) was prepared.

### (2) Preparation of Resist Composition

The components described in Table 3 were dissolved in the solvent described in the same table to prepare a solution having a solid content concentration described in the same table; and the solution was filtered through a polyethylene filter having a pore size of 0.03 m to prepare a resist composition.

### (3) Preparation of Resist Film

The resist composition was applied onto the 8-inch wafer using a spin coater Mark8 manufactured by Tokyo Electron Ltd., and dried on a hot plate at 120° C. for 600 seconds to provide a resist film having a film thickness of 100 nm. Thus, a resist-coated wafer was obtained. EB exposure and development

### (4) Preparation of Resist Pattern

The resist film obtained in (3) above was irradiated to form a pattern using an electron-beam lithography apparatus (manufactured by ADVANTEST CORPORATION; F7000S, accelerating voltage: 50 KeV). After the irradiation, heating at 100° C. for 600 seconds on a hot plate was performed; immersion using a 2.38 mass % aqueous solution of tetramethylammonium hydroxide (TMAH) for 60 seconds was performed; subsequently, rinsing with water for 30 seconds and drying were performed.

### Evaluations

### (5) Evaluation of Resist Pattern

The obtained pattern was evaluated for resolution, roughness performance, pattern profile, and development defects by the following methods. The results will be described later in Table 4.

The irradiation energy for resolving a 1:1 line-and-space pattern having a line width of 50 nm was defined as sensitivity (Eop).

### L/S Resolution

The limiting resolving power (minimum line width at which a line and a space (line:space=1:1) are separated and resolved) at the exposure dose providing the above-described sensitivity (Eop) was defined as the resolving power (nm).

### Roughness Performance

The roughness performance was evaluated on the basis of line width roughness (LWR) in the following manner.

For the line width roughness, the line widths were measured at 50 points randomly selected over 0.5 m in the longitudinal direction of a line-and-space pattern (line:space=1:1) having a line width of 50 nm and provided at the above-described Eop; and the standard deviations of the line widths were determined and 3σ (nm) was calculated. The smaller the value, the higher the performance.

### Pattern Profile

Profiles of 1:1 line-and-space patterns having a line width of 50 nm and formed at an irradiation dose providing the above-described sensitivity were observed using a scanning electron microscope (S-4800 manufactured by Hitachi, Ltd.) and evaluated: a profile of a line pattern in which a ratio represented by [line width at top portion (surface portion) of line pattern/line width at middle portion (at height position corresponding to half of height of line pattern) of line pattern] was 1.1 or more, was evaluated as “Reverse taper”; a profile of a line pattern in which the ratio was 1.03 or more and less than 1.1 was evaluated as “Slightly reverse taper”; and a profile of a line pattern in which the ratio was less than 1.03 was evaluated as “Square”.

### Development Defects

The 1:1 line-and-space pattern having a line width of 50 nm and formed at the sensitivity (Eop) was, using a defect inspection apparatus KLA2360 (trade name) manufactured by KLA-Tencor Corporation such that, in the defect inspection apparatus, the pixel size was set to 0.16 m and the threshold value was set to 20, superimposed on a comparison image on a pixel-by-pixel basis; from the resultant difference, defects (defects/cm²) were extracted and detected and the number of defects (defects/cm²) per unit area was calculated. Subsequently, the defects were reviewed to thereby classify and extract development defects from all the defects, and the number of development defects per unit area (defects/cm²) was calculated. Cases in which the value was less than 0.5 were evaluated as A; cases in which the value was 0.5 or more and less than 1.0 were evaluated as B; cases in which the value was 1.0 or more and less than 5.0 were evaluated as C; and cases in which the value was 5.0 or more were evaluated as D. The smaller the value, the higher the performance.

Note that, in Table 3 below, the content (mass %) of each component other than the solvent means the content ratio relative to the total solid content. In addition, Table 3 below describes the content ratios (mass %) of solvents used to all the solvents.

Table 3 below describes the content (mass %) of the repeating unit (a) included in the resin (A), as “Repeating unit (a) in resin (A)”.

Table 3 also describes the mass ratio (repeating unit (a)/photoacid generator (B)) of the repeating unit (a) to the photoacid generator (B) in the composition, as “Repeating unit (a)/Photoacid generator (B)”.

TABLE 3

| | Resin (A) | | | | | | | Repeating | |
|---|---|---|---|---|---|---|---|---|---|
| | | | Repeating | Photoacid generator | | Acid diffusion control | | unit (a)/ | Surfactant |
| | | | unit (a) in | (B) | | agent | | Photoacid | Type |
| Resist | | Content | resin (A) | | Content | | Content | generator | (0.01 |
| composition | Compound | (mass %) | (mass %) | Compound | (mass %) | Compound | (mass %) | (B) | mass %) |
| R-1 | (A-1) | 85.23 | 56.10 | (B-62) | 14.57 | C-1 | 0.20 | 3.28 | |
| R-2 | (A-2) | 88.82 | 52.27 | (B-32) | 10.98 | C-2 | 0.19 | 4.23 | W-1 |
| R-3 | (A-3) | 89.62 | 45.84 | (B-6) | 10.13 | C-4 | 0.25 | 4.06 | |
| R-4 | (A-4) | 90.32 | 47.66 | (B-4) | 9.50 | C-6 | 0.18 | 4.53 | |
| R-5 | (A-5) | 82.35 | 42.76 | (B-21) | 17.47 | C-10 | 0.17 | 2.02 | W-1 |
| R-6 | (A-6) | 94.65 | 35.02 | (B-3) | 5.17 | C-9 | 0.18 | 6.41 | |
| R-7 | (A-7) | 92.31 | 20.99 | (B-7) | 7.49 | C-5 | 0.19 | 2.59 | W-4 |
| R-8 | (A-8) | 87.23 | 45.07 | (B-37) | 12.62 | C-11 | 0.15 | 3.12 | |
| R-9 | (A-9) | 89.32 | 19.13 | (B-9) | 10.50 | C-8 | 0.18 | 1.63 | |
| R-10 | (A-10) | 75.34 | 26.14 | (B-10) | 24.47 | C-7 | 0.18 | 0.80 | W-4 |
| R-11 | (A-11) | 85.01 | 50.17 | (B-11) | 14.85 | C-3 | 0.13 | 2.87 | W-2 |
| R-12 | (A-12) | 88.13 | 37.39 | (B-35) | 11.76 | C-3 | 0.11 | 2.80 | |
| R-13 | (A-13) | 94.21 | 48.44 | (B-13) | 5.66 | C-4 | 0.13 | 8.06 | |
| R-14 | (A-14) | 88.23 | 49.96 | (B-14) | 11.65 | C-4 | 0.11 | 3.78 | W-3 |
| R-15 | (A-15) | 90.52 | 37.85 | (B-15) | 9.34 | C-14 | 0.14 | 3.67 | |
| R-16 | (A-16) | 91.50 | 56.90 | (B-16) | 8.37 | C-13 | 0.13 | 6.22 | |
| R-17 | (A-17) | 86.81 | 36.60 | (B-17) | 13.04 | C-3 | 0.15 | 2.44 | |
| R-18 | (A-18) | 89.01 | 53.07 | (B-1) | 10.90 | C-7 | 0.09 | 4.33 | |
| R-19 | (A-19) | 88.37 | 65.88 | (B-19) | 11.48 | C-4 | 0.15 | 5.07 | |
| R-20 | (A-20) | 89.50 | 45.98 | (B-20) | 10.35 | C-1 | 0.15 | 3.98 | |
| R-21 | (A-21) | 77.62 | 59.45 | (B-35) | 22.03 | C-2 | 0.35 | 2.09 | |
| R-22 | (A-22) | 91.27 | 55.48 | (B-22) | 8.63 | C-4 | 0.09 | 5.87 | W-4 |
| R-23 | (A-23) | 87.68 | 53.72 | (B-32) | 12.13 | C-5 | 0.18 | 3.88 | W-2 |
| R-24 | (A-24) | 91.40 | 24.77 | (B-24) | 8.47 | C-3 | 0.13 | 2.67 | |
| R-25 | (A-25) | 86.00 | 45.97 | (B-69) | 13.88 | C-11 | 0.12 | 2.85 | |
| R-26 | (A-26) | 85.25 | 59.46 | (B-26) | 14.64 | C-4 | 0.11 | 3.46 | |
| R-27 | (A-27) | 86.96 | 11.75 | (B-27) | 12.92 | C-10 | 0.11 | 0.79 | W-2 |
| R-28 | (A-28) | 92.42 | 52.57 | (B-28) | 7.42 | C-12 | 0.16 | 6.55 | |
| R-29 | (A-29) | 89.38 | 29.81 | (B-66) | 10.44 | C-4 | 0.18 | 2.55 | |
| R-30 | (A-30) | 86.43 | 53.49 | (B-49) | 13.36 | C-7 | 0.20 | 3.46 | W-2 |
| R-31 | (A-31) | 90.33 | 44.60 | (B-18) | 9.48 | C-3 | 0.19 | 4.25 | |
| R-32 | (A-32) | 92.03 | 51.36 | (B-2) | 7.84 | C-4 | 0.13 | 6.03 | |
| R-33 | (A-33) | 91.90 | 33.72 | (B-78) | 7.92 | C-9 | 0.17 | 3.91 | W-2 |
| R-34 | (A-34) | 88.37 | 46.68 | (B-34) | 11.48 | C-2 | 0.15 | 3.59 | |
| R-35 | (A-35) | 88.74 | 30.04 | (B-12) | 11.08 | C-2 | 0.18 | 2.41 | |
| R-36 | (A-36) | 93.13 | 54.93 | (B-36) | 6.75 | C-4 | 0.11 | 7.58 | W-1 |
| R-37 | (A-37) | 89.68 | 41.66 | (B-25) | 10.20 | C-4 | 0.12 | 3.66 | |
| R-38 | (A-38) | 81.53 | 55.28 | (B-20) | 18.34 | C-2 | 0.13 | 2.46 | |
| R-39 | (A-39) | 88.64 | 37.01 | (B-39) | 11.15 | C-2 | 0.21 | 2.94 | |
| R-40 | (A-40) | 91.66 | 51.39 | (B-53) | 8.25 | C-3 | 0.09 | 5.71 | |
| R-41 | (A-41) | 92.11 | 47.97 | (B-41) | 7.75 | C-13 | 0.14 | 5.70 | |
| R-42 | (A-42) | 94.76 | 17.71 | (B-42) | 5.10 | C-12 | 0.14 | 3.29 | |
| R-43 | (A-43) | 91.08 | 64.97 | (B-43) | 8.82 | C-7 | 0.10 | 6.71 | |
| R-44 | (A-44) | 93.91 | 22.96 | (B-44) | 5.91 | C-4 | 0.18 | 3.65 | |
| R-45 | (A-45) | 90.69 | 45.11 | (B-45) | 9.11 | C-13 | 0.20 | 4.49 | |
| R-46 | (A-38) | 88.59 | 55.28 | (B-65) | 11.30 | C-2 | 0.11 | 4.33 | |
| R-47 | (A-27) | 88.79 | 11.75 | (B-47) | 11.01 | C-3 | 0.19 | 0.95 | W-2 |
| R-48 | (A-8) | 86.49 | 45.07 | (B-48) | 13.21 | C-5 | 0.30 | 2.95 | |
| R-49 | (A-1) | 94.11 | 56.10 | (B-30) | 5.67 | C-1 | 0.22 | 9.31 | |
| R-50 | (A-39) | 90.41 | 37.01 | (B-50) | 9.42 | C-11 | 0.17 | 3.55 | |
| R-51 | (A-7) | 91.88 | 9.46 | (B-7) | 7.93 | C-5 | 0.19 | 1.10 | |
| RX-1 | AX-1 | 90.35 | 0.00 | (B-20) | 9.42 | C-2 | 0.23 | 0.00 | |
| RX-2 | AX-2 | 89.74 | 0.00 | (B-35) | 10.05 | C-3 | 0.21 | 0.00 | |
| RX-3 | (A-1) | 92.65 | 56.10 | BX-1 | 7.16 | C-13 | 0.18 | 7.26 | W-2 |
| RX-4 | AX-3 | 91.82 | 0.00 | (B-1) | 8.00 | C-1 | 0.18 | 0.00 | |
| RX-5 | AX-4 | 90.26 | 0.00 | (B-1) | 9.57 | C-3 | 0.17 | 0.00 | |
| RX-6 | (A-3) | 92.81 | 45.84 | BX-2 | 6.97 | C-4 | 0.22 | 6.10 | |
| RX-7 | AX-5 | 89.63 | 0.00 | (B-20) | 10.14 | C-2 | 0.23 | 0.00 | |
| R-52 | A-47 | 91.65 | 55.98 | (B-1) | 8.06 | C-4 | 0.29 | 6.36 | |
| R-53 | A-48 | 90.64 | 52.42 | (B-12) | 9.14 | C-2 | 0.22 | 5.20 | |
| R-54 | A-49 | 88.65 | 41.86 | (B-51) | 11.16 | C-10 | 0.19 | 3.33 | |
| R-55 | A-50 | 89.13 | 56.72 | (B-62) | 10.64 | C-3 | 0.23 | 4.75 | |
| R-56 | A-51 | 90.02 | 39.43 | (B-3) | 9.73 | C-11 | 0.25 | 3.65 | |
| R-57 | A-52 | 88.14 | 49.09 | (B-72) | 11.57 | C-8 | 0.29 | 3.74 | |
| R-58 | A-53 | 90.67 | 52.46 | (B-22) | 9.12 | C-1 | 0.21 | 5.22 | |
| R-59 | A-54 | 87.69 | 41.65 | (B-36) | 12.13 | C-13 | 0.18 | 3.01 | |
| R-60 | A-55 | 84.99 | 38.56 | (B-48) | 14.78 | C-6 | 0.23 | 2.22 | |
| R-61 | A-56 | 89.37 | 43.67 | (B-50) | 10.37 | C-2 | 0.26 | 3.76 | |
| | | | Solvent | | | | | | |
| | | | | Content | | Content | | Content | |
| | | | | ratio of | | ratio of | | ratio of | |
| | | | | solvent | | solvent | | solvent | Solid content |
| | | Resist | Solvent | 1 | Solvent | 2 | Solvent | 3 | concentration |
| | | composition | 1 | (mass %) | 2 | (mass %) | 3 | (mass %) | (mass %) |
| | | R-1 | S-1 | 30 | S-2 | 20 | S-6 | 50 | 2.8 |
| | | R-2 | S-1 | 90 | S-4 | 10 | — | | 2.8 |
| | | R-3 | S-1 | 70 | S-2 | 20 | S-3 | 10 | 3.0 |
| | | R-4 | S-1 | 20 | S-2 | 20 | S-3 | 60 | 3.3 |
| | | R-5 | S-1 | 20 | S-5 | 50 | S-7 | 30 | 2.9 |
| | | R-6 | S-1 | 70 | S-2 | 20 | S-3 | 10 | 2.7 |
| | | R-7 | S-1 | 70 | S-4 | 25 | S-5 | 5 | 3.1 |
| | | R-8 | S-2 | 30 | S-3 | 50 | S-4 | 20 | 3.2 |
| | | R-9 | S-1 | 30 | S-2 | 20 | S-3 | 50 | 2.7 |
| | | R-10 | S-1 | 40 | S-2 | 25 | S-4 | 35 | 3.9 |
| | | R-11 | S-1 | 50 | S-2 | 50 | — | | 4.5 |
| | | R-12 | S-1 | 20 | S-3 | 50 | S-7 | 30 | 3.2 |
| | | R-13 | S-1 | 55 | S-4 | 30 | S-8 | 15 | 3.1 |
| | | R-14 | S-1 | 40 | S-5 | 10 | S-9 | 50 | 2.8 |
| | | R-15 | S-1 | 50 | S-4 | 20 | S-7 | 30 | 4.0 |
| | | R-16 | S-1 | 30 | S-4 | 25 | S-7 | 45 | 3.5 |
| | | R-17 | S-1 | 50 | S-4 | 50 | — | | 3.5 |
| | | R-18 | S-1 | 20 | S-2 | 30 | S-3 | 50 | 3.3 |
| | | R-19 | S-1 | 20 | S-2 | 70 | S-3 | 10 | 2.7 |
| | | R-20 | S-1 | 40 | S-6 | 20 | S-8 | 40 | 2.5 |
| | | R-21 | S-1 | 40 | S-4 | 50 | S-5 | 10 | 3.1 |
| | | R-22 | S-1 | 30 | S-3 | 50 | S-7 | 20 | 3.5 |
| | | R-23 | S-2 | 10 | S-3 | 50 | S-7 | 40 | 5.6 |
| | | R-24 | S-2 | 20 | S-3 | 20 | S-9 | 60 | 4.8 |
| | | R-25 | S-1 | 10 | S-2 | 70 | S-9 | 20 | 5.0 |
| | | R-26 | S-1 | 60 | S-2 | 40 | — | | 4.3 |
| | | R-27 | S-1 | 55 | S-4 | 45 | — | | 5.3 |
| | | R-28 | S-1 | 50 | S-2 | 40 | S-8 | 10 | 3.2 |
| | | R-29 | S-1 | 80 | S-4 | 20 | — | | 3.2 |
| | | R-30 | S-1 | 70 | S-2 | 15 | S-3 | 15 | 4.2 |
| | | R-31 | S-1 | 60 | S-3 | 40 | — | | 3.3 |
| | | R-32 | S-1 | 20 | S-2 | 20 | S-3 | 60 | 4.6 |
| | | R-33 | S-3 | 40 | S-4 | 30 | S-8 | 30 | 3.1 |
| | | R-34 | S-1 | 20 | S-2 | 50 | S-5 | 30 | 3.8 |
| | | R-35 | S-1 | 20 | S-2 | 70 | S-6 | 10 | 2.8 |
| | | R-36 | S-3 | 70 | S-4 | 30 | — | | 3.2 |
| | | R-37 | S-4 | 60 | S-2 | 40 | — | | 2.7 |
| | | R-38 | S-1 | 50 | S-3 | 50 | — | | 3.8 |
| | | R-39 | S-1 | 60 | S-2 | 40 | — | | 3.5 |
| | | R-40 | S-1 | 60 | S-4 | 40 | — | | 4.1 |
| | | R-41 | S-1 | 50 | S-2 | 50 | — | | 3.2 |
| | | R-42 | S-1 | 70 | S-2 | 30 | — | | 2.9 |
| | | R-43 | S-1 | 65 | S-2 | 35 | — | | 4.3 |
| | | R-44 | S-1 | 65 | S-5 | 30 | S-6 | 5 | 4.0 |
| | | R-45 | S-1 | 50 | S-4 | 20 | S-5 | 30 | 3.3 |
| | | R-46 | S-1 | 50 | S-4 | 40 | S-5 | 10 | 3.2 |
| | | R-47 | S-1 | 65 | S-4 | 20 | S-7 | 15 | 4.7 |
| | | R-48 | S-2 | 50 | S-3 | 50 | — | | 3.0 |
| | | R-49 | S-2 | 20 | S-3 | 20 | S-8 | 60 | 3.4 |
| | | R-50 | S-1 | 30 | S-2 | 70 | — | | 2.8 |
| | | R-51 | S-1 | 70 | S-4 | 25 | S-5 | 5 | 3.3 |
| | | RX-1 | S-1 | 60 | S-2 | 40 | — | | 4.1 |
| | | RX-2 | S-1 | 55 | S-4 | 45 | — | | 3.8 |
| | | RX-3 | S-1 | 60 | S-2 | 40 | — | | 3.5 |
| | | RX-4 | S-1 | 60 | S-3 | 40 | — | | 3.9 |
| | | RX-5 | S-1 | 70 | S-4 | 30 | — | | 3.8 |
| | | RX-6 | S-1 | 60 | S-4 | 40 | — | | 4.0 |
| | | RX-7 | S-1 | 60 | S-2 | 40 | — | | 3.9 |
| | | R-52 | S-1 | 20 | S-2 | 50 | S-5 | 30 | 3.8 |
| | | R-53 | S-1 | 65 | S-5 | 30 | S-6 | 5 | 4.0 |
| | | R-54 | S-3 | 70 | S-4 | 30 | — | | 3.9 |
| | | R-55 | S-1 | 60 | S-2 | 40 | — | | 2.9 |
| | | R-56 | S-1 | 60 | S-2 | 40 | — | | 3.8 |
| | | R-57 | S-1 | 40 | S-6 | 20 | S-8 | 40 | 3.9 |
| | | R-58 | S-1 | 55 | S-2 | 35 | — | | 2.9 |
| | | R-59 | S-1 | 65 | S-5 | 30 | S-6 | 5 | 3.5 |
| | | R-60 | S-1 | 50 | S-4 | 20 | S-5 | 30 | 3.7 |
| | | R-61 | S-1 | 60 | S-2 | 40 | — | | 3.2 |

TABLE 4

| | | L/S | | | Develop- |
|---|---|---|---|---|---|
| | Resist | resolution | LWR | Pattern | ment |
| | composition | [nm] | [nm] | profile | defects |
| Example 1a | R-1 | 17.5 | 4.2 | Square | A |
| Example 2a | R-2 | 19.8 | 4.6 | Square | A |
| Example 3a | R-3 | 18.3 | 4.5 | Square | A |
| Example 4a | R-4 | 18.6 | 4.4 | Square | A |
| Example 5a | R-5 | 17.3 | 4.3 | Square | A |
| Example 6a | R-6 | 19.5 | 4.6 | Square | A |
| Example 7a | R-7 | 18.3 | 4.6 | Square | A |
| Example 8a | R-8 | 18.2 | 4.4 | Square | B |
| Example 9a | R-9 | 19.3 | 4.5 | Square | A |
| Example 10a | R-10 | 19.5 | 4.6 | Square | A |
| Example 11a | R-11 | 18.8 | 4.3 | Square | B |
| Example 12a | R-12 | 18.2 | 4.5 | Square | A |
| Example 13a | R-13 | 18.1 | 4.6 | Square | A |
| Example 14a | R-14 | 18.6 | 4.3 | Square | A |
| Example 15a | R-15 | 19.2 | 4.5 | Square | A |
| Example 16a | R-16 | 19.6 | 4.6 | Square | A |
| Example 17a | R-17 | 19.0 | 4.3 | Square | A |
| Example 18a | R-18 | 18.2 | 4.4 | Square | A |
| Example 19a | R-19 | 18.3 | 4.4 | Square | A |
| Example 20a | R-20 | 18.5 | 4.5 | Square | B |
| Example 21a | R-21 | 17.6 | 4.3 | Square | A |
| Example 22a | R-22 | 19.1 | 4.6 | Square | A |
| Example 23a | R-23 | 19.6 | 4.5 | Square | A |
| Example 24a | R-24 | 18.9 | 4.4 | Square | A |
| Example 25a | R-25 | 18.5 | 4.3 | Square | A |
| Example 26a | R-26 | 19.3 | 4.6 | Square | A |
| Example 27a | R-27 | 19.9 | 4.6 | Square | A |
| Example 28a | R-28 | 18.5 | 4.5 | Square | A |
| Example 29a | R-29 | 18.2 | 4.4 | Square | B |
| Example 30a | R-30 | 18.6 | 4.5 | Square | A |
| Example 31a | R-31 | 18.7 | 4.5 | Square | A |
| Example 32a | R-32 | 18.4 | 4.4 | Square | A |
| Example 33a | R-33 | 19.0 | 4.5 | Square | A |
| Example 34a | R-34 | 18.9 | 4.5 | Square | B |
| Example 35a | R-35 | 18.7 | 4.6 | Square | A |
| Example 36a | R-36 | 19.7 | 4.5 | Square | A |
| Example 37a | R-37 | 19.5 | 4.6 | Square | A |
| Example 38a | R-38 | 17.6 | 4.3 | Square | A |
| Example 39a | R-39 | 19.2 | 4.6 | Square | A |
| Example 40a | R-40 | 18.7 | 4.5 | Square | A |
| Example 41a | R-41 | 19.7 | 4.4 | Square | A |
| Example 42a | R-42 | 19.3 | 4.6 | Square | A |
| Example 43a | R-43 | 18.5 | 4.5 | Square | B |
| Example 44a | R-44 | 18.8 | 4.5 | Square | A |
| Example 45a | R-45 | 19.0 | 4.6 | Square | A |
| Example 46a | R-46 | 18.4 | 4.4 | Square | A |
| Example 47a | R-47 | 18.6 | 4.6 | Square | A |
| Example 48a | R-48 | 18.8 | 4.5 | Square | B |
| Example 49a | R-49 | 19.0 | 4.6 | Square | A |
| Example 50a | R-50 | 19.6 | 4.6 | Square | A |
| Example 51a | R-51 | 19.8 | 4.6 | Square | A |
| Comparative | RX-1 | 21.5 | 5.0 | Slightly | A |
| Example 1a | | | | reverse taper | |
| Comparative | RX-2 | 22.6 | 4.8 | Reverse taper | A |
| Example 2a | | | | | |
| Comparative | RX-3 | 24.6 | 4.7 | Slightly | B |
| Example 3a | | | | reverse taper | |
| Comparative | RX-4 | Failed to form the pattern | | | |
| Example 4a | | | | | |
| Comparative | RX-5 | 25.6 | 4.9 | Reverse taper | C |
| Example 5a | | | | | |
| Comparative | RX-6 | 20.9 | 4.7 | Slightly | D |
| Example 6a | | | | reverse taper | |
| Comparative | RX-7 | 22.6 | 5.0 | Slightly | A |
| Example 7a | | | | reverse taper | |
| Example 52a | R-52 | 17.8 | 4.4 | Square | A |
| Example 53a | R-53 | 17.9 | 4.4 | Square | A |
| Example 54a | R-54 | 18.1 | 4.4 | Square | A |
| Example 55a | R-55 | 18.2 | 4.6 | Square | B |
| Example 56a | R-56 | 18.3 | 4.6 | Square | A |
| Example 57a | R-57 | 18.5 | 4.6 | Square | A |
| Example 58a | R-58 | 18.4 | 4.5 | Square | B |
| Example 59a | R-59 | 18.0 | 4.4 | Square | A |
| Example 60a | R-60 | 18.1 | 4.5 | Square | B |
| Example 61a | R-61 | 17.9 | 4.4 | Square | A |

The results described in Table 4 have demonstrated the following: the composition of the present invention can have high resolution and high roughness performance, can provide an excellent pattern profile, and can achieve reduction in development defects in the formation of an ultrafine pattern (having, in particular, a line width or a space width of 20 nm or less). Extreme ultraviolet (EUV) exposure

### (4) Preparation of Resist Pattern

The wafer coated with the resist film obtained in (3) above was subjected to pattern exposure using an EUV exposure apparatus (Micro Exposure Tool manufactured by Exitech Ltd., NA (numerical aperture): 0.3, Quadrupole, outer sigma: 0.68, inner sigma: 0.36) and an exposure mask (line/space=1/1). After the exposure, heating on a hot plate was performed at 100° C. for 90 seconds; subsequently, immersion in a 2.38 mass % aqueous solution of tetramethylammonium hydroxide (TMAH) for 60 seconds was performed, and subsequently rinsing with water for 30 seconds was performed. Subsequently, the wafer was rotated at a number of rotations of 4000 rpm for 30 seconds, and subsequently baked at 95° C. for 60 seconds for drying.

### Evaluations

### (5) Evaluation of Resist Pattern

The obtained pattern was evaluated for resolution, roughness performance, and pattern profile in the following manner. The results will be described later in Table 5.

The irradiation energy for resolving a 1:1 line-and-space pattern having a line width of 50 nm was defined as sensitivity (Eop).

### L/S Resolution

The limiting resolving power (minimum line width at which a line and a space (line:space=1:1) are separated and resolved) at the exposure dose providing the above-described sensitivity (Eop) was defined as the resolving power (nm).

### Roughness Performance

The roughness performance was evaluated on the basis of line width roughness (LWR) in the following manner.

For the line width roughness, the line widths were measured at 50 points randomly selected over 0.5 m in the longitudinal direction of a line-and-space pattern (line:space=1:1) having a line width of 50 nm and provided at the above-described Eop; and the standard deviations of the line widths were determined and 3a (nm) was calculated. The smaller the value, the higher the performance.

### Pattern Profile

Profiles of 1:1 line-and-space patterns having a line width of 50 nm and formed at an irradiation dose providing the above-described sensitivity were observed using a scanning electron microscope (S-4800 manufactured by Hitachi, Ltd.) and evaluated: a profile of a line pattern in which a ratio represented by [line width at top portion (surface portion) of line pattern/line width at middle portion (at height position corresponding to half of height of line pattern) of line pattern] was 1.1 or more, was evaluated as “Reverse taper”; a profile of a line pattern in which the ratio was 1.03 or more and less than 1.1 was evaluated as “Slightly reverse taper”; and a profile of a line pattern in which the ratio was less than 1.03 was evaluated as “Square”.

### Development Defects

The 1:1 line-and-space pattern having a line width of 50 nm and formed at the sensitivity (Eop) was, using a defect inspection apparatus KLA2360 (trade name) manufactured by KLA-Tencor Corporation such that, in the defect inspection apparatus, the pixel size was set to 0.16 m and the threshold value was set to 20, superimposed on a comparison image on a pixel-by-pixel basis; from the resultant difference, defects (defects/cm²) were extracted and detected and the number of defects (defects/cm²) per unit area was calculated. Subsequently, the defects were reviewed to thereby classify and extract development defects from all the defects, and the number of development defects per unit area (defects/cm²) was calculated. Cases in which the value was less than 0.5 were evaluated as A; cases in which the value was 0.5 or more and less than 1.0 were evaluated as B; cases in which the value was 1.0 or more and less than 5.0 were evaluated as C; and cases in which the value was 5.0 or more were evaluated as D. The smaller the value, the higher the performance.

TABLE 5

| | | L/S | | | Develop- |
|---|---|---|---|---|---|
| | Resist | resolution | LWR | Pattern | ment |
| | composition | [nm] | [nm] | profile | defects |
| Example 1b | R-1 | 17.4 | 4.2 | Square | A |
| Example 2b | R-2 | 18.9 | 4.5 | Square | A |
| Example 3b | R-3 | 18.5 | 4.5 | Square | A |
| Example 4b | R-4 | 18.5 | 4.4 | Square | A |
| Example 5b | R-5 | 17.4 | 4.3 | Square | A |
| Example 6b | R-6 | 19.3 | 4.5 | Square | B |
| Example 7b | R-7 | 18.5 | 4.6 | Square | A |
| Example 8b | R-8 | 18.2 | 4.4 | Square | A |
| Example 9b | R-9 | 19.3 | 4.5 | Square | A |
| Example 10b | R-10 | 18.9 | 4.6 | Square | A |
| Example 11b | R-11 | 18.8 | 4.2 | Square | B |
| Example 12b | R-12 | 18.6 | 4.6 | Square | A |
| Example 13b | R-13 | 18.2 | 4.6 | Square | A |
| Example 14b | R-14 | 18.5 | 4.3 | Square | A |
| Example 15b | R-15 | 19.1 | 4.5 | Square | A |
| Example 16b | R-16 | 19.6 | 4.6 | Square | A |
| Example 17b | R-17 | 19.1 | 4.3 | Square | B |
| Example 18b | R-18 | 18.3 | 4.4 | Square | A |
| Example 19b | R-19 | 18.5 | 4.5 | Square | A |
| Example 20b | R-20 | 18.4 | 4.5 | Square | B |
| Example 21b | R-21 | 17.5 | 4.3 | Square | A |
| Example 22b | R-22 | 19.2 | 4.6 | Square | A |
| Example 23b | R-23 | 19.5 | 4.5 | Square | A |
| Example 24b | R-24 | 19.2 | 4.5 | Square | A |
| Example 25b | R-25 | 18.7 | 4.3 | Square | A |
| Example 26b | R-26 | 19.2 | 4.6 | Square | A |
| Example 27b | R-27 | 19.5 | 4.6 | Square | A |
| Example 28b | R-28 | 18.8 | 4.5 | Square | A |
| Example 29b | R-29 | 18.4 | 4.4 | Square | B |
| Example 30b | R-30 | 18.5 | 4.4 | Square | A |
| Example 31b | R-31 | 18.7 | 4.5 | Square | A |
| Example 32b | R-32 | 18.5 | 4.4 | Square | A |
| Example 33b | R-33 | 18.9 | 4.5 | Square | A |
| Example 34b | R-34 | 18.7 | 4.6 | Square | B |
| Example 35b | R-35 | 18.9 | 4.6 | Square | A |
| Example 36b | R-36 | 19.6 | 4.5 | Square | B |
| Example 37b | R-37 | 19.6 | 4.4 | Square | A |
| Example 38b | R-38 | 17.5 | 4.3 | Square | A |
| Example 39b | R-39 | 19.0 | 4.6 | Square | A |
| Example 40b | R-40 | 18.8 | 4.5 | Square | A |
| Example 41b | R-41 | 19.6 | 4.4 | Square | A |
| Example 42b | R-42 | 19.3 | 4.6 | Square | A |
| Example 43b | R-43 | 18.6 | 4.5 | Square | B |
| Example 44b | R-44 | 18.9 | 4.5 | Square | A |
| Example 45b | R-45 | 19.1 | 4.6 | Square | B |
| Example 46b | R-46 | 18.4 | 4.4 | Square | A |
| Example 47b | R-47 | 18.5 | 4.6 | Square | A |
| Example 48b | R-48 | 19.0 | 4.5 | Square | A |
| Example 49b | R-49 | 19.1 | 4.6 | Square | A |
| Example 50b | R-50 | 19.7 | 4.6 | Square | A |
| Example 51b | R-51 | 19.7 | 4.6 | Square | A |
| Comparative | RX-1 | 21.4 | 4.8 | Slightly | A |
| Example 1b | | | | reverse taper | |
| Comparative | RX-2 | 21.9 | 4.7 | Reverse taper | A |
| Example 2b | | | | | |
| Comparative | RX-3 | 23.5 | 4.8 | Slightly | B |
| Example 3b | | | | reverse taper | |
| Comparative | RX-4 | Failed to form the pattern | | | |
| Example 4b | | | | | |
| Comparative | RX-5 | 25.7 | 4.9 | Reverse taper | C |
| Example 5b | | | | | |
| Comparative | RX-6 | 20.8 | 4.8 | Slightly | D |
| Example 6b | | | | reverse taper | |
| Comparative | RX-7 | 22.3 | 5.0 | Slightly | A |
| Example 7b | | | | reverse taper | |
| Example 52b | R-52 | 17.7 | 4.4 | Square | A |
| Example 53b | R-53 | 17.8 | 4.3 | Square | A |
| Example 54b | R-54 | 18.2 | 4.4 | Square | A |
| Example 55b | R-55 | 18.3 | 4.6 | Square | A |
| Example 56b | R-56 | 18.2 | 4.5 | Square | A |
| Example 57b | R-57 | 18.4 | 4.5 | Square | A |
| Example 58b | R-58 | 18.5 | 4.5 | Square | B |
| Example 59b | R-59 | 18.3 | 4.5 | Square | A |
| Example 60b | R-60 | 18.1 | 4.6 | Square | B |
| Example 61b | R-61 | 17.9 | 4.3 | Square | A |

The results described in Table 5 have demonstrated the following: the composition of the present invention can have high resolution and high roughness performance, can provide an excellent pattern profile, and can achieve reduction in development defects in the formation of an ultrafine pattern (having, in particular, a line width or a space width of 20 nm or less).

The present invention can provide an actinic ray-sensitive or radiation-sensitive resin composition that has high resolution and high roughness performance, can provide an excellent pattern profile, and can achieve reduction in development defects in the formation of an ultrafine pattern (having, in particular, a line width or a space width of 20 nm or less), and an actinic ray-sensitive or radiation-sensitive film, a pattern forming method, and a method for producing an electronic device that use the composition.

The present invention has been described in detail and with reference to specific embodiments thereof, however, it would be apparent to those skilled in the art that various changes and modifications can be made therein without departing from the spirit and scope of the present invention.

What is claimed is:

1. An actinic ray-sensitive or radiation-sensitive resin composition comprising:
(A) a resin having a repeating unit (a) having a group that is decomposed by an action of an acid to generate a carboxylic acid, the repeating unit (a) being represented by a general formula (a) below; and
(B) a compound that generates an acid upon irradiation with an actinic ray or a radiation, the compound (B) being represented by a general formula (1) below, 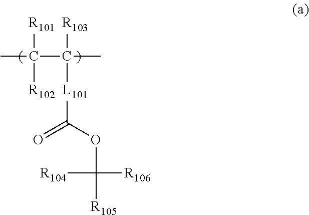
in the general formula (a), R₁₀₁ to R₁₀₃ each independently represent a hydrogen atom, an organic group, or a halogen atom; L₁₀₁ represents a divalent aromatic ring group; R₁₀₄ to R₁₀₆ each independently represent a hydrogen atom, an alkyl group, a cycloalkyl group, an aryl group, an alkenyl group, or an alkynyl group; two among R₁₀₄ to R₁₀₆ may be linked together to form a ring; when R₁₀₄ is a hydrogen atom, at least one of R₁₀₅ or R₁₀₆ represents an alkenyl group; when R₁₀₄ and R₁₀₅ are methyl groups and two among R₁₀₄ to R₁₀₆ are not linked together, R₁₀₆ represents a substituent other than a methyl group and an ethyl group, 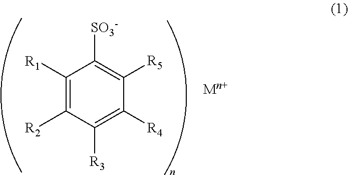
in the general formula (1), R₁ and R₅ each independently represent an aryl group or a heteroaryl group, R₂ to R₄ each independently represent a hydrogen atom or a substituent, Mⁿ⁺ represents a cation, and n represents an integer of 1 or more.

2. The actinic ray-sensitive or radiation-sensitive resin composition according to claim 1, wherein, in the general formula (1), R₃ represents an aryl group.

3. The actinic ray-sensitive or radiation-sensitive resin composition according to claim 1, wherein, in the general formula (1), at least one of R₁ to R₅ is a group including a polar group, a group including a group that is decomposed by an action of an acid to provide increased polarity, or a group including a group that is decomposed by an action of an alkali developer to provide an increased degree of solubility in the alkali developer.

4. The actinic ray-sensitive or radiation-sensitive resin composition according to claim 1, wherein, in the general formula (1), R₁, R₃, and R₅ are each a group represented by a general formula (Ar) below: 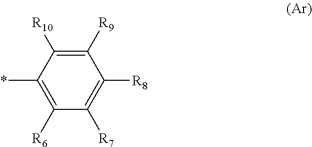
in the general formula (Ar), R₆ to R₁₀ each independently represent a hydrogen atom or a substituent; at least one of R₆ to R₁₀ is a group including a polar group, a group including a group that is decomposed by an action of an acid to provide increased polarity, or a group including a group that is decomposed by an action of an alkali developer to provide an increased degree of solubility in the alkali developer; and * represents a direct bond to the benzene ring in the general formula (1).

5. The actinic ray-sensitive or radiation-sensitive resin composition according to claim 1, wherein, in the general formula (1), R₁, R₃, and R₅ are each a group represented by a general formula (Ar1) below: 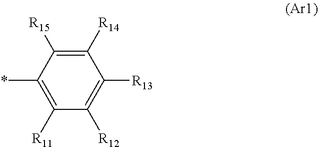
in the general formula (Ar1), R₁₁ to R₁₅ each independently represent a hydrogen atom or a substituent, and at least one of R₁ to R₁₅ represents a substituent Y below; and * represents a direct bond to the benzene ring in the general formula (1),
Substituent Y: a hydroxy group, a carboxyl group, a group having a carbonyl bond, an acyloxy group, an alkoxycarbonyloxy group, an aryloxycarbonyloxy group, an aryloxycarbonyl group, an alkoxycarbonyl group, a carbamoyl group, or an imide group.

6. The actinic ray-sensitive or radiation-sensitive resin composition according to claim 1, wherein the acid generated from the compound (B) upon irradiation with an actinic ray or a radiation has a pKa of −10 or more and 5 or less.

7. The actinic ray-sensitive or radiation-sensitive resin composition according to claim 1, wherein L₁₀₁ in the general formula (a) is a phenylene group.

8. The actinic ray-sensitive or radiation-sensitive resin composition according to claim 1, wherein a total number of carbon atoms included in R₁₀₄ to R₁₀₆ in the general formula (a) is 5 to 9.

9. The actinic ray-sensitive or radiation-sensitive resin composition according to claim 1, wherein a total number of carbon atoms included in R₁₀₄ to R₁₀₆ in the general formula (a) is 10 to 16.

10. The actinic ray-sensitive or radiation-sensitive resin composition according to claim 1, wherein at least one of R₁₀₄ to R₁₀₆ in the general formula (a) represents a group having a cyclic group.

11. The actinic ray-sensitive or radiation-sensitive resin composition according to claim 1, wherein two among R₁₀₄ to R₁₀₆ in the general formula (a) are linked together to form a ring.

12. The actinic ray-sensitive or radiation-sensitive resin composition according to claim 1, wherein the resin (A) further includes a repeating unit (c) represented by a general formula (c) below: 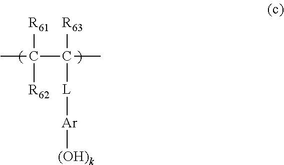
in the general formula (c), R₆₁ to R₆₃ each independently represent a hydrogen atom, an organic group, or a halogen atom, with the proviso that R₆₂ may be bonded to Ar to form a ring, and, in this case, R₆₂ represents a single bond or an alkylene group; L represents a single bond or a divalent linking group; Ar represents a (k+1) valent aromatic ring group and, when Ar is bonded to R₆₂ to form a ring, Ar represents a (k+2) valent aromatic ring group; and k represents an integer of 1 to 5.

13. The actinic ray-sensitive or radiation-sensitive resin composition according to claim 12, wherein L in the general formula (c) is a single bond.

14. The actinic ray-sensitive or radiation-sensitive resin composition according to claim 12, wherein Ar in the general formula (c) is a phenylene group.

15. The actinic ray-sensitive or radiation-sensitive resin composition according to claim 1, wherein a content of the repeating unit (a) is 10 mass % or more relative to a total mass of the resin (A).

16. The actinic ray-sensitive or radiation-sensitive resin composition according to claim 1, wherein a mass ratio (repeating unit (a)/compound (B)) of the repeating unit (a) included in the resin (A) to the compound (B), the resin (A) and the compound (B) being included in the actinic ray-sensitive or radiation-sensitive resin composition, is 0.75 or more.

17. An actinic ray-sensitive or radiation-sensitive film formed from the actinic ray-sensitive or radiation-sensitive resin composition according to claim 1.

18. A pattern forming method comprising:
forming an actinic ray-sensitive or radiation-sensitive film from the actinic ray-sensitive or radiation-sensitive resin composition according to claim 1;
exposing the actinic ray-sensitive or radiation-sensitive film; and
developing the exposed actinic ray-sensitive or radiation-sensitive film with a developer.

19. A method for producing an electronic device, the method comprising the pattern forming method according to claim 18.
